(19) United States
(12) Patent Application Publication
(10) Pub. No.: US 2024/0135259 A1
(43) Pub. Date: Apr. 25, 2024

(54) COMPUTER IMPLEMENTED METHOD FOR GENERATING A 3D OBJECT

(71) Applicant: MONOLITH AI LIMITED, London (GB)

(72) Inventors: Richard AHLFELD, London (GB); Saravanan SATHYANANDHA, London (GB); Peter WOOLDRIDGE, London (GB); Marc EMANUELLI, London (GB); Syed SAMI, London (GB); Stefan DRUC, London (GB); Konstantin SHMELKOV, London (GB); Will JENNINGS, London (GB)

(21) Appl. No.: 18/543,600

(22) Filed: Dec. 18, 2023

Related U.S. Application Data
(63) Continuation of application No. PCT/GB22/51532, filed on Jun. 17, 2022.

(30) Foreign Application Priority Data
Jun. 17, 2021 (GB) 2108687.1

(51) Int. Cl. G06N 20/00

(52) U.S. Cl. CPC G06N 20/00

(57) ABSTRACT

There is provided a method for a computer implemented method for generating a 3D object. The method comprises training a machine learning system to learn design parameter values that give rise to an optimally performing version of the 3D object; and processing, using the machine learning system, input data relating to the 3D object, in an unsupervised manner such that it can be used for generative purposes, such as the creation of novel geometries or other parameters of the 3D object.

### CROSS-REFERENCE TO RELATED APPLICATIONS

This application is a continuation of U.S. Application No. PCT/GB2022/051532, filed on Jun. 17, 2022, which claims priority to GB Application No. GB 2108687.1, filed Jun. 17, 2021, the entire contents of which being fully incorporated herein by reference.

### BACKGROUND OF THE INVENTION

### 1. Field of the Invention

The field of the invention relates to computer implemented methods and systems for generating or predicting the performance of a 3D object or of novel geometries of the 3D object.

A portion of the disclosure of this patent document contains material, which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### 2. Description of the Prior Art

Accurately modelling and predicting the performance of complex engineering problems often rely on expensive, time-intensive, or repetitive tests.

Complex engineering design is an iterative design process that combines creativity, scientific and engineering knowledge and that consists of many interactions between CAD designers, engineers and/or data scientists. Normally a CAD designer provides a concept and gives it to the engineering team to perform simulation and testing. However, since engineering design is a creative process with many unknowns, designs may be revised or updated at any step of the design process. Even the stage of the final testing may call for a re-design, leading to additional simulations and tests being performed. This may often result in long development lead time as well as problems when for example design requirements are fluctuating.

Interactions between designers and engineers through the development of a product, such as a complex engineering product, need to be facilitated.

Neural Networks (NNs) algorithms are computational learning systems that use a network of functions to understand and translate data inputs of one form into desired outputs given training samples. NNs are widely applicable to a large range of machine learning problems. Training and programming a NN can be a very challenging task, especially when applying it to complex problems, such as engineering problems.

With a large enough dataset, NNs can learn to predict extremely complex non-linear relationships. NNs have many parameter choices which affect the accuracy and performance of the model predictions. A common criticism of NNs is that they are more difficult to explain than other simpler models and it can often be hard to understand why a model has made a specific prediction.

A lot of engineering R&D is also done using 3D simulations, such as Finite Element Analysis (FEA) or Computational Fluid Dynamics. Depending on the complexity of the problem and accuracy required, 3D simulations may be costly to compute. Surrogate models may then be used for evaluating computationally expensive problems. A surrogate model is a simple model that approximate complex models using training samples. However, trust issues with surrogate models also exist such as knowing when the surrogate model has made a wrong prediction, or not understanding the steps for the model obtain a result.

A solution for a platform that would allow end-users to quickly build models that can predict the performance of complex engineering problems is also needed such that less testing is performed, and quality products are developed in an efficient manner.

There is also a need for a 3D explainability solution that can be applied to complex 3D data, including, but not limited to, complex engineering problems.

### SUMMARY OF THE INVENTION

The invention is a computer implemented method for generating a 3D object as defined in the appended Claims.

The method comprises training a machine learning system to learn design parameter values that give rise to an optimally performing version of the 3D object; processing, using the machine learning system, input data relating to the 3D object, in an unsupervised manner such that it can be used for generative purposes, such as the creation of novel geometries or other parameters of the 3D object.

A consolidated list of key features is provided in Section 9.

Engineers create an incredibly varied and versatile range of products; they also make use of a wide range of tools to understand and predict how these products will perform. A few examples: you first need to predict what the performance will be before prototyping an actual real-world product. For example, in the automotive industry, engineers spend weeks setting up aerodynamic simulations to assess virtual products' behaviour. Engineers also need to understand all the different scenarios in which products will be used. To certify an aircraft design, for example, engineers simulate millions of flight scenarios taking into account different weather conditions, different pilot manoeuvres and different weight distributions. Engineers also need to figure out how to make a product in high volumes: manufacturing is a complicated thing since it involves different materials, different geometries and different test conditions: just imagine trying to stamp a million car doors under high pressure. It is not easy to consistently ensure high manufacturing quality.

Design, simulation, testing and manufacturing seem like wildly different disciplines. The present invention is implemented in the Monolith platform: a single software platform that allows engineers to better solve problems in all of these areas. It does this by enabling engineers to build their own expert systems, fueled by historic data and their own expertise.

Conventionally, engineers from different disciplines are often split into separate departments. Experts in different sectors (design, durability, ergonomics, structural dynamics, aerodynamics, simulation, testing and manufacturing etc.) will all work in the same physical system but they will spend a great deal of time trying to piece together requirements from these different disciplines: this is what makes engineering a highly iterative, time consuming and costly process: Engineers need to carry out many tests or simulations before finally deciding on the best design.

The Monolith AI platform helps engineers instantly and automatically predict the performance of their products (e.g across parameters relevant to any one or more of the previously separated sectoral domains, such as design, durability, ergonomics, structural dynamics, aerodynamics, simulation, testing and manufacturing), not by starting from scratch each time, but by using AI models trained on what worked best in the past, whether this was acquired from tests or from expert intuition. The Monolith platform for engineering data makes the latest artificial intelligence solutions accessible to any engineer: this platform empowers engineers to automatically predict the performance of materials, components, designs, simulations, or manufacture-ability results using past data. This makes it much easier to make decisions, to help engineering companies accelerate their product development workflow in a completely new way.

Using the Monolith platform, any engineer can link their designs to predicted product performance, across potentially all of the relevant sectors (e.g. (design, durability, ergonomics, structural dynamics, aerodynamics, simulation, testing, and manufacturing etc.) with the assistance of machine learning.

One example: the length of time and cost involved in developing new cars could be halved in the future using the Monolith platform. For new car design, the Monolith platform uses self-learning models to instantly predict the results of complex vehicle dynamics systems, in the process reducing the need for physical tests or simulations. This ensures every element of the development process is accelerated, from the initial design to iterations, validation, and production. There is also less of a requirement to construct expensive physical prototypes, meaning significant cost savings, while a reduction in on-road testing enhances sustainability, too. While at present there is a reliance on a combination of physical and simulator testing, this is inefficient because the accuracy of the latter can be limited, which means an increased number of physical tests are necessary to validate the results. The Monolith platform makes use of the vast amounts of data produced by physical and simulation tests. The platform leverages this data to train AI self-learning models to accurately predict performance; by interpreting vehicle systems' behavior from the data, the AI helps engineers understand how vehicles react in areas that are currently impossible to simulate, as well as under different conditions.

Areas of the development process aided by the approach are wind tunnel testing, track testing, wheel and tire assessment, vehicle dynamics, durability, crash testing and powertrain appraisal. The Monolith platform empowers automotive R&D teams to use AI to learn the best possible insights from years of existing test data, or instantly predict results from a small sample of current tests. This means manufacturers can bring new vehicles to market faster—which is vital to reach EV ambitions.

### BRIEF DESCRIPTION OF THE FIGURES

Aspects of the invention will now be described, by way of example(s), with reference to the following Figures, which each show features of the invention:

FIG. 1 shows a screenshot of a notebook area of the Monolith platform.

FIG. 2 shows a screenshot of the file manager area of the Monolith platform.

FIG. 3 shows a screenshot of the code area of the Monolith platform.

FIG. 4 shows a screenshot of creating or coding a new function.

FIG. 5 shows a screenshot of the teams area.

FIG. 6 shows another screenshot of the teams area.

FIG. 7 shows a screenshot of an end-user creating a team.

FIG. 8 shows a screenshot with an example of a team content.

FIG. 9 shows a screenshot illustrating how to create a notebook.

FIG. 10 shows a screenshot of the notebook layout displaying several manipulators.

FIG. 11 shows a screenshot with an example of a notebook explorer displaying the list of all datasets and models present in a specific notebook.

FIG. 12 shows a screenshot listing the features of the ‘Import & Export’ manipulator.

FIG. 13 shows the notebook style interface displaying the tabular step including any useful metadata associated with this step.

FIG. 14 shows a screenshot listing the features of the ‘Explore’ manipulator.

FIG. 15 shows a screenshot of user-configurable parameters of the ‘2D Point plot’ feature.

FIG. 16 shows a screenshot with an example of output of the 2D point plot.

FIG. 17 shows a screenshot listing the features of the ‘Model’ manipulator.

FIG. 18 shows a screenshot of user-configurable parameters when training a neural network.

FIG. 19 shows a screenshot of a notebook style interface area including the output when a machine learning model has been trained.

FIG. 20 shows a screenshot listing the features of the ‘Apply’ manipulator.

FIG. 21 shows a screenshot of user-configurable parameters of the ‘Scalar Prediction’ feature.

FIG. 22 shows a screenshot with an example of output of the ‘Scalar Prediction’ feature.

FIG. 23 shows a notebook style interface area with the steps or queries that have been applied.

FIG. 24 shows a screenshot illustrating when tabular data has been loaded.

FIG. 25 shows a screenshot with an example of output of the ‘Count’ feature.

FIG. 26 shows a screenshot with an example of output of the ‘Head’ feature.

FIG. 27 shows a screenshot of user-configurable parameters of the ‘Distribution’ feature.

FIG. 28 shows a screenshot with an example of output of the ‘Distribution’ feature.

FIG. 29 shows a screenshot with another example of output of the 2D point plot.

FIG. 30 shows a screenshot of user-configurable parameters of the ‘Intelligent Correlation’ feature.

FIG. 31 shows a screenshot with an example of output of the ‘Intelligent Correlation’ feature.

FIG. 32 shows a screenshot of user-configurable parameters of the ‘Parallel Coordinates’ feature.

FIG. 33 shows a screenshot with an example of output of the ‘Parallel Coordinates’ feature.

FIG. 34 shows a screenshot with an example of output of the ‘Parallel Coordinates’ feature in which an end-user has selected a specific region for one or more variable.

FIG. 35 shows a screenshot with an example of output of the ‘Parallel Coordinates’ feature in which an end-user has further selected a specific region for one or more variable.

FIG. 36 shows a screenshot listing the features of the ‘Transform’ manipulator.

FIG. 37 shows a screenshot of user-configurable parameters of the ‘Quick Column’ feature.

FIG. 38 shows a screenshot of user-configurable parameters of the ‘Train Test Split’ feature.

FIG. 39 shows a screenshot of the output when the neural network has been trained.

FIG. 40 shows a screenshot with an example of output of the ‘Predicted vs. Actual’ feature.

FIG. 41 shows a screenshot with an example of output of the ‘Validation Plot’ feature.

FIG. 42 shows a screenshot with an example of output of the ‘Learning Curve’ feature.

FIG. 43 shows a screenshot with an example of output of the ‘Curve Prediction’ feature.

FIG. 44 shows a screenshot with an example of output of the ‘Min/Max Optimisation’ feature.

FIG. 45 shows a screenshot with an example of output of the ‘Line Plot’ feature.

FIG. 46 shows a screenshot with an example of output of the ‘Parallel Coordinates’ feature.

FIG. 47 shows the output of the validation plot that shows the ‘ground truth’ data overlaid with predictions from each model.

FIG. 48 shows a screenshot with an example of output of the ‘Compare Performance Metrics’ feature.

FIG. 49 shows a screenshot with an example of output of the ‘Compare Against Criteria’ feature.

FIG. 50 shows a screenshot with an example of output of the ‘Curve Prediction’ feature.

FIG. 51 shows a screenshot with an example of output of the ‘Surface Prediction’ feature.

FIG. 52 shows example of input variables or design parameters of a wind turbine.

FIG. 53 shows a screenshot with an example of a ‘Custom code’ area in the notebook.

FIG. 54 shows the output of the line plot tool in which the axial velocity is displayed as a function of distance.

FIG. 55 shows a screenshot with an example illustrating the instant prediction of the performance of the wind turbine.

FIG. 56 shows a screenshot with an example of output of the ‘3D point plot’ feature.

FIG. 57 shows a 3D data visualisation.

FIG. 58 shows a screenshot with an example of output of the ‘Surface Prediction’ feature.

FIG. 59 shows a diagram illustrating the structure of an autoencoder.

FIG. 60 shows a screenshot of user-configurable parameters of the ‘Autoencoder’ feature.

FIG. 61 shows a screenshot with plots indicating the model's scoring metric for a specific instant as the model learns to parameterise.

FIG. 62 shows the final output of the ‘Autoencoder’ feature.

FIG. 63 shows a screenshot of user-configurable parameters of the ‘Assess Autoencoder’ feature.

FIG. 64 shows the output of a qualitative assessment, with the original mesh overlaid with the same mesh which has been encoded and decoded.

FIG. 65 shows diagrams with further output of qualitative assessment.

FIG. 66 shows the output of the ‘view decoded designs’ feature.

FIG. 67 shows the effect of varying some of the latent parameters on the geometry of the wind turbine dataset.

FIG. 68 shows the output displaying the results of the optimisation step displaying three optimal set of input parameters found for a target set of outputs.

FIG. 69 shows a screenshot in which the end-user can scroll up to the Targeted Optimisation step results and generate a new design.

FIG. 70 shows an optimal turbine blade design for different windspeed conditions.

FIG. 71 shows a plot comparing a neural network model trained on a small data set and one trained on a large dataset.

FIG. 72 shows a plot comparing a neural network model trained on a small data set and one trained on a large dataset for a different, more complex problem.

FIG. 73 shows a plot illustrating the impact of missing data on the predictions of a machine learning model.

FIG. 74 shows the output of the ‘Plot Missing Data’ step.

FIG. 75 shows a plot comparing two neural network models.

FIG. 76 shows a 3D point plot for a neural network when the input data is without noise.

FIG. 77 shows a plot of the model performance when trained with the data without noise.

FIG. 78 shows a 3D point plot for a neural network when the input data includes medium noise.

FIG. 79 shows a plot of the model performance when trained with the data with medium noise.

FIG. 80 shows a 3D point plot for a neural network when the input data includes strong noise.

FIG. 81 shows a plot of the model performance when trained with the data with strong noise.

FIG. 82 shows the performance of three neural network models, when trained without noise, with medium noise and with strong noise.

FIG. 83 shows a histogram plot of the prediction error for three neural network models, when trained without noise, with medium noise and with strong noise.

FIG. 84 shows the output of the ‘Intelligent Correlations’ feature.

FIG. 85 shows the output of a ‘Predicted vs Actual’ step illustrating the performance of the neural network.

FIG. 86 shows a diagram illustration the impact of each input of a model on the different outputs.

FIG. 87 shows diagrams providing results of different explainability techniques for wind turbines.

FIG. 88 shows diagrams providing results of different explainability techniques for cars.

FIG. 89 shows plots providing results of different explainability techniques for wind turbines (89A) and for cars (89B).

FIG. 90 shows a screenshot with the output of the ‘Explain Predictions’ feature.

FIG. 91 shows a screenshot displaying the impact of different design parameters on product recyclability.

FIG. 92 shows a screenshot displaying the impact of different design parameters on product cost.

FIG. 93 shows a screenshot displaying the impact of different design parameters on product cost.

FIG. 94 shows a diagram illustrating a SHAP algorithm.

FIG. 95 shows the heat map generated after selecting to run Sobol with first order.

FIG. 96 shows the heat map generated after selecting to run Sobol with second order.

FIG. 97 shows the output of the Morris method.

FIG. 98 shows the output of the FAST method.

FIG. 99 shows the results in which actual (left) and predicted (right) surface pressure results are compared using mean squared error.

FIG. 100 shows further results in which actual (left) and predicted (right) surface pressure on a test set is compared.

FIG. 101 shows a structured autoencoder results from Shapenet cars.

FIG. 102 shows a diagram illustrating the unstructured autoencoder.

FIG. 103 shows an example of an exported 3D model.

FIG. 104 shows an example of a script of a non-convolutional UAE.

FIG. 105 shows an example of a script of a convolutional UAE.

FIG. 106 shows an example of a script of a non-convolutional UAE decoder.

FIG. 107 shows an example of a script of a convolutional UAE decoder.

FIG. 108 shows results with 3D input data consisting of 64\hat{ }3 voxels and of 1283 voxels.

FIG. 109 shows the actual and reconstructed 2D slice.

FIG. 110 shows an image of the results on spoiler with an interpolation between random shapes (110A) and with an interpolation from large to small (110B).

FIG. 111 shows images of reconstructed 3D objects.

FIG. 112 shows images of 3D objects generated from random sampling.

FIG. 113 shows an image of the reconstructed shape of a car.

FIG. 114 shows the results of the surface pressure prediction

FIG. 115 shows a pictorial representation of the concept activation vectors method for generating user-defined 3D shapes or objects.

FIG. 116 shows a diagram illustrating a conceptual path in latent space.

FIG. 117 shows a table with collected and generated examples of concepts.

FIG. 118 shows a histogram providing TCAV metric expressed in terms of sign count and magnitude, since the values for each concept in the CAV pair are complementary we only show the values for the first concept. Error bars represent one standard error.

FIG. 119 shows diagrams including concept blending for two pairs of CAVs. We blend the Ellipsoids—Cuboids CAV with the Sport—Sedan CAV (left) and with the Sport—Random CAV (right). Note the different effect of moving towards the Sport concept in both cases.

FIG. 120 shows the top five queries from the dataset for a specific concept. From the top: Sedan, Ellipsoids, Sport and Cuboids.

FIG. 121 shows query results for the re-computed Sport—Random CAV.

FIG. 122 shows query results of varying the HighBump CAV. Original shape is in the middle with negative s translations to the left and positive to the right.

FIG. 123 shows a diagram illustrating how HighBump—LowBump CAV isolates the height parameter of the deformation for variable ellipsoid bodies.

### DETAILED DESCRIPTION

This Detailed Description section describes one implementation of the invention, called Monolith or the Monolith platform.

The Monolith platform provides the following features, such as, but not limited to:
engineers and designers are able to easily collaborate as Monolith provides a single platform in which the vision of the designers can be pieced together alongside the simulation and testing of the engineering team;
a data agnostic approach is provided such that the platform can take many types or form of data as input such as simulation data, measurement data, test data or physics data. The type of data used can also be interchangeable or updated to any other types within a workflow;
engineering data is used to create accurate, self-learning models to quickly understand and instantly predict the performance of complex systems under many operating conditions;
self-learning models are built with test data from all measurement, signal or sensor data types including time-series, 3D CAD and tabular data;
self-learning models can be improved by feeding more data, hence more learning and less testing is needed to develop quality product faster;
the parameter choices of NNs are simplified down to the most common ones for engineering use-cases;
engineers are empowered to spend less time running expensive, repetitive tests and more time learning from their data to predict the exact tests to run;
no coding or expertise in statistics is required; just engineering expertise and test data;
a cloud-based AI software is provided with an intuitive, easy-to-use UI designed for quick adoption and time to obtain results;
the platform provides understanding on how AI is best applied in engineering so the ideal use cases to achieve tangible ROI can be identified;
the platform is not a black box: instead, engineers use their test data to develop better quality and performing products faster;

Generally, the methods and systems presented may be applied to any complex engineering problems implemented for example in one of the following industries: aerospace, automotive, defense, pharmaceutical or fast-moving consumer goods.

An implementation of the invention is described in the following Sections:
SECTION 1. Engineering Workflow
SECTION 2. Explainability
SECTION 3. DGCNN
SECTION 4. Structured Autoencoder (SAE)
SECTION 5. Unstructured Autoencoder (UAE)
SECTION 6. Shape Optimization
SECTION 7. Examples of Use Cases
SECTION 8. Concept Activation Vectors for Generating User-Defined 3D Shapes
SECTION 9. Key Features

### Section 1. Engineering Workflow

This section describes the engineering workflow and includes several use cases applications.

An environment is provided for building a data processing/modelling pipeline that can transform engineering data into an AI model. The AI model is then configured to make predictions to dramatically accelerate the engineering workflow.

As will be apparent in the following examples, the graphical user interface (GUI) displays a low code/notebook style interface. Within a notebook, steps may be added sequentially to build a data processing pipeline. Advantageously, the steps may be combined in any order to arrive at a solution.

The platform is configured such that the design process is not a repetitive task. The platform is also agnostic to the type or source of data used, and the data processing pipeline may be continually updated when new or revised data is received.

Within the Monolith platform, an end-user can quickly train a machine learning system to predict the performance of a 3D object. The number of steps that the end-user must perform to train a machine learning system and arrive at a solution is also minimised. The performance of complex engineering 3D objects can also be predicted across multiple areas, the areas including several of the following areas: design, durability, ergonomics structural dynamics, aerodynamics, simulation, testing, and manufacturing. Advantageously, engineering, and aesthetic requirements may be simultaneously satisfied.

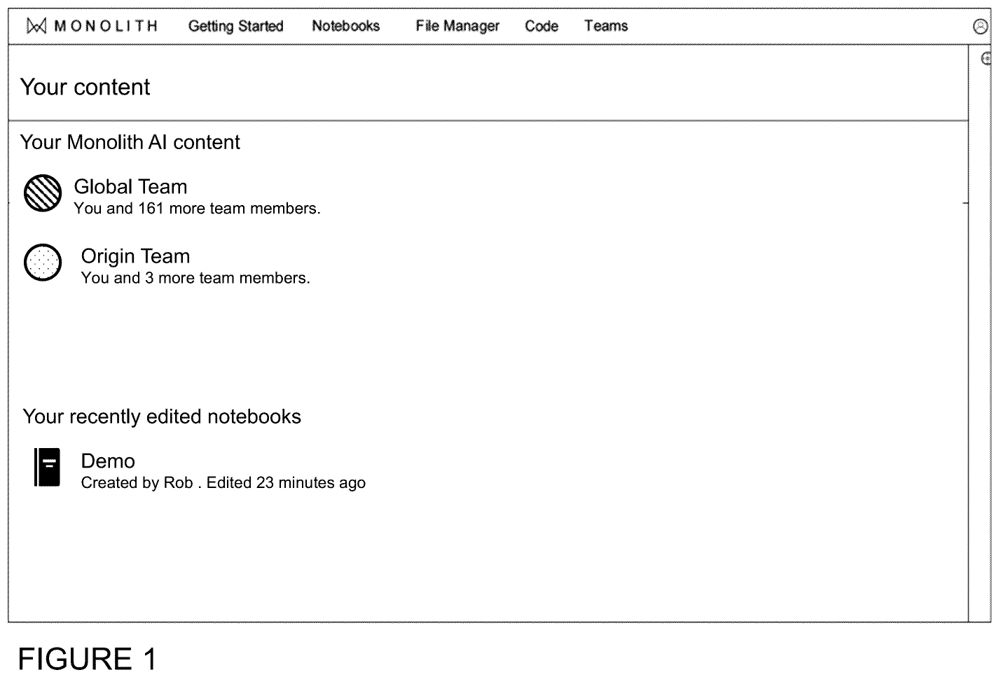

FIG. 1 shows a screenshot of a notebook area of the Monolith platform. The header of the platform contains the following areas or items: Getting Started, Notebooks, File Manager, Code, Teams. The Getting Started includes several tutorials.

In the Notebooks area, a view with the different folders and notebooks available is displayed. The end-user can see the teams they belong to. One of the team areas is the ‘Global team’ that shows a folder area visible to everyone with a log-in to the same platform.

Private teams may also be created to separate workflow and data from other teams with access to the same platform. Only members of a specific team can see notebooks created in the specific team folder or files that have been uploaded to the specific team folder.

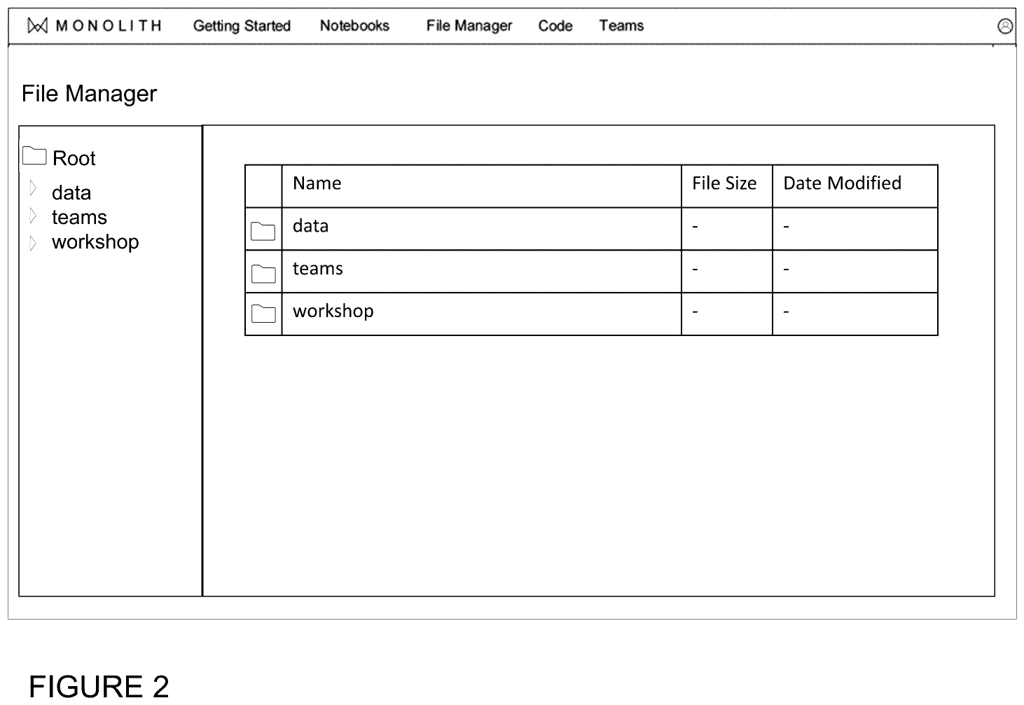

FIG. 2 shows an example of the file manager area. The file manager may be used to load data in the platforms, although this may also be done via APIs. The file manager area includes a navigation panel on the left-hand side that enables the end-user to choose a specific folder. Each team in the platform may have its own folder, only visible and accessible by the members of that team. Sub-folders may also be created.

Once a file is uploaded in a team folder, it can be imported to any notebook created in that team environment.

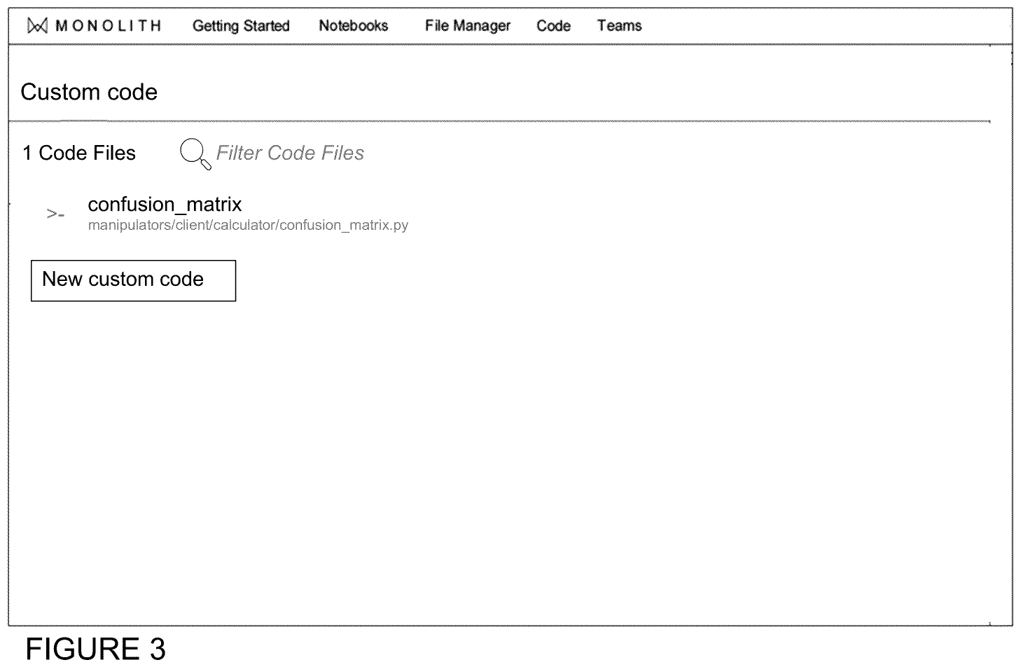

FIG. 3 shows an example of the code area. The custom code area enables a user to write and run his own code, such as python code to transform a tabular or 3D data set. Even though the platform offers numerous functions to transform tables, users might sometimes want to transform their data in a way so specific that no general solution is available. The custom code area function may therefore allow such users to manipulate the data with total freedom and flexibility.

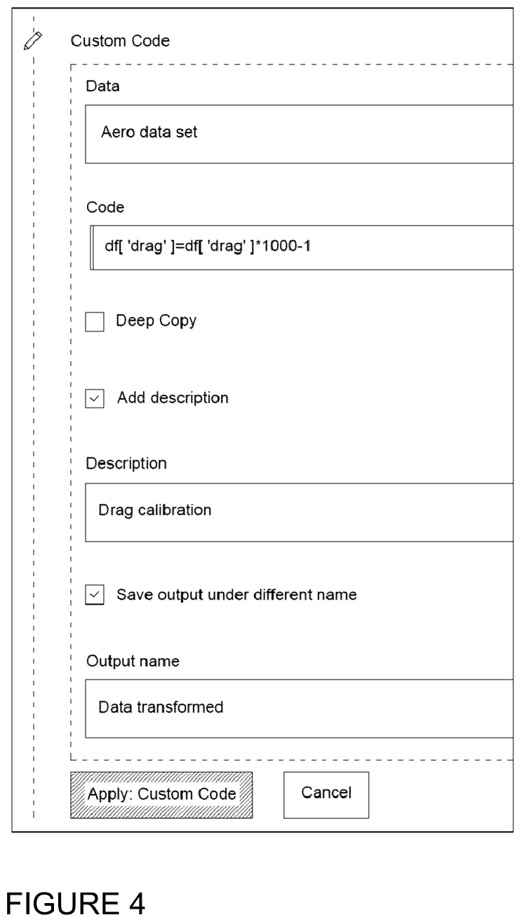

FIG. 4 shows an example of creating or coding a new function. The function can be used for example to manually modify the values of the table, restructure the table, to create new columns in a complex way that cannot be handled by the quick column function. First, the data on which to apply the Python code is selected. The code can then be written in the code section. A description to the code may be visible from the notebook (e.g. “data filtered in my specific way”) can be created. The code can be modified or updated and re-run at any time. For example, the data selected initially may be replaced, or any modifications may be saved in a new table.

A few examples of codes are now provided:
df[‘score’]=df[‘drag’]*2/(1−df[‘lift’]*1000); this code creates a new column “score” that will be calculated from the two columns “drag” and “lift”.
df[‘drag’]=df[‘drag’]*1000−1; this code simply modifies the existing column “drag” according to a user defined operation.
df=df.loc[df[‘drag’]>2]; this code keeps rows for which the value of the drag column is higher than 2.
df[‘time’]=df.ID.apply(lambda st:int(st[4:]))/100; this code creates a column called “time” which would remove the first 4 characters of the column “ID”, then convert the result into an integer, and then divide the result by 100.
df[‘critical’]=np.where(df[‘drag’]<0.75, 0, 1); this code creates a new column called “critical” which would be 0 if the drag column is lower than 0.75, and 1 otherwise.
polydata.point_arrays[‘NewField’]=polydata.points[:, 0]; this code creates a new field called “NewField” that would be assigned the value of the X coordinate at each point (see below for more details on custom code for 3D data).
tempVariable=polydata.points[:, 0]polydata.points [:, 0]=polydata.points[:, 1] polydata.points[:, 1]=tempVariable; this code swaps the X and Y coordinates.
polydata=polydata.triangulate( ); this code transforms a mesh to triangular faces, which may be easier to manipulate than quadrilateral faces.

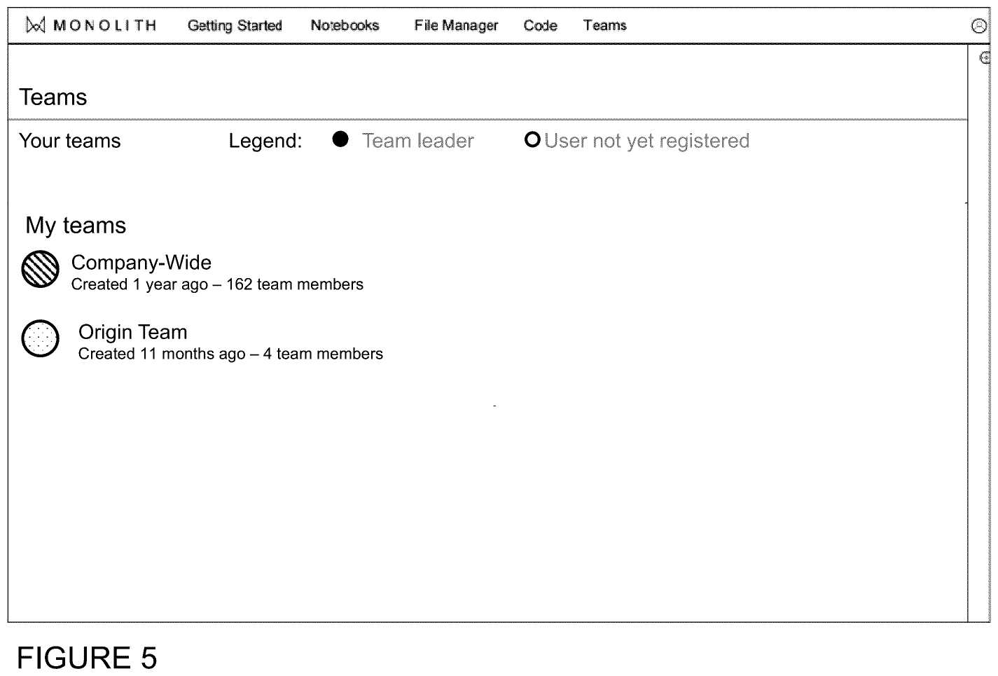

FIG. 5 shows a screenshot of the Teams area. The platform offers the possibility to create different teams. This is to enable different user groups to work on different projects that cannot be shared with the rest of a company. Teams may isolate the data, models, notebooks, dashboards of the team from other platform users. On the launching page of the platform, a list of teams may be displayed.

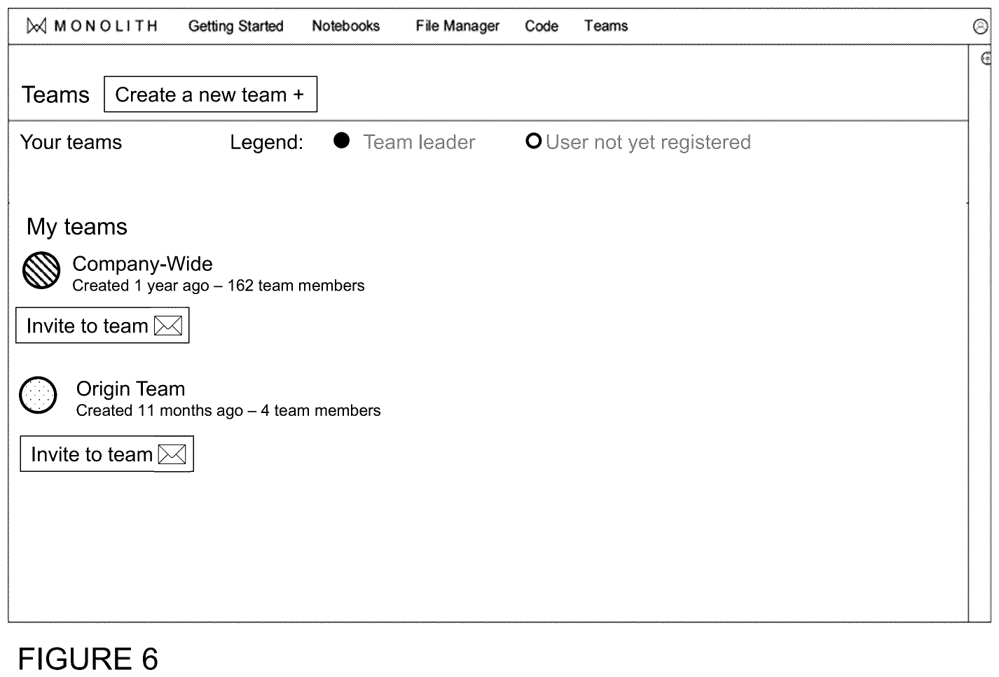

As shown in FIG. 6, a tab may be displayed to create a new team by clicking on the team tab.

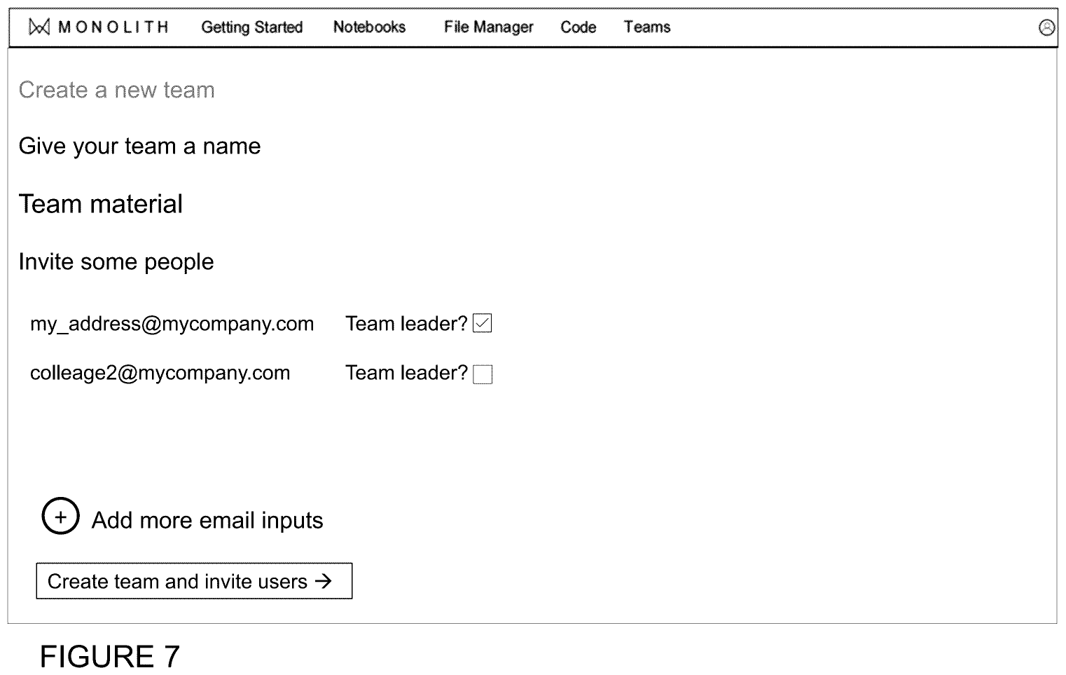

FIG. 7 shows an example of an end-user creating the team material, including themselves as a team leader and two other end-users as team members.

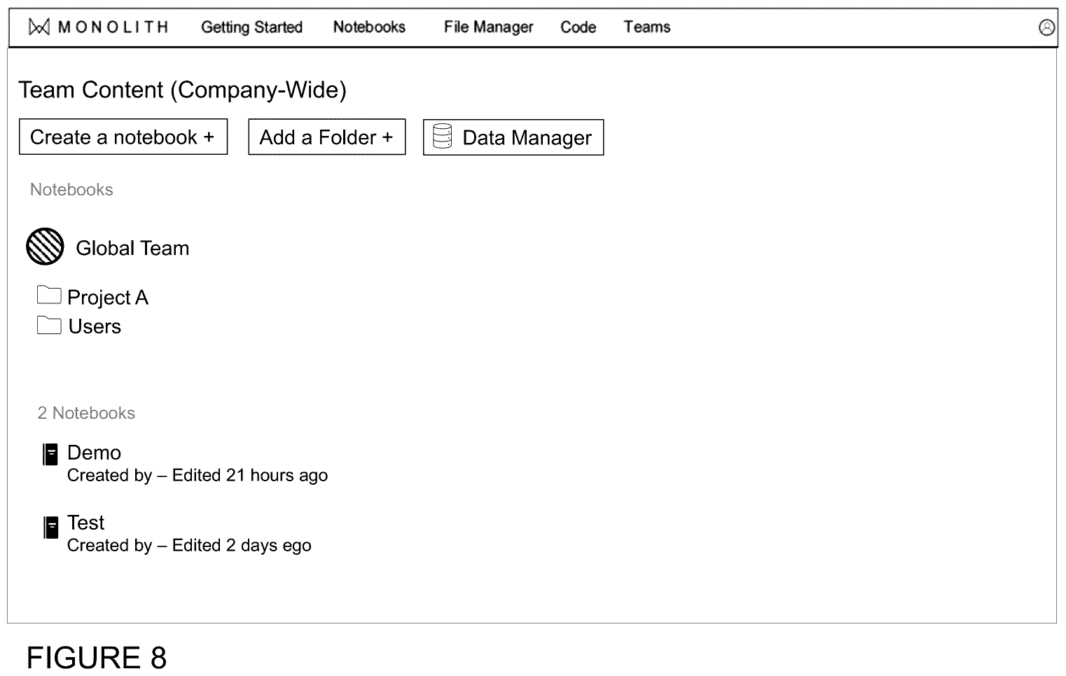

To create a notebook, an end-user may click on the button or item ‘Create a notebook’ as shown on the screenshot on FIG. 8.

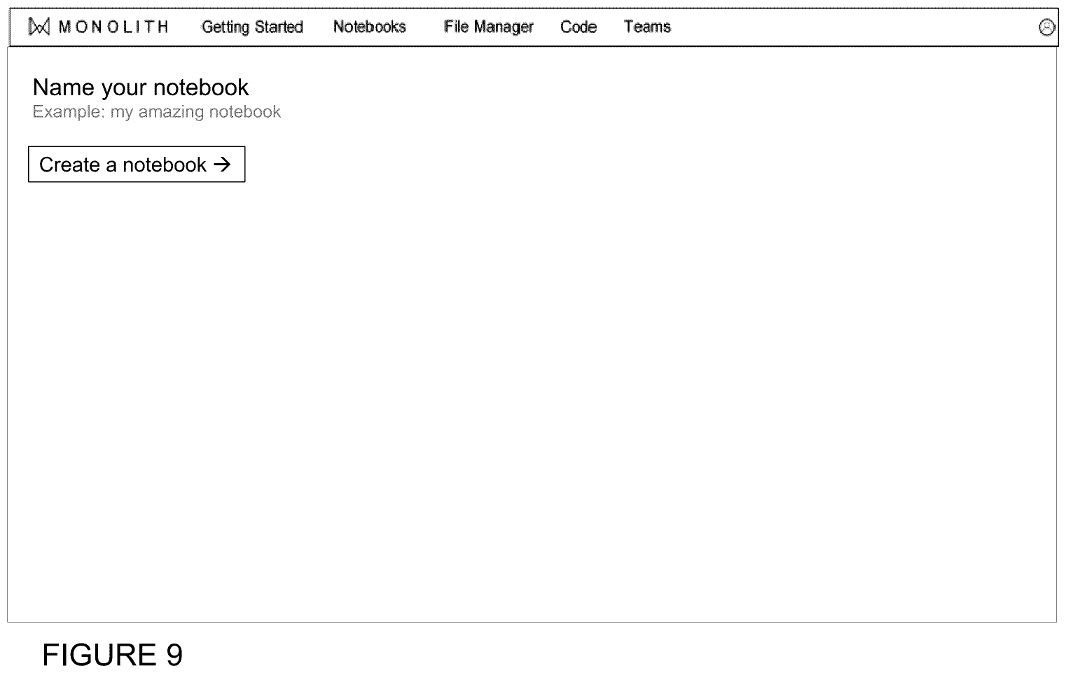

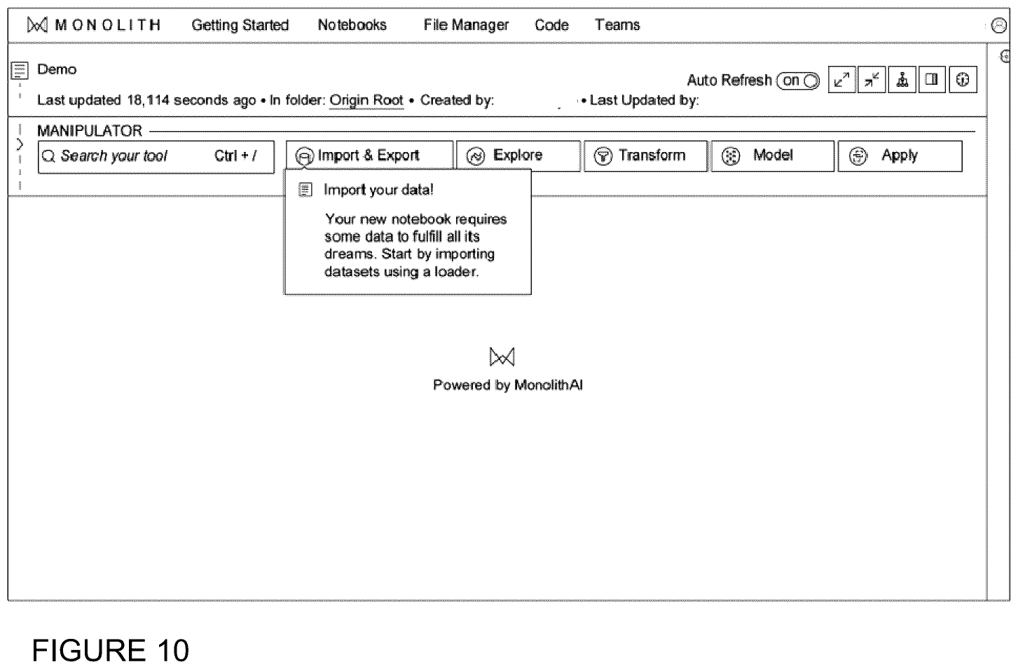

Once a notebook is created and named as shown in FIG. 9, the notebook layout displays several manipulators as shown in FIG. 10.

In the example provided in FIG. 10, the following five manipulators are displayed: Import/export, Explore, Transform, Model, Apply. The platform is configured to give quick access to manipulators. The total number of clicks needed to access manipulators is reduced, such that it is easier to interact with the platform. These manipulators may always be accessible using a single click or action via the user interface.

The notebook style interface is configured to provide a low code interface that displays each step or query from an end-user. The orders of any steps or queries in a notebook may be easily reorganised and each subsequent steps may be automatically re-run when the order of the steps is changed.

When editing a step in a notebook, all subsequent steps may also be automatically rerun with an auto refresh feature. For example, a tabular loader may be updated to include more training data in a notebook—this will automatically retrain any models in the notebook, saving the time to rebuild a new data processing/modelling pipeline. A toggle button is therefore easily accessible on the notebook interface, to temporarily disable auto refresh. This may be useful when editing multiple post-processing steps in a long notebook to avoid any subsequent steps are re-run before the updating of pre-processing steps is completed.

Notebooks may start to get quite long with many different datasets and models. A button “Notebook explorer” on the top right of a notebook will display a list of all data sets and models present in the notebook. This list also enables the end-user to follow the workflow of the notebook and see how and when each data set and model was created, transformed, and used. For each data set or model, there is a list of the steps where it is used in the notebook.

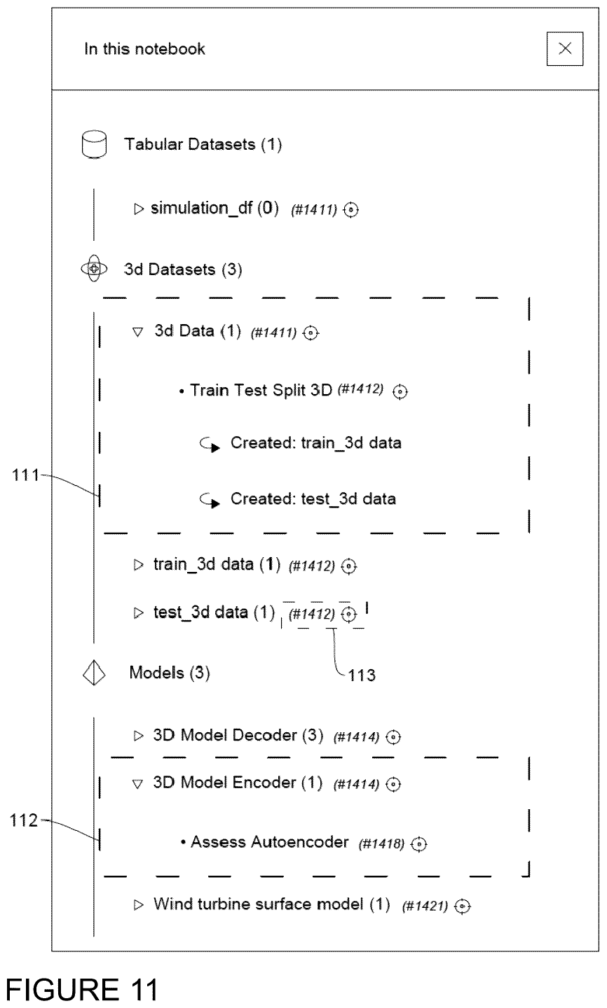

FIG. 11 shows an example of list of steps used in a notebook. Region 111 shows that the “3d data” was only used in the train test split 3D to generate train and test data. Region 112 shows that the encoder was used to assess the auto-encoder. The link at the end of any line (for example 113) can also be clicked to directly access the relevant step in the notebook. This may also slightly change a link or URL of the notebook, which means that if a new link or URL is shared with someone else, they would be brought directly to this step within the notebook.

Buttons are also included to minimise/expand all steps in a notebook at once, and to open notebooks in ‘Safe Mode’ (with all steps minimised).

Distributed data processing is also implemented to speed up operations on large datasets such as datasets containing millions of rows. Both the speed at which the user options appear after selecting data in a manipulator, and the speed of the actual manipulation steps are therefore increased.

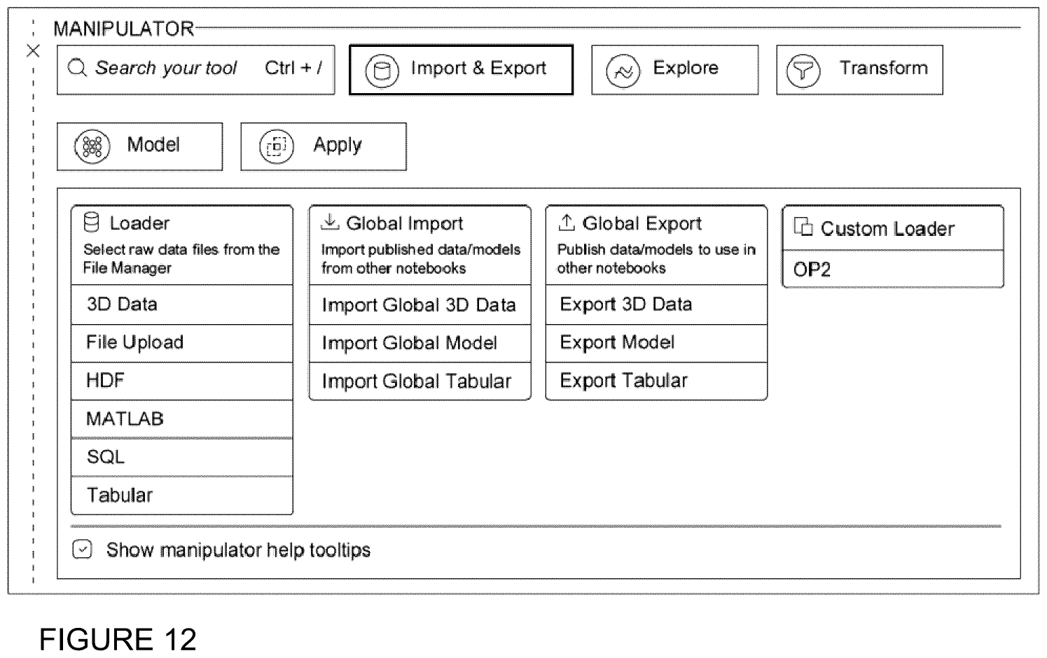

Several use case examples are now provided. FIGS. 12 to 23 show a typical workflow of a notebook in which data is first imported and then used to train a machine learning model or system. Finally, predictions are made, and results are shared. In this example, the original dataset or input data used contains results from Computational Fluid Dynamics (CFD) simulations of spoiler designs for a race car.

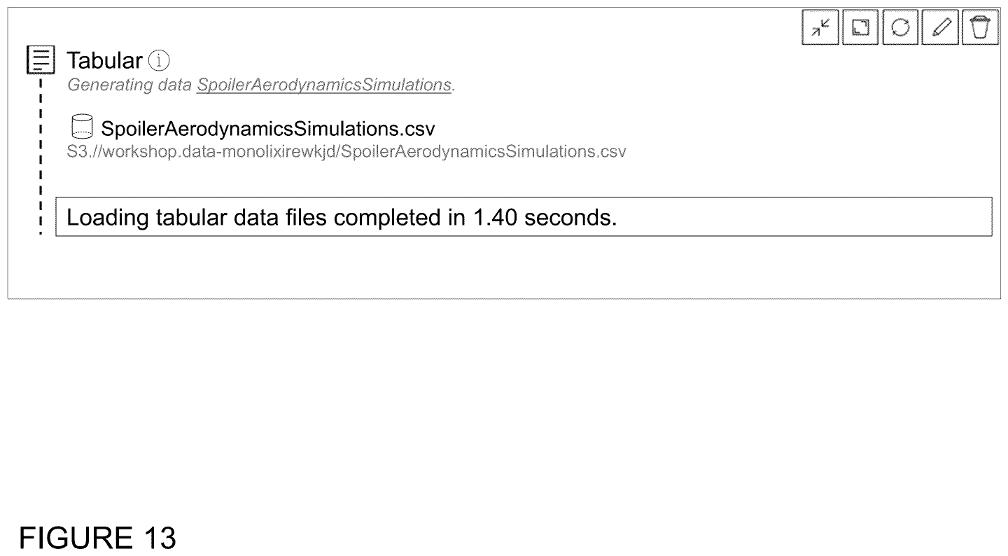

As shown in FIG. 12, an end-user may click on the ‘Import & Export’ manipulator. The end-user may then click on tabular data, select a dataset, and click apply. Multiple datasets may also be selected and exported. FIG. 13 shows the notebook style interface displaying the tabular step including any useful metadata associated with this step.

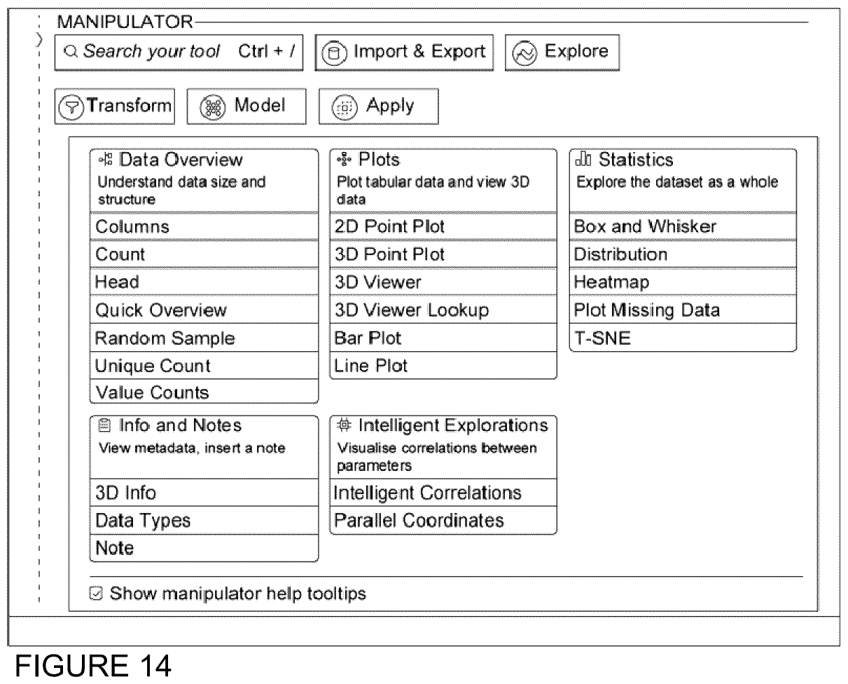

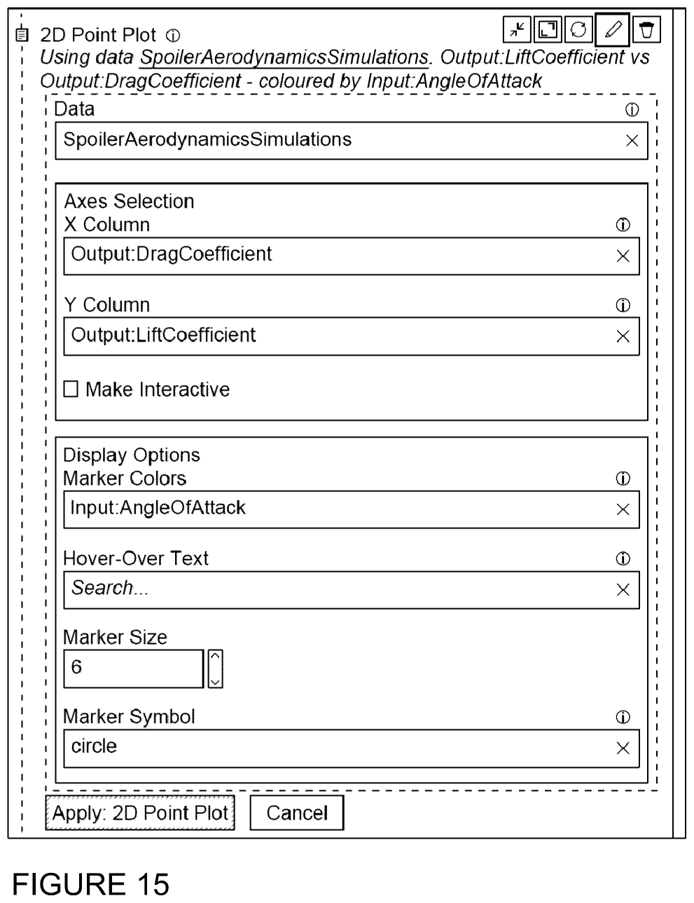

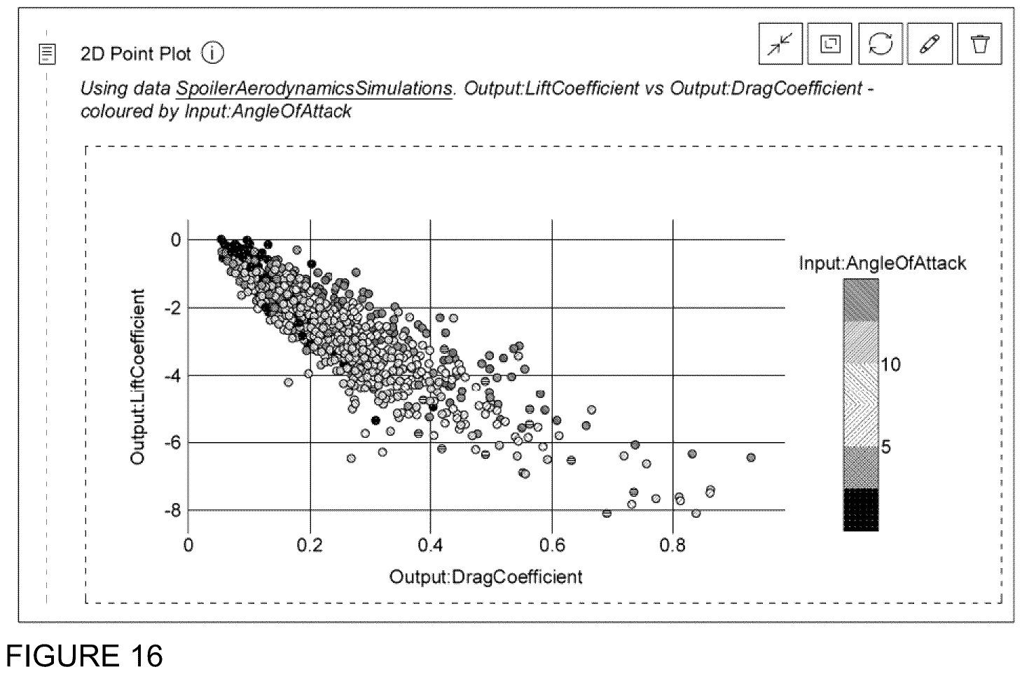

The end-user clicks on the ‘Explore’ manipulator and the ‘Explore’ features are then displayed as shown in FIG. 14. In this example, the end-user selects ‘2D Point plot’. The end-user then selects the axes and the display options using one or more variables from the original dataset, as shown in FIG. 15. The end-user chooses ‘Output:DragCoefficient’ for the X column, ‘Output:LiftCoefficient’ for the Y column, and ‘Input:AngleOfAttack’ for the Marker colour, and clicks ‘Apply’. FIG. 16 shows the plot obtained. An ideal design would be in the bottom left of the plot, but the plot shows that there is a trade-off between the target variables, such as a good drag or a good lift.

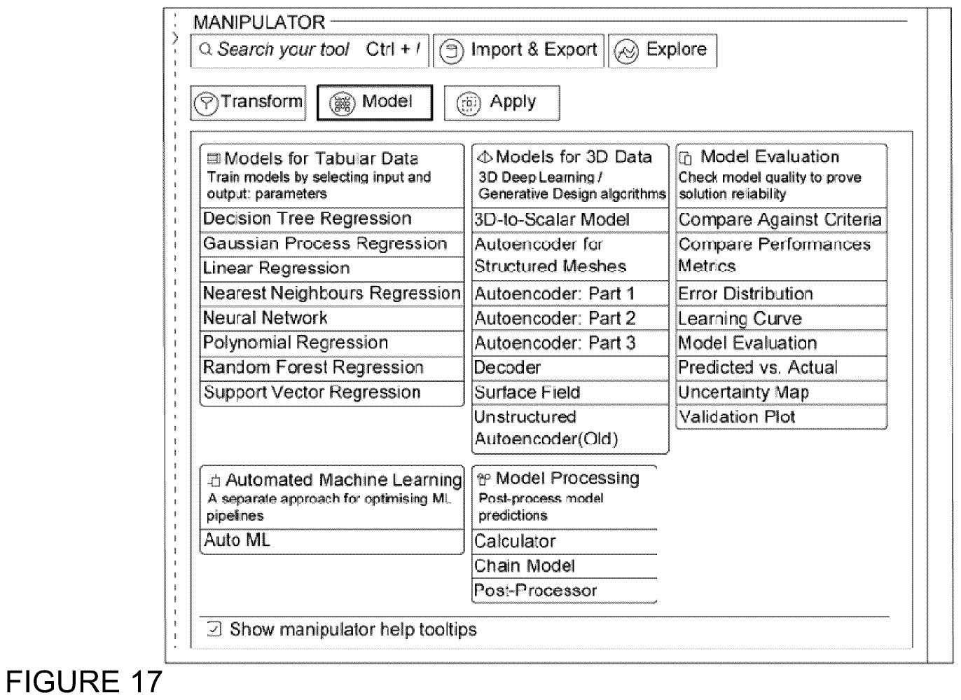

The end-user clicks on the ‘Model’ manipulator and the ‘Model’ features are then displayed as shown in FIG. 17. In this example, the end-user selects ‘Neural Network’. Training a model means building a mathematical model which will be able to correlate the simulation inputs to its outputs. As with all AI models, a dataset must be selected to train the model. Then the Input and Output columns should be selected for the model to learn.

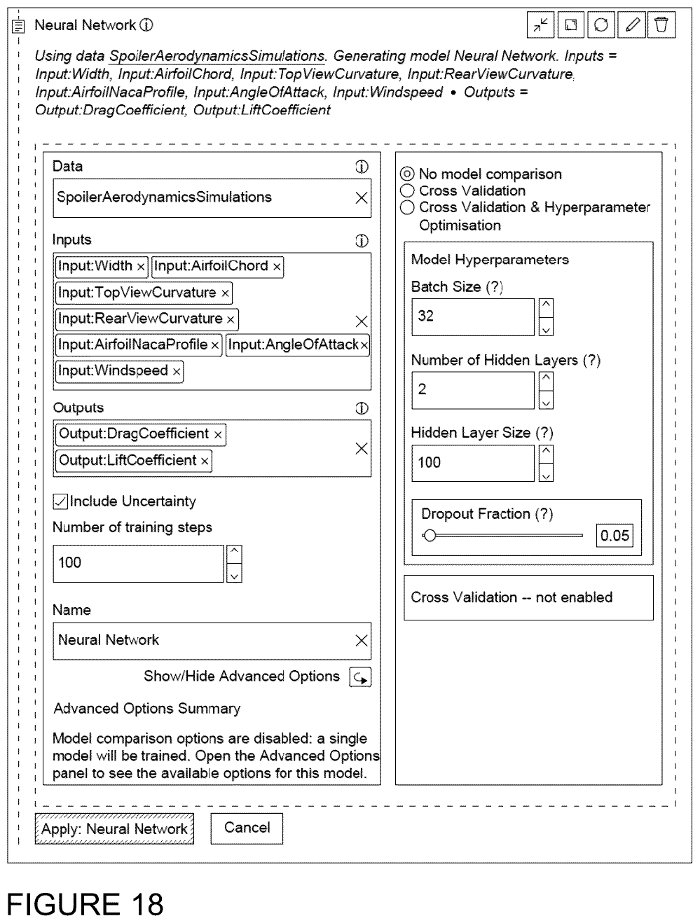

The end-user then selects all the input parameters in the ‘Inputs’ dropdown menu, then selects both output parameters in the ‘Outputs’ fields, ticks the ‘Include Uncertainty’ checkbox, and clicks ‘Apply’ as shown in FIG. 18. Several advanced options can also be selected or updated.

Machine learning models include many parameters that the end-user can use to tune the prediction performance of a model. Sensible default choices for all these parameters are automatically selected, so the end-user can just press Apply and train a model immediately. Alternatively, the end-user may also configure any parameters related to the machine learning system or model.

As an example, several Neural Network parameters may also be either user-configurable or automatically determined by the platform:
Number of Hidden Layers & Hidden Layer Size: One important choice is the shape of the network. The neurons in a Neural Network are arranged in a series of layers known as “hidden layers”. The number and the size of these hidden layers may be easily configurable by an end-user. Both choices affect the model performance: a model with more layers (or larger layers) will be able to fit complex relationships but is more liable to overfitting. A model with fewer layers (or smaller layers) will only be able to capture simpler relationships but is less prone to overfitting. In general, finding the best choice is a balance between these two extremes (underfitting and overfitting). Advantageously, the platform is configured such that multiple machine learning models can be trained and compared with different architectures, and the performance both on training data and on unseen testing data is determined and displayed to an end-user.
Number of training steps: Another important choice is how many training steps to use. Using more training steps will make the model fit more closely to the training data. It is usually a good thing to make the model predictions match the training data more closely. However, if a model is trained for too many steps then the training data can be overfitted. Overfitting means that the model makes good predictions for training data, but worse predictions for unseen data. The platform may be configured to automatically determine an optimum number of training steps. Further loss history curves may also be determined and displayed to enable an end-user to decide how many training steps to use.
Batch Size: Neural Networks look at the data in chunks or ‘batches’. The number of rows in each batch (‘Batch Size’) can affect how quickly the model trains and can also affect the final performance.
Dropout Fraction: This parameter can be used to control the randomness in the network. A higher dropout fraction increases the randomness in the model, by randomly turning off (‘dropping out’) some fraction of the neurons in each training step. Higher dropout fraction can help reduce the chance of overfitting (through a process known as ‘regularization’), but it can mean that the model will require more training steps to learn to fit the data.
Uncertainty: Neural Networks can provide uncertainty estimates along with their predictions. This may only be possible if the Dropout Fraction has a non-zero value.

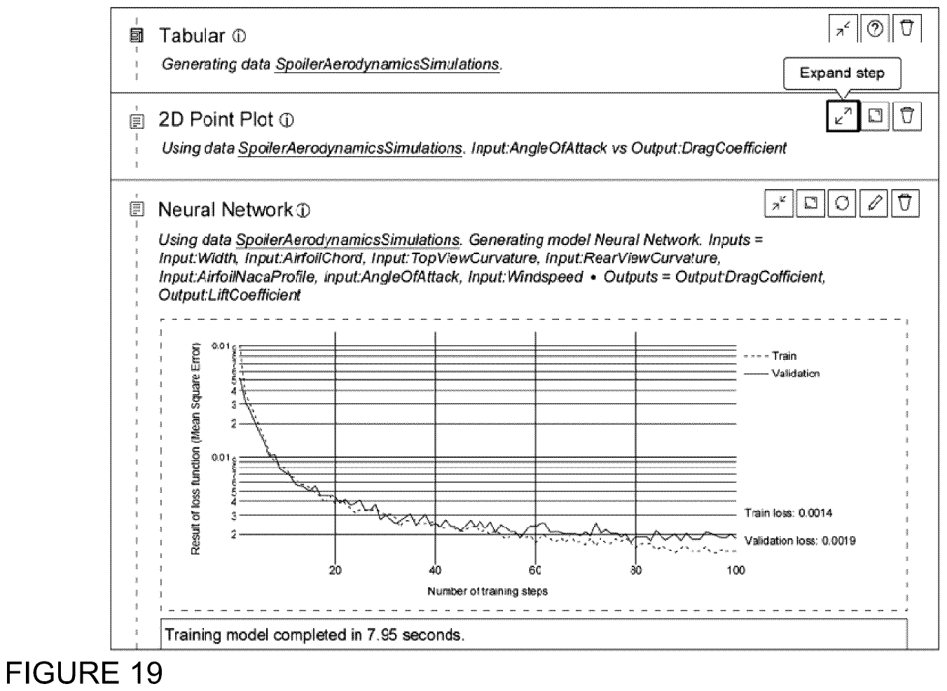

When all the parameters are entered or selected, a plot is then provided with the result of loss function as a function of the number of training steps, as shown in FIG. 19.

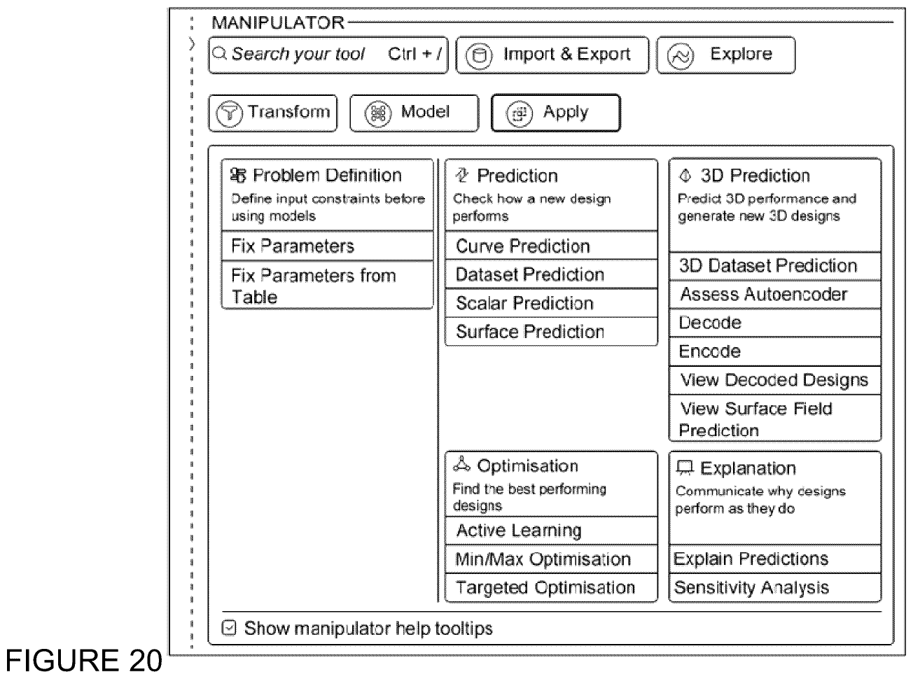

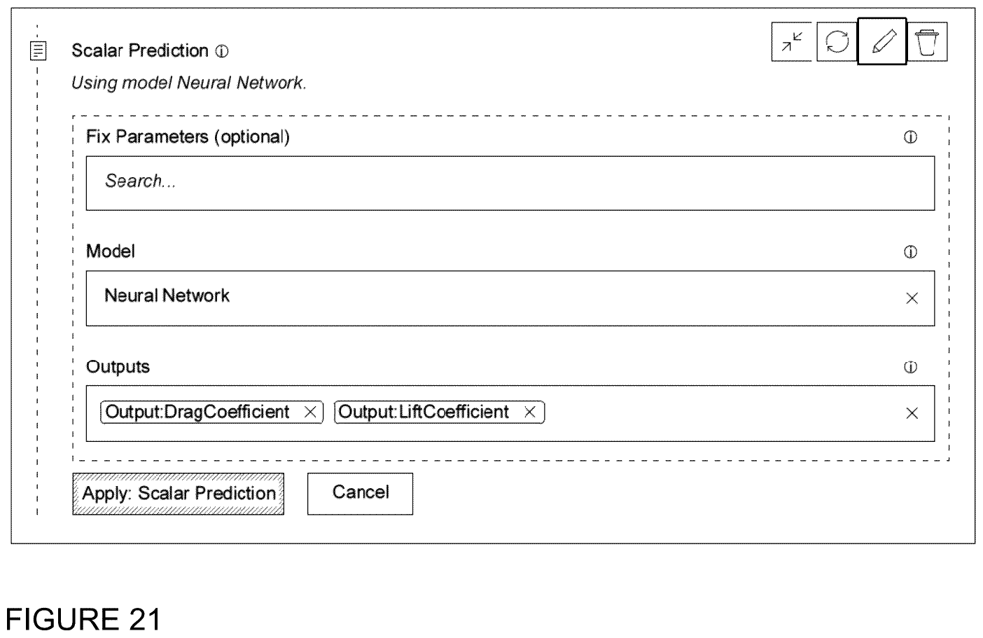

The end-user clicks on the ‘Apply’ manipulator and the ‘Apply’ features are then displayed as shown in FIG. 20. In this example, the end user selects ‘Scalar Prediction’. The end-user then chooses ‘DragCoefficient’ and ‘LiftCoefficient’ for the outputs, and clicks ‘Apply’, as shown in FIG. 21.

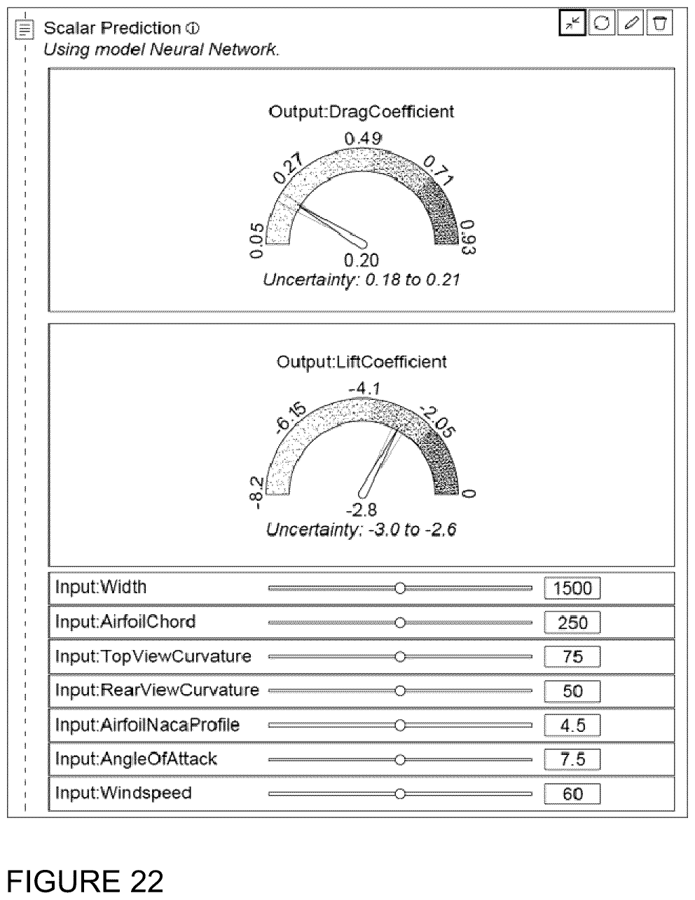

FIG. 22 shows the results of the scalar prediction using the neural network model previously applied, in which the predictions of the outputs are instantly displayed for a new selection of input parameters. Sliders are provided to change any of the input parameters. The range of the input sliders is defined by the min and max values of the inputs in the training set of the model. Each time an input value is modified, the output value changes accordingly. As the model used for the prediction was trained with the option to predict uncertainty, a shaded range around the dial that indicates the uncertainty of the prediction is provided. This is because some predictions are more uncertain than others, and this can help the end-user when making decisions. Hence, the performance of a new design tested under new conditions can instantly be predicted, rather than waiting for hours of re-design, simulation, post processing to complete.

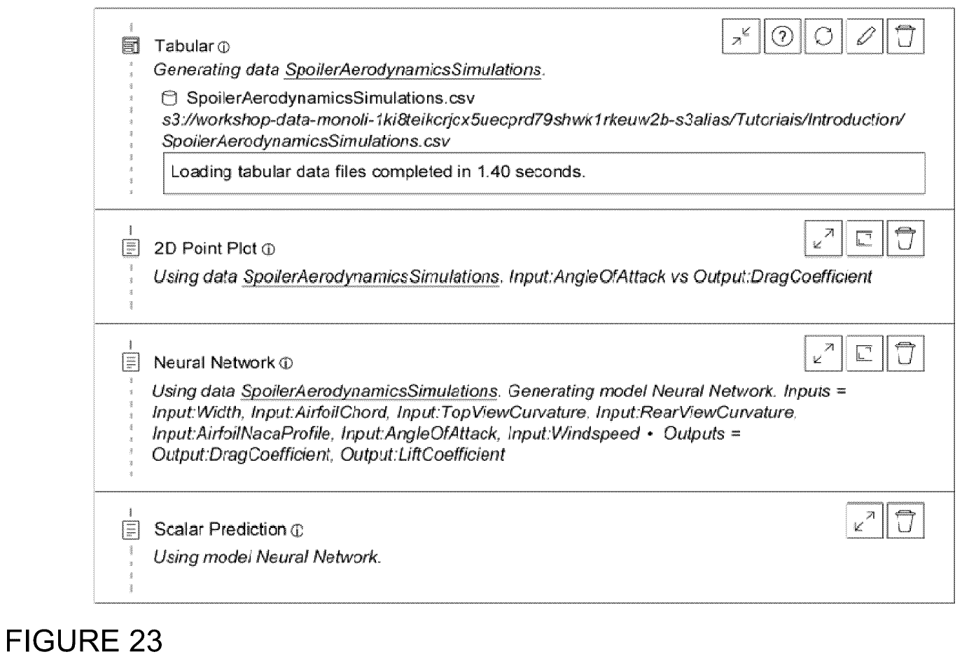

FIG. 23 displays the notebook style interface with the steps or queries previously applied in this example, namely ‘Tabular’, ‘2D Point Plot’, ‘Neural Network’ and ‘Scalar Prediction’.

Each of the steps in the notebook can be edited or updated. The end-user can also easily re-order the steps in the notebook by dragging and dropping any of the step within the notebook style interface. Any subsequent steps will then automatically re-run based on the previously edited step. The results may also easily be shared by clicking on ‘Generate New Dashboard’ button.

The following figures show another example in which the dataset contains results from CFD simulations of spoiler design for a race car. Many design parameters may affect the aerodynamic performance of spoiler designs, such as their position, shape, and size, as well as the operating conditions in which they are tested, such as the sped of the incoming wind.

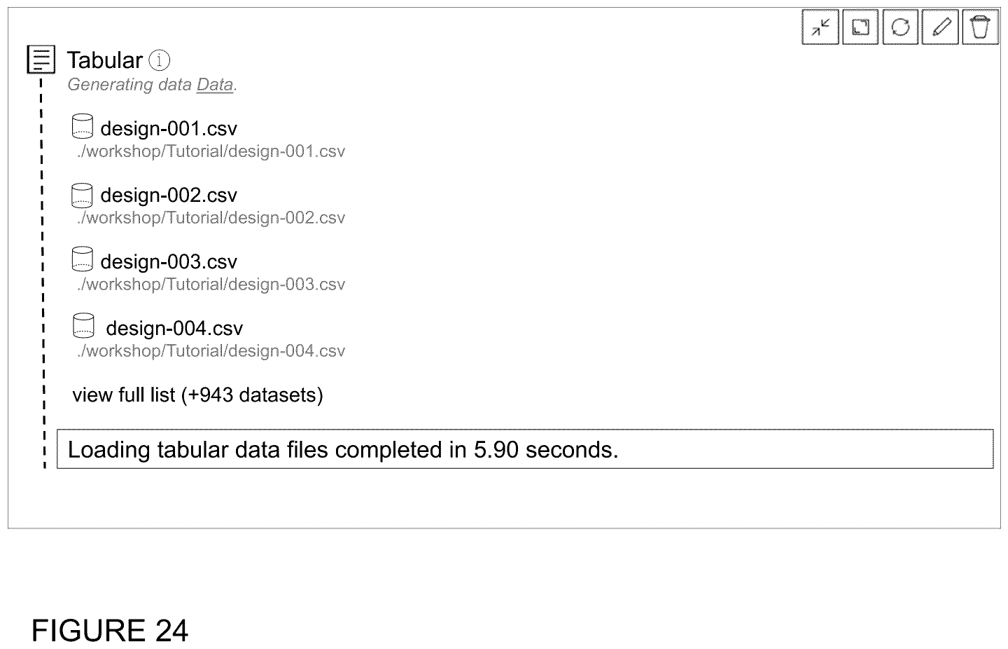

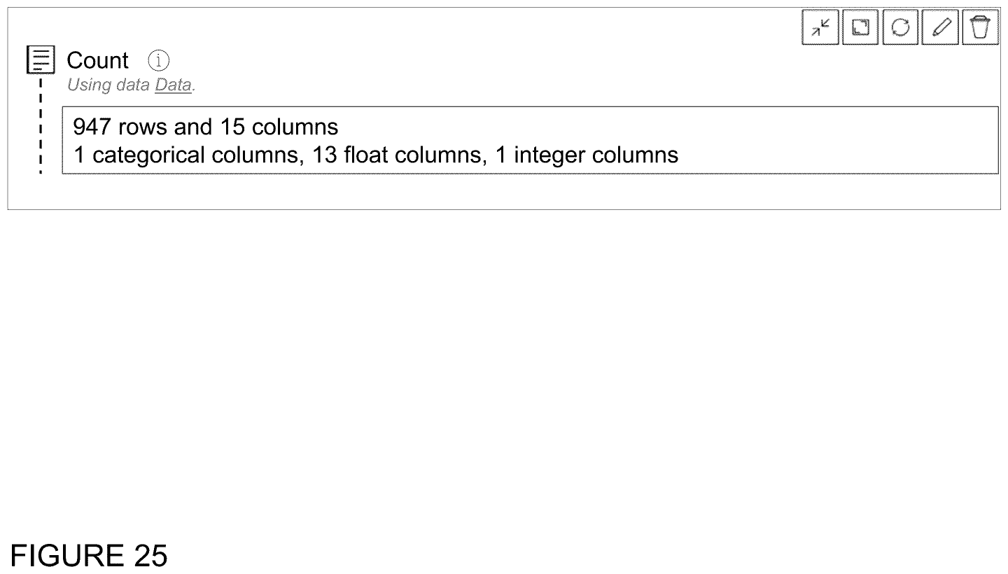

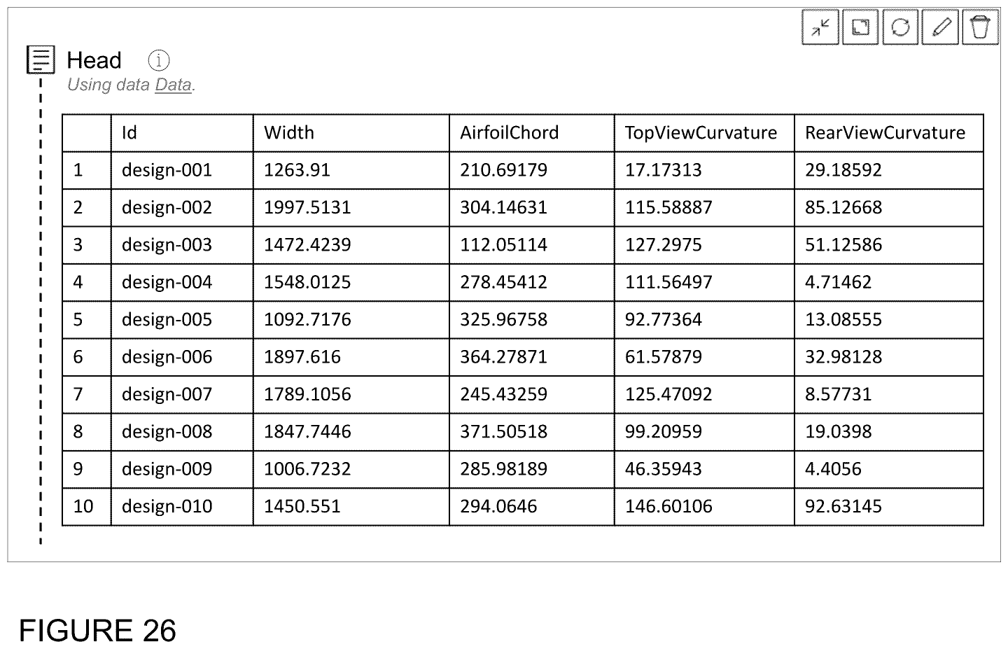

As shown in the notebook provided in FIG. 24, tabular data is selected, and several .csv files are selected as a first step. The platform provides a feature for sanity checking that the data imported is in order. The Explore→Count step helps check the size of the data as (FIG. 25) and Explore→Head (leaving the Columns selection field blank) will display the first few rows of the entire table (FIG. 26). Each CSV file imported contains one row which corresponds to the results of one CFD simulation. The import process consolidated this data into one table. Each column represents a simulation parameter. DragCoefficient and LiftCoefficient are the most significant simulation results (design performance metrics). yPlus is another output—a dimensionless value indicating the amount of turbulence in the simulation. The other parameters are inputs: geometric properties such as AngleOfAttack, and Windspeed which is an operating condition.

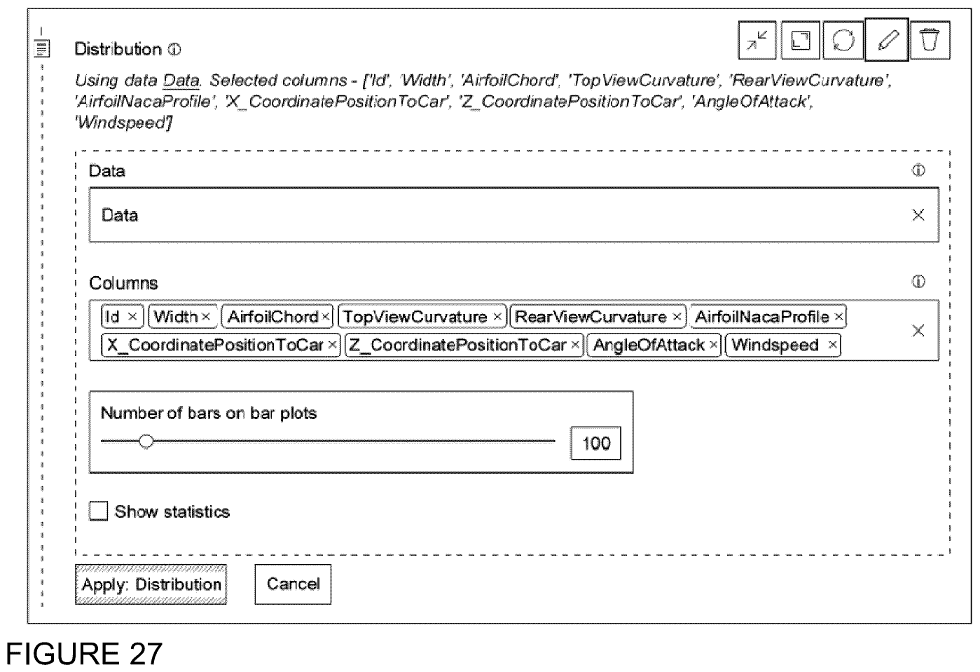

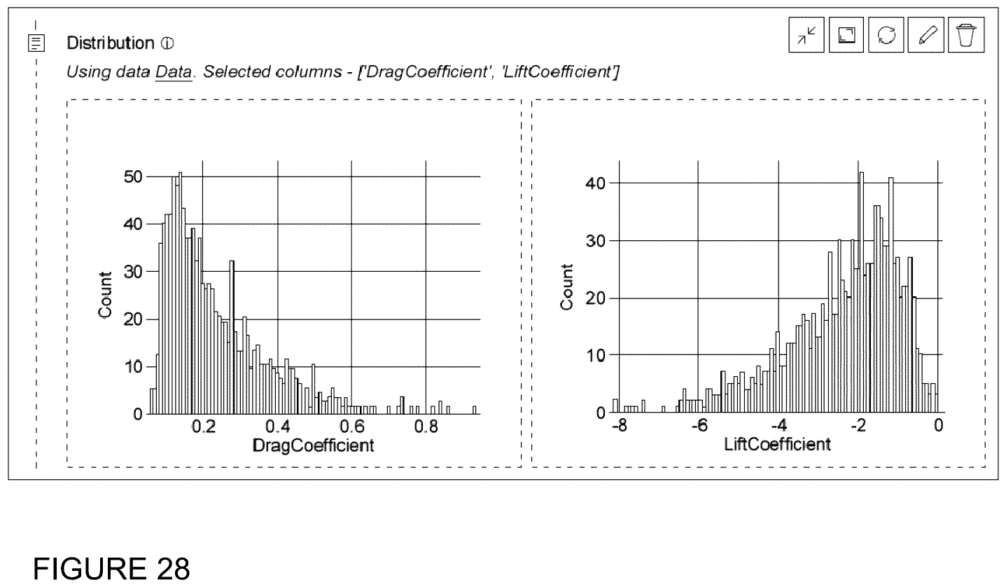

As shown in FIG. 27, to inspect the distribution of data, use ‘Explore→Distribution’, and select all columns. The distribution of categorical variables (Id column) is displayed as a table, whilst numerical variables are displayed with histograms. The distribution of ‘DragCoeffectient’ and ‘LiftCoefficient’ is displayed in FIG. 28.

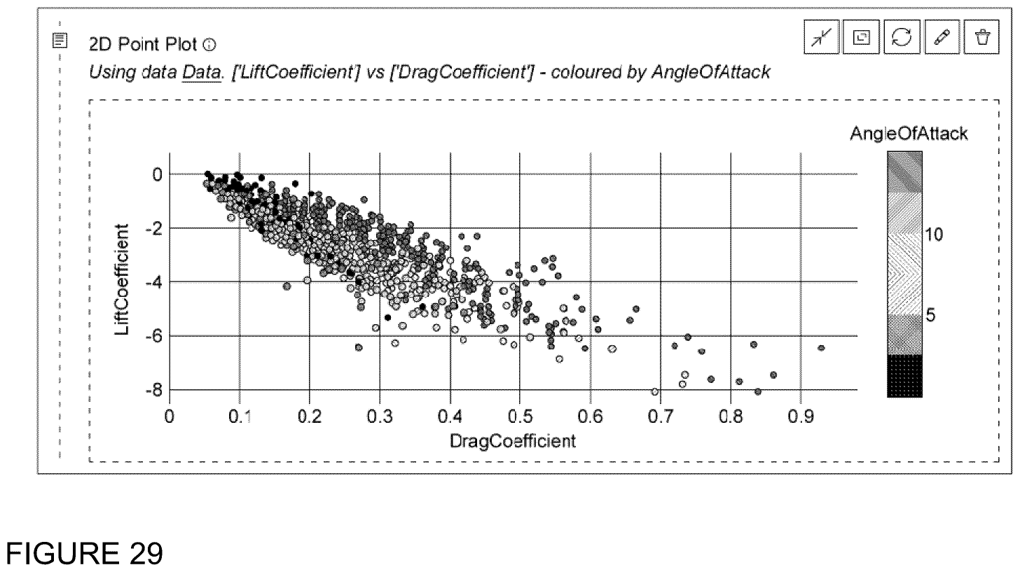

FIG. 29 provides a 2D point plot to take a closer look at performance trade-off of spoiler designs. As can be deduced from the plot, Lift and Drag seems correlated, in the sense that designs with good drag tends to have bad downforce, and vice versa. An ideal spoiler would then be located somewhere at the bottom left of the plot.

The platform enables an end-user to visualise correlations between parameters, using for example the ‘Intelligent Correlations’ or ‘Parallel Coordinates’ features of the ‘Explore’ manipulator.

The Intelligent Correlation tool gives a summary of the simple one-to-one relationships between pairs of variables in a data set. The tool takes the datapoints for a pair of variables and finds the best linear, power law or exponential line of best fit. This is a powerful tool to quickly get a snapshot of the relationship between two parameters, to provide with insight on the relationships present in the data.

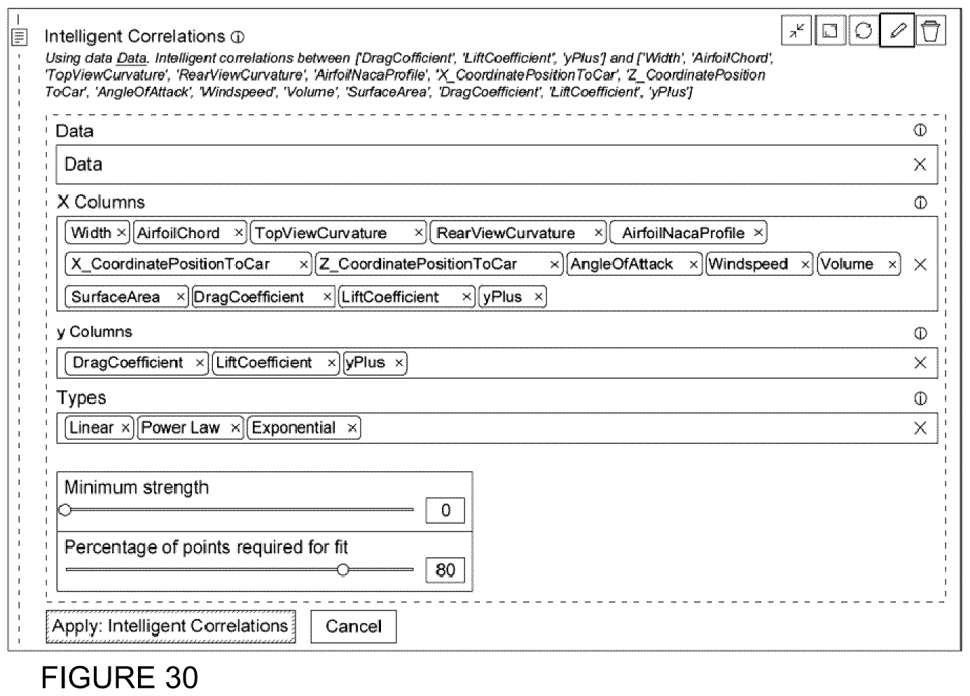

As shown in the example provided in FIG. 30, all parameters are selected in the X Columns field and the simulation outputs are selected for the Y Columns (DragCoefficient, LiftCoefficient and yPlus).

Other options may include:
Types: what types of relationships should be checked for between the variables. Choices may be for example: Linear, Power Law and Exponential.
Minimum strength: the minimum correlation strength to plot. This can be adjusted to visualise only the significant relationships in the data.
Percentage of points required for fit—anomalies or areas of abnormality in the data may impact the quality of the lines of best fit found between pairs of variables. To reduce this impact and still visualise the trend in the rest of the data, the percentage of points needed to be used can be adjusted when calculating the lines of best fit.

When working with a big dataset of numerous variables, the intelligent correlation tool provides a useful starting point for selecting the input variables that are likely to influence outputs and reducing the size of the design space. It could also be used to identify which input variables are dependent on each other and could therefore be redundant to include. The drawback of this tool is that it is only looking for one-to-one relationships so it may miss a multivariate interaction that would be important for including in a Machine Learning model.

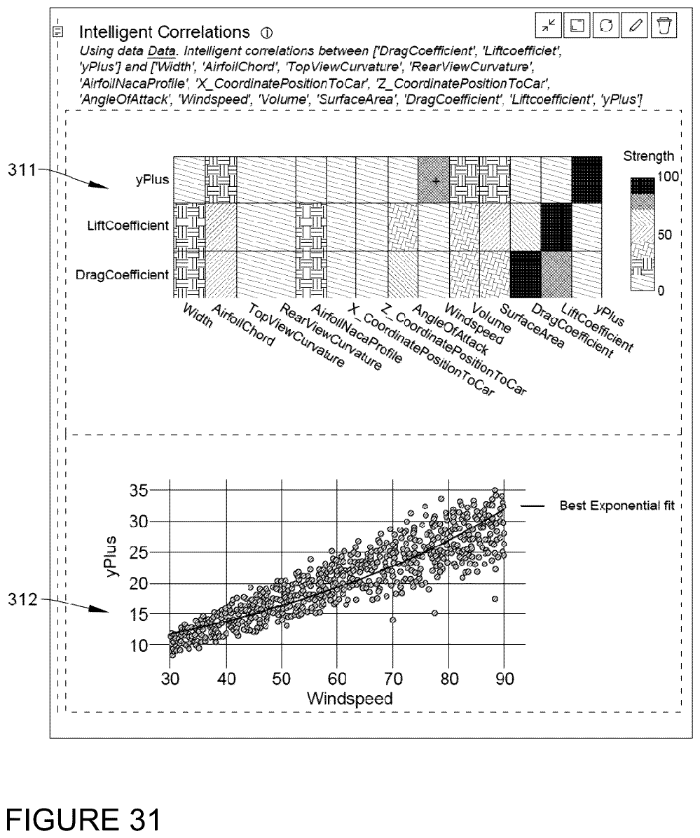

FIG. 31 provides the output of the intelligent correlations step 311: a heat map with the colour intensity representing the strength of correlation for the strongest relationship found between any pair of variables. Each pair of parameters is given a strength factor: the higher it is, the stronger the correlation (linear, exponential, . . . ) between the two parameters.

Once the step has finished, the end-user can also interact with the heatmap by hovering and/or clicking on a single square, and a scatterplot with the associated line of best fit will appear below the heatmap for the two variables that are represented when the end-user clicks on a square.

Hovering over each box will indicate the nature of this correlation and clicking on each box will plot it. A plot of yPlus as a function of windspeed is provided 312 by clicking on the box linking Windspeed and yPlus. A strong correlation between these two parameters can be noticed, this is explained because yPlus is a measure of how much turbulence is present in the simulation (which is more likely with high windspeed).

Sometimes, the complexity of a data set makes it hard to really understand it. The Monolith platform is therefore configured to enable an end-user to quickly understand the relationships between multiple different variables, such as 5 or 10 different variables, using a parallel coordinates plot.

The parallel coordinates plot enables to visualise data in a very intuitive way. Moreover, the interactivity enables an end-user to select specific regions for each variable. This function may be used for example to find non-trivial relationship in a data set, and to filter data in an interactive way.

Parallel coordinates plots are an interactive way to display the data of a table where each row is represented by a line taking different values on multiple parallel axes. A colour scheme may be applied for further clarity.

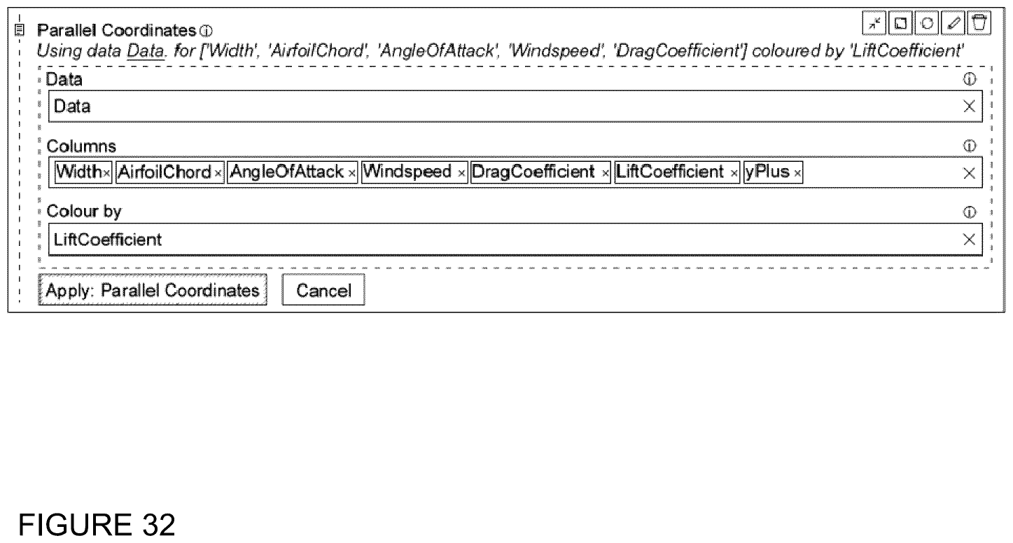

As shown in FIG. 32, the desired table is selected in the “Data” field and numerical columns from this table are then selected in the “Columns” field. It is also possible to colour the lines by one of the numerical columns to get extra information in the final plot.

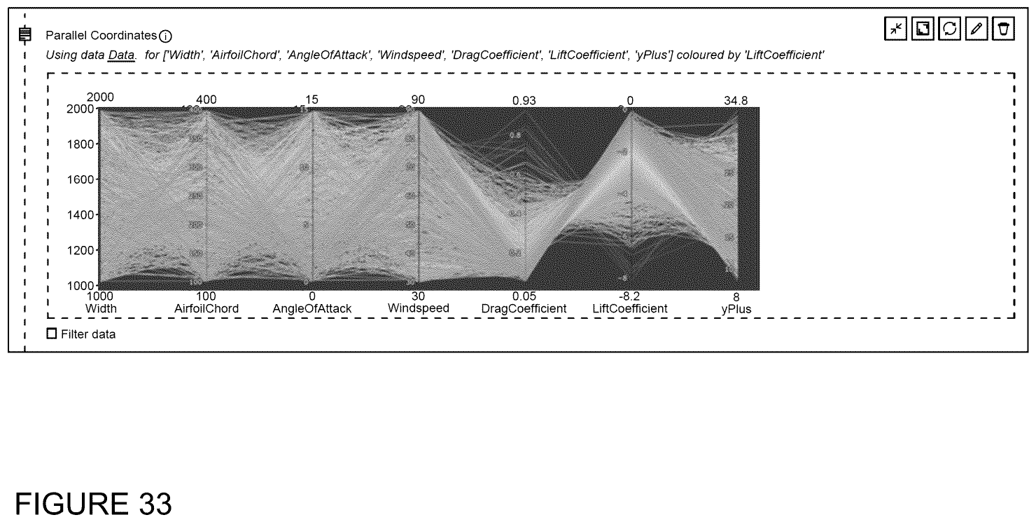

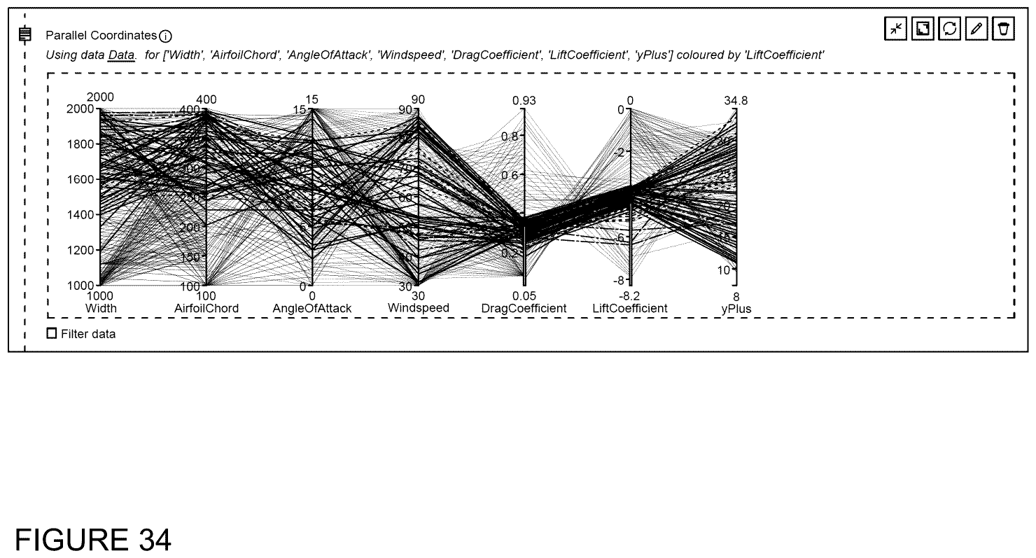

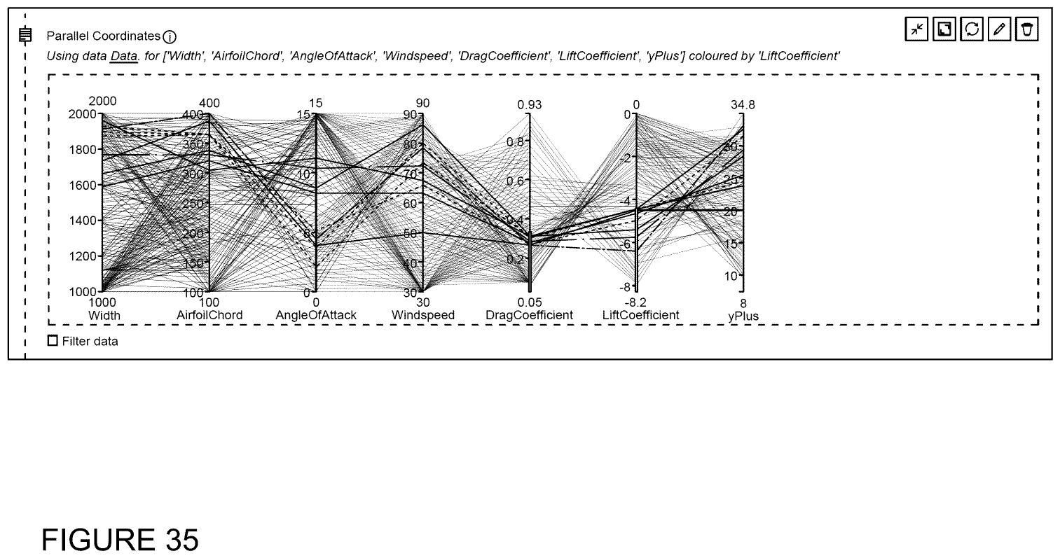

FIG. 33 shows the output displayed. Each line represents a row from the table. On the left figure, all lines are shown. It is possible to filter lines along an axis by clicking and dragging a line along this axis, as shown in FIGS. 34 and 35. These ranges can be moved along the axis or resized by clicking and dragging within the range or on its extremities. It is also possible to create multiple ranges along the same axis.

For each row in the data, a line will be plotted which displays each selected column on vertical axes. An end-user may interact with the vertical axes to filter out data points, by selecting custom ranges for each parameter. As shown in FIGS. 34 and 35, by clicking and dragging along the DragCoefficient and a LiftCoefficient axes, a fewer number of simulations are selected. An insight which can be extracted from this simple manipulation is that the types of designs which are close to ideal (low drag and high downforce), tend to have high Width (2000 mm), high AirfoilChord (400 mm), and average AngleOfAttack (8 degrees).

The function can be used as an exploration tool, to visualise relationship, but the filtered data can be saved and reused later in the notebook, such as by ticking the box “Filter data” below the graph.

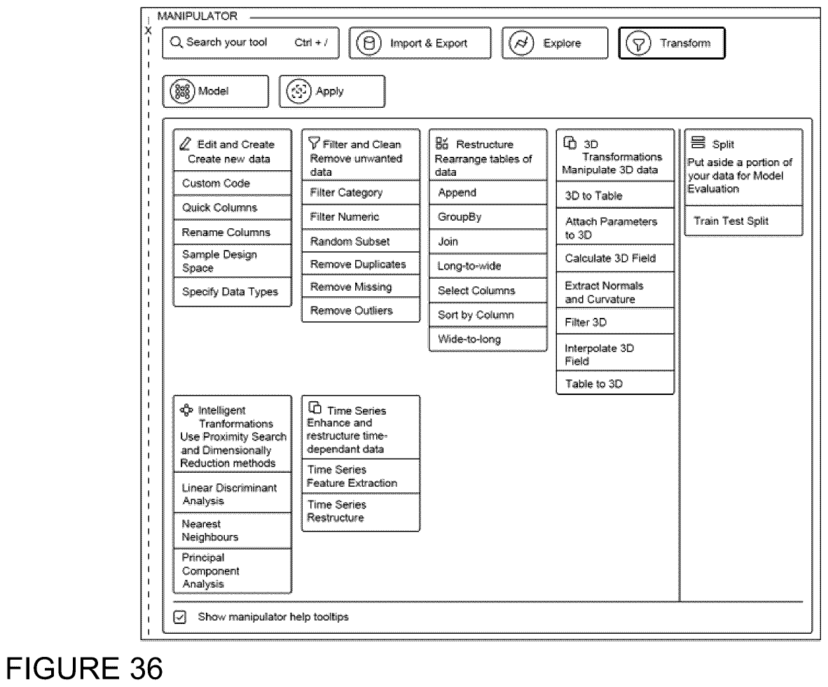

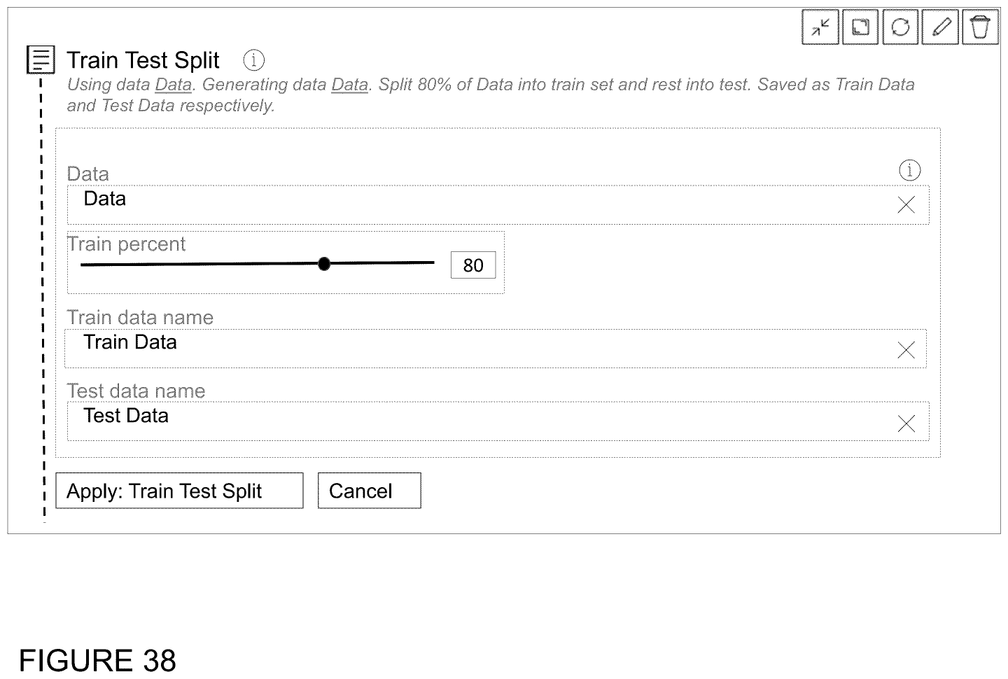

FIGS. 36 to 44 now provide the steps for building an AI model using as an example CFD simulations on spoiler designs for a race car.

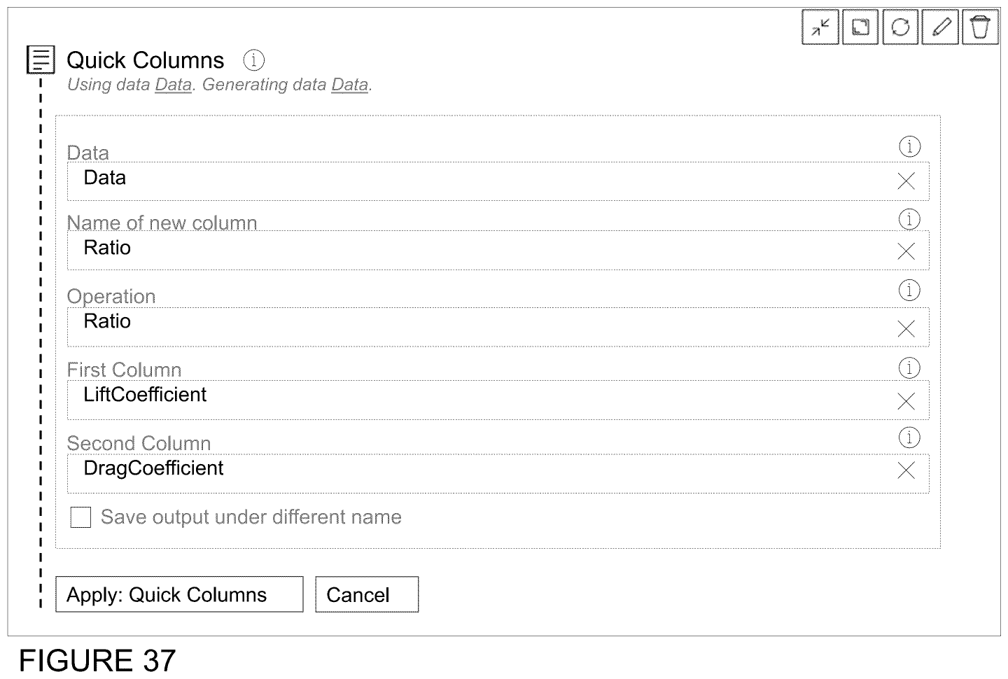

FIG. 36 shows the features of the ‘Transform’ manipulator. In order to get more insight into the trade-off which exists between downforce (negative LiftCoefficient) and drag (DragCoefficient), a new column (new parameter) is created which will be the ratio of the two using ‘Transform->quick Columns’ as shown in FIG. 37. Ratio is given as the new column name, and the operation is set to be the ratio of LiftCoefficient (first column) and DragCoefficient (second column).

An AI model may also be trained on a subset of the training data (such as about 80%) and the remaining 20% of the training data is used as validation data to evaluate the model's quality. As shown in FIG. 37, the feature ‘Transform->Train test split’ is used to split the data into two tables.

The neural network feature is now selected and configured by an end-user. Training Data, the inputs (Width, AirfoilChord, TopViewCurvature, RearViewCurvature, AirfoilNacaProfile, X_CoordinatePositionToCar, Z_CoordinatePositionToCar, AngleOfAttack and Windspeed) and the outputs (LiftCoefficient, DragCoefficient and Ratio) are also selected by the end-user. The number of training steps is chosen to be 200 and uncertainty is included to ensure that each prediction is accompanied by a measure of uncertainty.

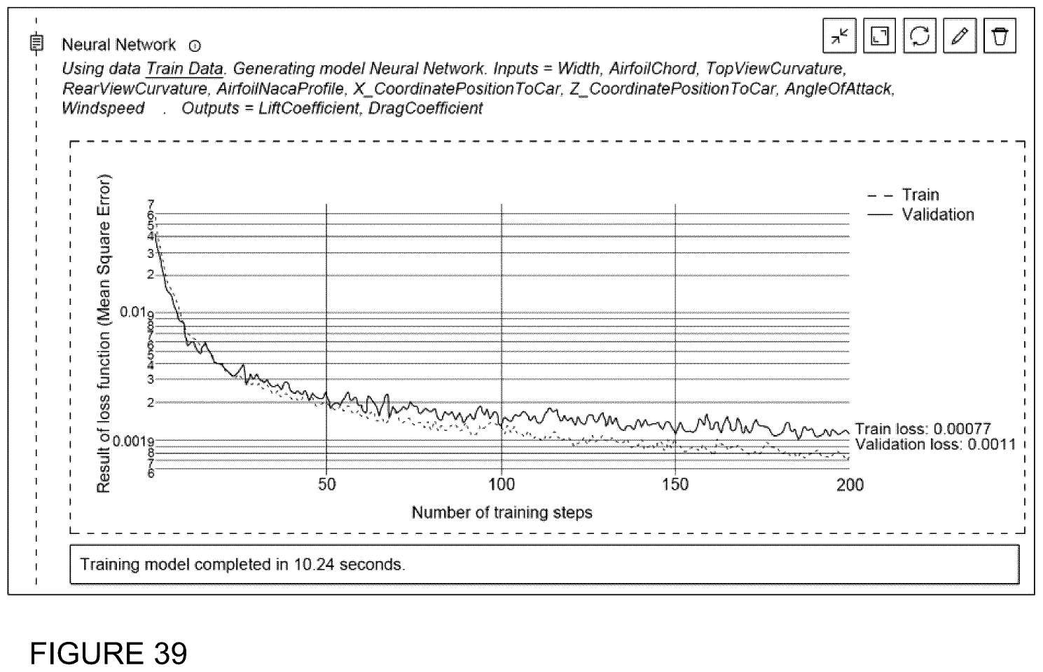

After the end-user clicks apply, a graph is displayed. The graph displayed is continuously updating as the Neural Network is being trained as shown in FIG. 39. MSE (Mean Square Error) is a scoring metric by which the model is iteratively refined with each new training step. Training deep learning models involves an internal Train-Validation split of the data, to ensure this iterative learning. Ideally, both loss curves should converge to a stable, single value. A Validation Loss far greater than the Training Loss indicates that the model is ‘overfitting’ to the training data.

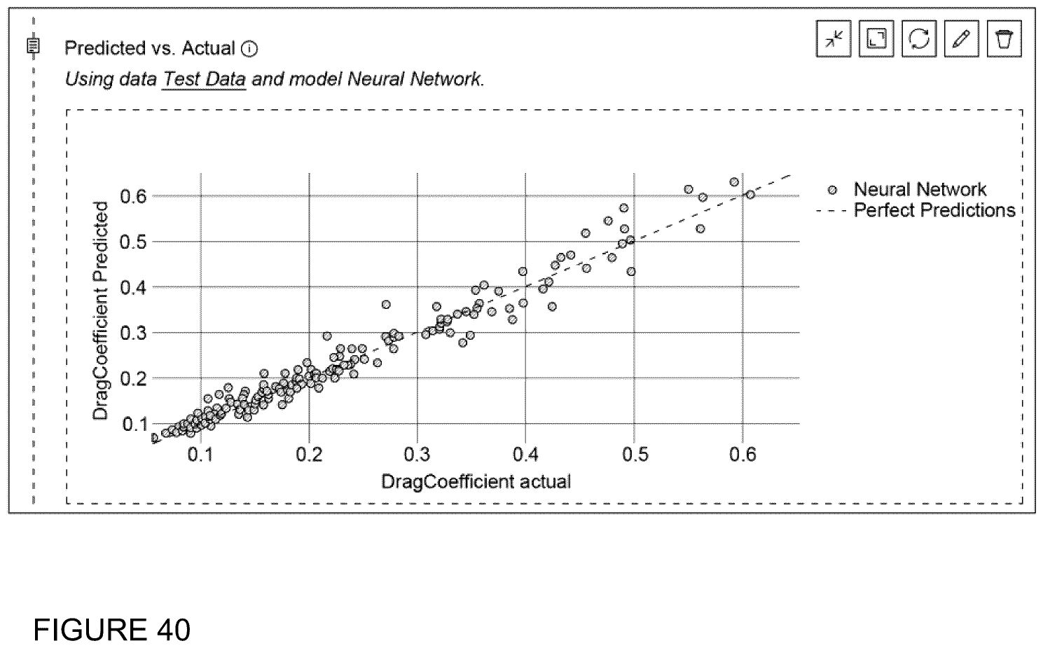

Once the model is trained, its quality/accuracy can be evaluated using the test data put aside as part of pre-processing. The end-user then selects the predicted vs. actual step of the model manipulator. Test data and DragCoefficient is selected as the output. This may be used to evaluate how a model is predicting unseen data. In this case, the model has high accuracy, as the points are closed to the perfect prediction line as shown in FIG. 40.

Another way to evaluate the model is to import data which is especially designed to validate predictions. Using ‘Import & Export→Tabular’, validation files can be uploaded as a new table. In this example, the validation data is a design sweep: AngleOfAttack is the only parameter changing between each simulation.

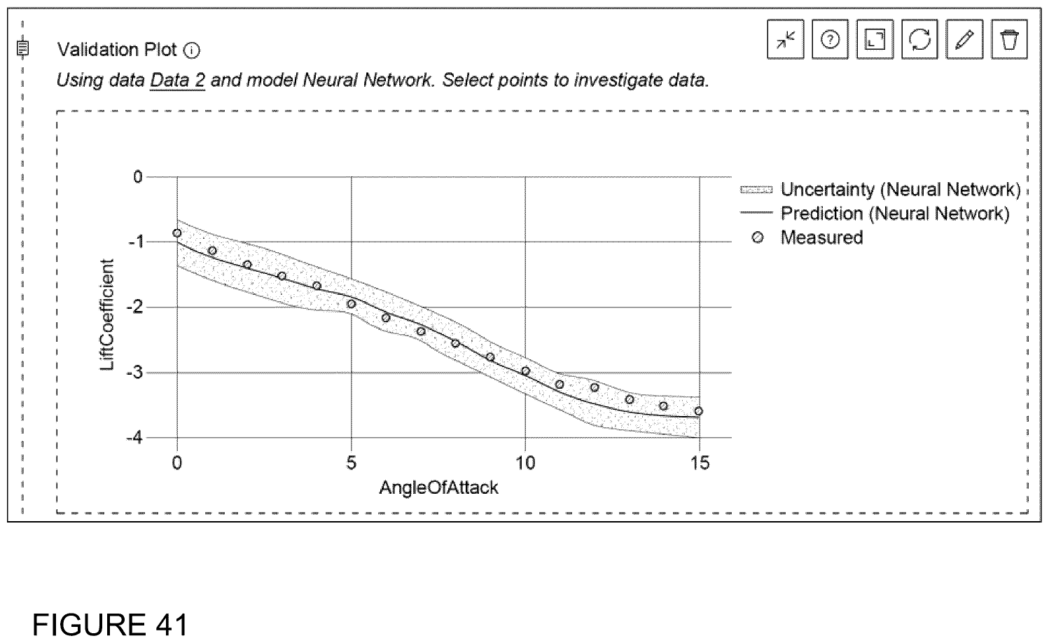

Using ‘Model->Validation Plot’, the validation data is selected for the test data, AngleOfAttack for the X-axis and LiftCoefficient for the yAxis. FIG. 41 provides the results which shows that the predictions are accurate. An important outcome of training the model is uncertainty quantification: There's a 95% probability that measured data will be contained within the uncertainty region. This helps an end-user knowing when the predictions can be trusted.

Advantageously, the platform provides an understanding of how data volumes affect the accuracy of machine learning models. In turns, this helps accelerate engineering development.

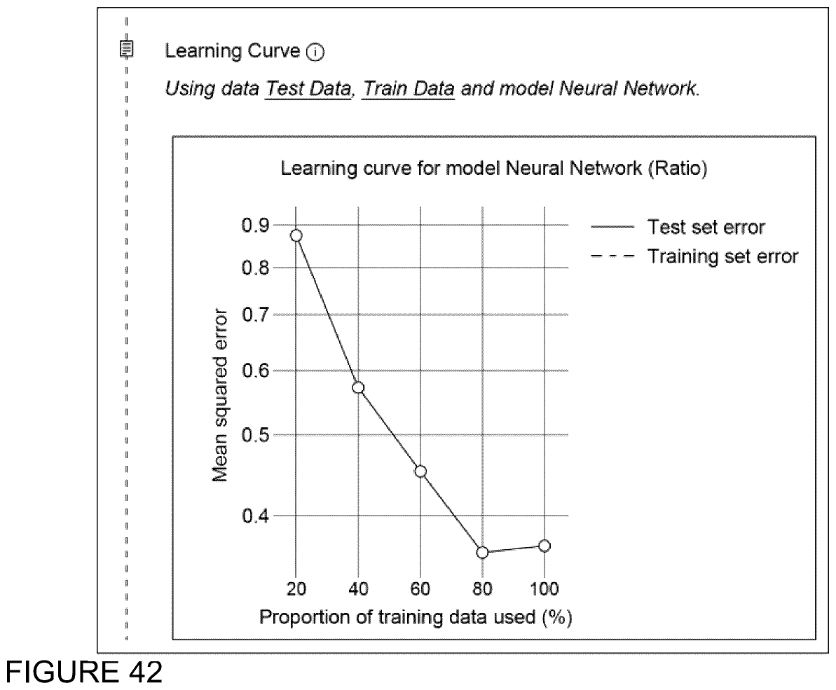

Within ‘Model->learning curve’, the end-user selects the training and test datasets which were generated earlier by the Train/Test split feature. Multiple Neural Network models may be retrained using subsets of the training data and evaluated against test data. In this case, the Neural Network is twice as accurate when trained on 80% of the data as compared to 20% of it, as shown in FIG. 42.

Advantageously, this provides a helpful tool for an end-user to understand how much more data is needed to reach a specific accuracy.

Additionally, an end-user may also want to understand the accuracy required to make a particular model useful. This may largely depend on a specific use case or downstream application. The platform may therefore predict the performance of a 3D object across multiple areas based on a specific downstream application. For example, at the concept stage of engineering, a model with relatively low accuracy might suffice. When working towards the production/manufacturing stage of engineering and the end-goal is optimisation, higher accuracy will be required.

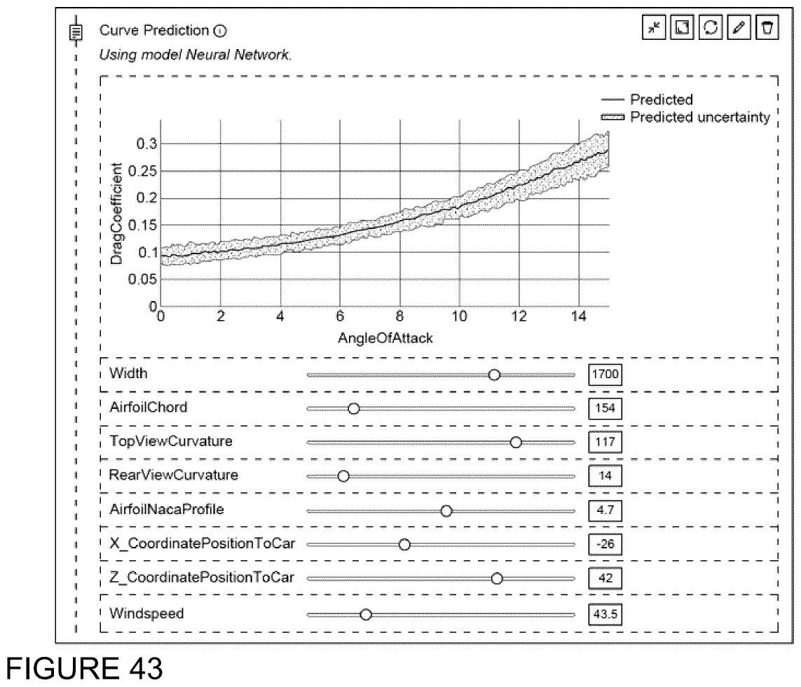

The end-user then selects ‘Curve Prediction’ as shown in FIG. 43. AngleOfAttack is selected as the input and DragCoefficient as the output. New design variables may be chosen or selected with sliders to make an instant assessment of spoiler performance. Each time an input value is modified, the curve value changes accordingly.

The results suggest that the uncertainty will be higher for higher values of AngleOfAttack. This makes physical sense since the flow around the spoiler will become more and more turbulent (and therefore harder to predict) as the angle of attack increases.

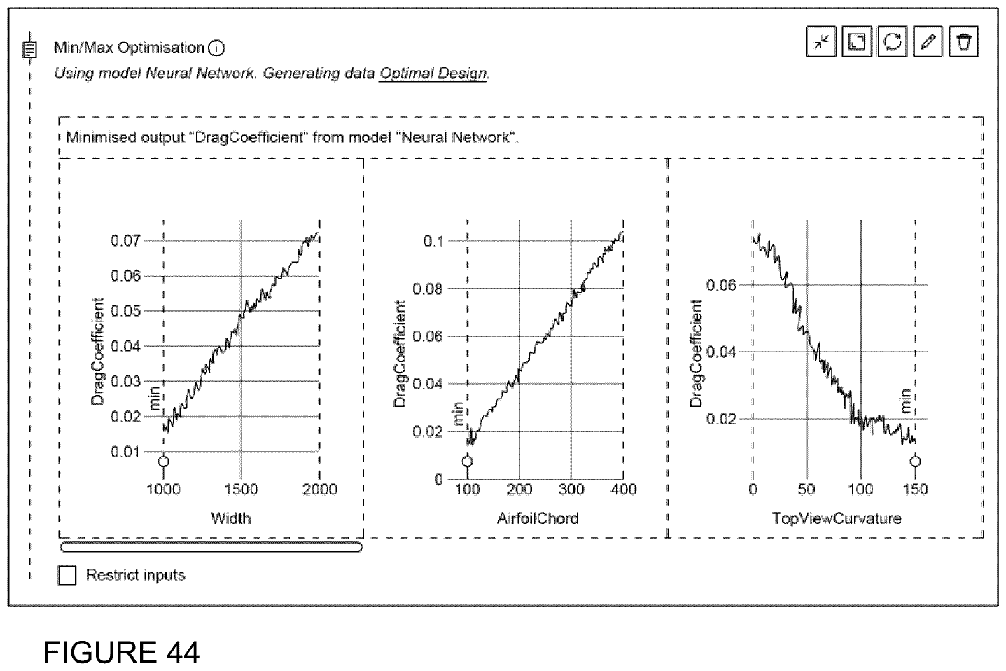

As well as giving predictions of performance for a new selection of designs, the platform is also capable of providing optimal designs for a selection of target variables or performance metrics. The end-user then selects ‘Apply->Min/Max Optimisation’ as shown in FIG. 44.

This algorithm will use the Neural Network model to search for the best Lift-to-Drag ratio and will return the set of design parameters corresponding to the most efficient spoiler wing. This tool may be used for quickly identifying the best possible combination of design parameters which satisfy a target variable or performance.

In flight, an aircraft will encounter gusts of wind of different types, which may provide turbulence. Hence the dynamic response of an aircraft to vertical positive gusts is now studied. One value which is a strong indicator of this response is the pitch angle (a). Variations in pitch angle over time will affect the forces applied by the air on the wings, which in turn will affect the stress distribution in the structure. It is therefore critical for aeronautical engineers to understand the variation of pitch angle over time for different aircraft configurations.

Building AI models is often an investigative process and evaluating the accuracy of models is an integral part of this process. The following examples are provided to show how to compare the quality of different AI models to identify the one which provides the best accuracy and most engineering insight for a specific use case.

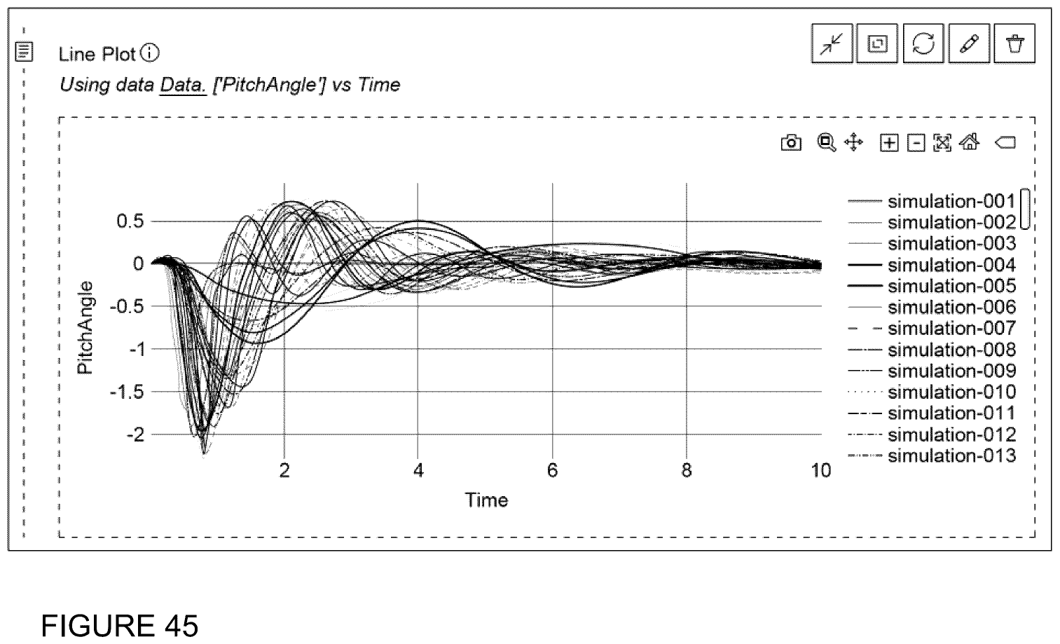

FIG. 45 shows the results of the step ‘Explore->Line plot’. The pitch angle is plotted as a function of time showing all the training data: 100 different dynamic responses to a gust, for different aircraft characteristics. The amplitude, frequency, and damping vary for each dynamic response. To further explore the data, the minimum pitch angle value for each simulation may be explored. First the end-user selects the ‘Transform->GroupBy’ step and computes the minimum value of pitch angle for each simulation.

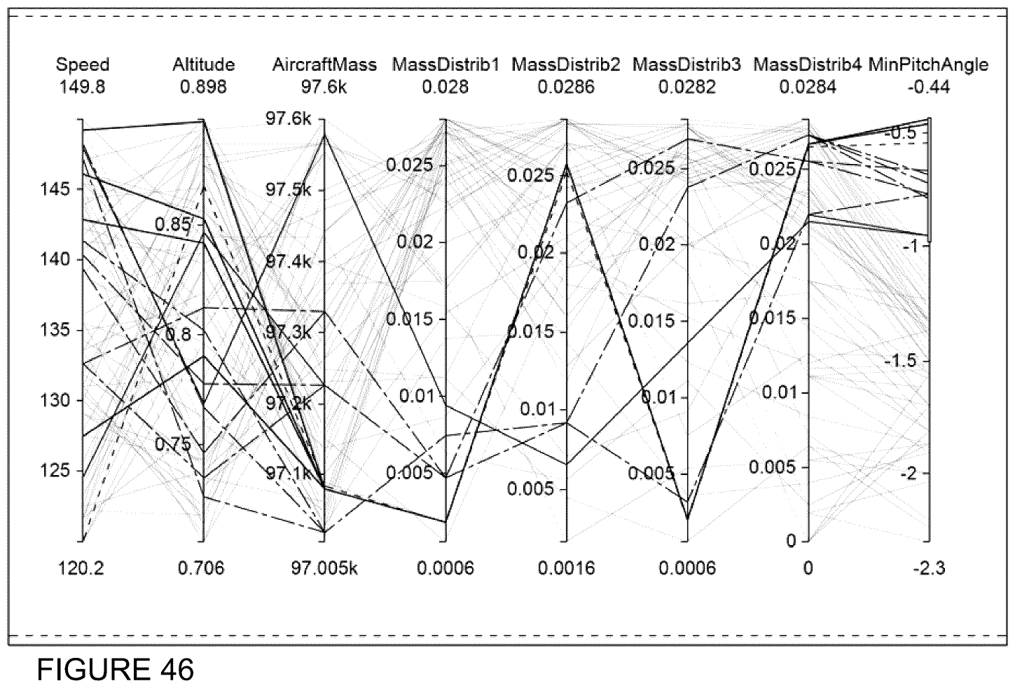

FIG. 46 provides the output of the ‘Explore→Parallel Coordinates’ for the newly created table. The data points plotted are the single lowest values of pitch angle over time for each simulation. Clicking on the pitch angle vertical axis enables the end-user to filter the pitch angle data. This highlights an interesting insight on the impact of the mass distribution of the aircraft on the dynamic response: low values of MassDistrib1 and high values of MassDistrib4 (which means most of the weight is concentrated towards the rear of the aircraft) tend to reduce the amplitude of pitch angle oscillations.

The platform also enables to train multiple models. We'll now compare different models to compare their accuracy. Three AI models are now trained: polynomial regression, random forest regression and neural network. The different models are then compared to decide on which one is the most suitable for a specific use case. A new validation data of a single simulation is exported. Using the same input variables as this validation data (same aircraft characteristics), we'll make predictions with the three different AI models to assess their ability to capture the physics from this new simulation.

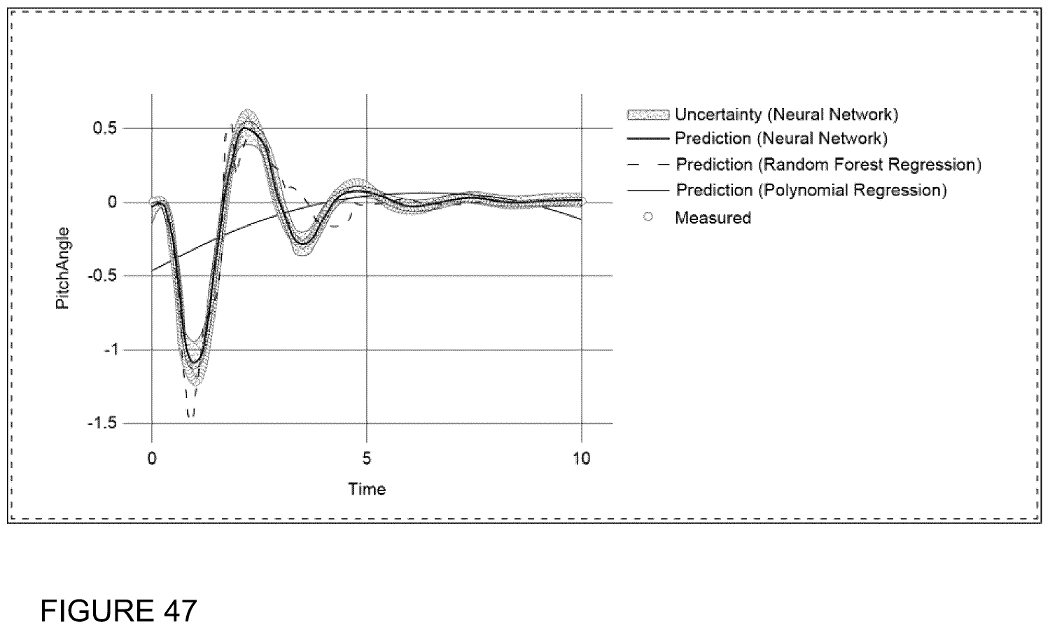

FIG. 47 provides the output of the validation plot that shows the ‘ground truth’ data (outcome of a simulation) overlaid with predictions from each model. As would be expected for the oscillating response, the results from the Polynomial Regression model are poor. The Random Forest Regression model and the neural network, however, capture the non linear physical trends.

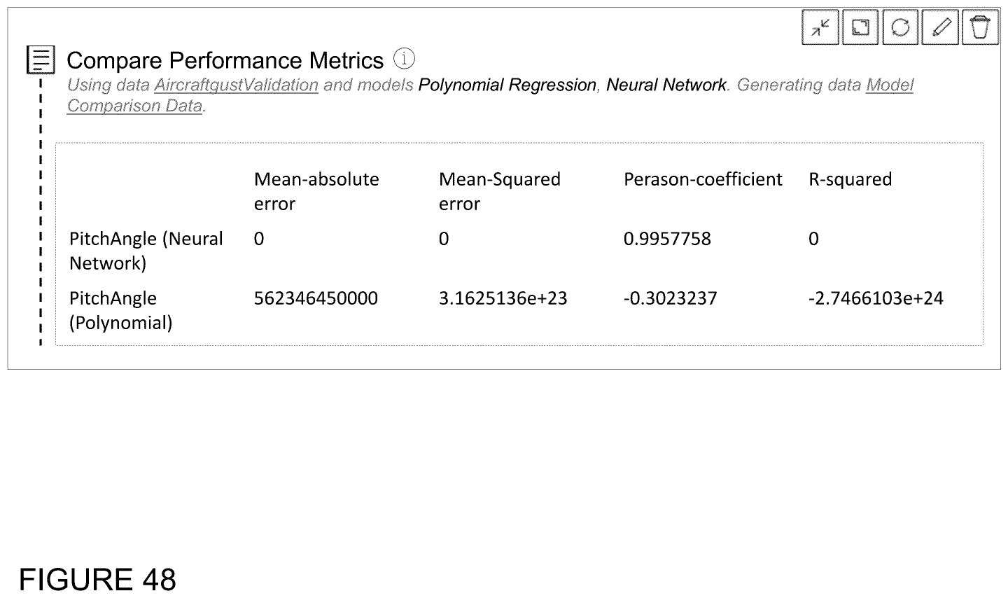

FIG. 48 provides a more quantitative assessment of model performances and shows a table listing different metrics for the error between prediction and reality, to easily compare and rank the quality of multiple models quantitatively according to scalar metrics.

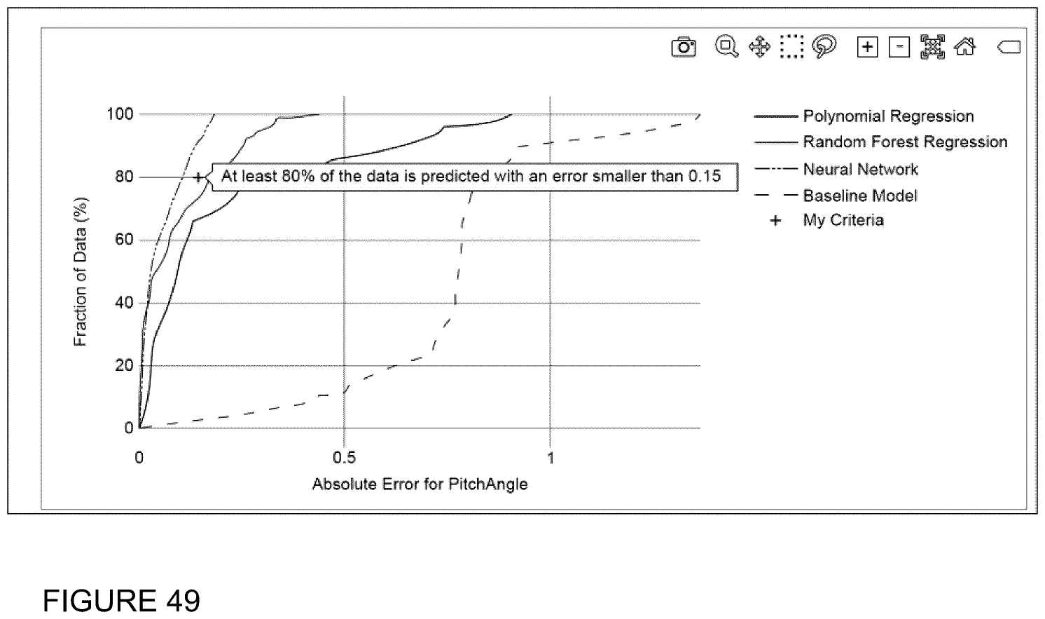

FIG. 49 provides the output of the step ‘Model→Compare against Criteria’. This plot shows how great a portion of the test data has all predictions contained below a certain error value. The closer the curve is to the top left of the plot, the more accurate the model. In this example, only the neural network model satisfies the criteria.

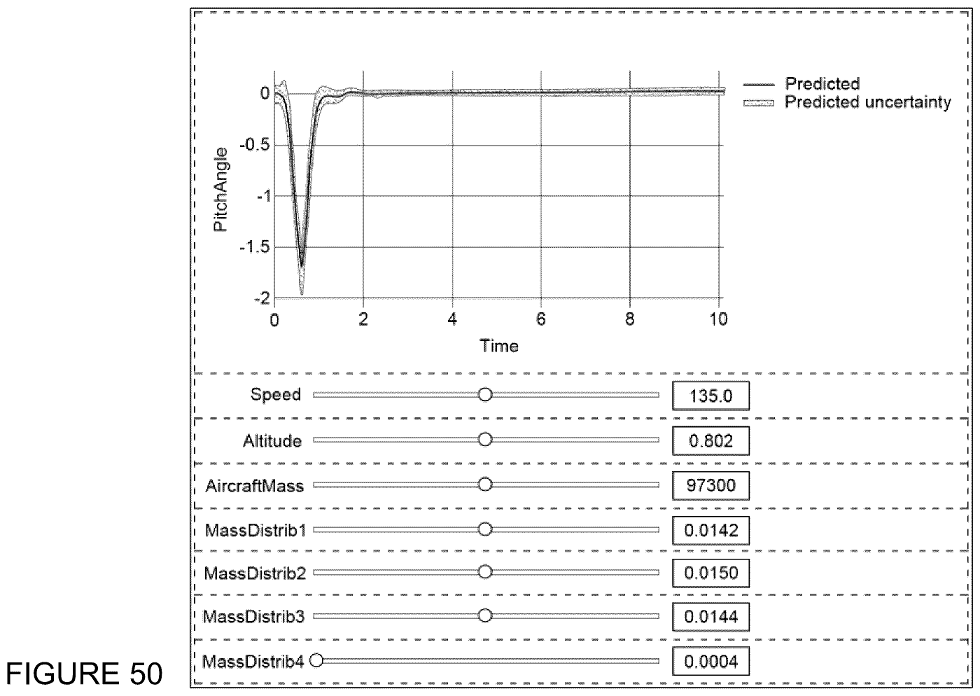

FIG. 50 provides the output of the step ‘Apply->Curve Prediction’ with the neural network model selected to plot pitch angle against time. Instant predictions for the dynamic response to gusts of wind for any new combination of aircraft characteristics are provided. Sliders can be interacted with to identify the ones which most affect the peak amplitude, frequency and damping of the oscillations. MassDristrib4 which indicates how much of the mass distribution is concentrated towards the rear of the aircraft has an important impact on the dynamic response.

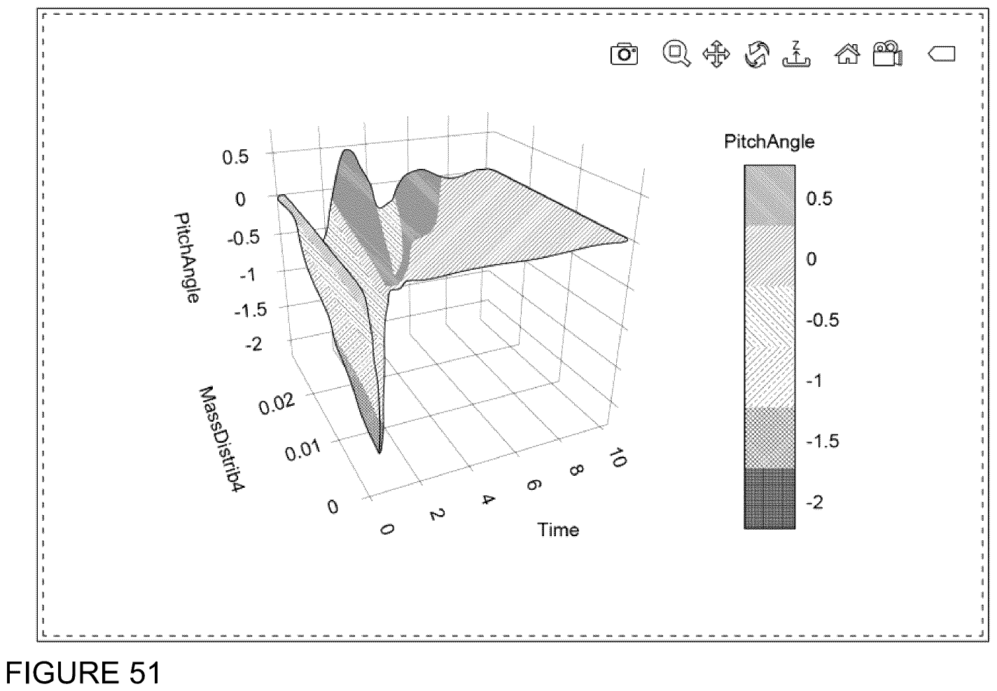

FIG. 51 provides the output of the step ‘Apply→Surface Prediction’. The resultant plot is like the curve prediction tool, except with an extra input dimension. By rotating the response surface around, it is possible to quickly identify how this trade-off exists. For example, for low values of MassDistrib4, there is no oscillation but a very sudden drop in pitch angle. For highest values of MassDistrib4, the variation in pitch angle due to gusts lasts longer but is lower amplitude and frequency.

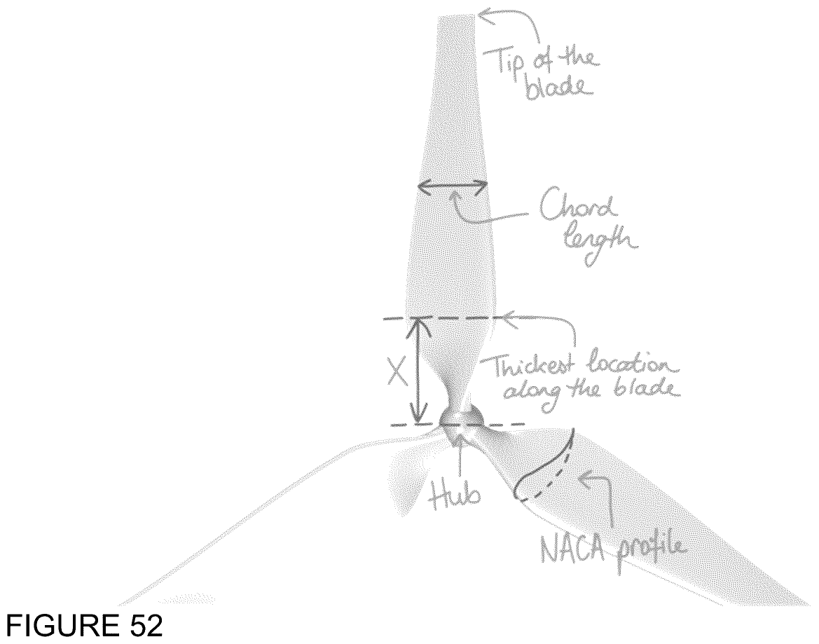

FIGS. 52 to 55 now provide a further example of multi-physics optimisation for designing wind turbines.

The Monolith platform may be used to predict the outcome of multi-physics 3D numerical simulations (including entire 3D fields of data) for any new combination of design parameters or target variables. AI models may also be used to solve complex optimisation problems: finding the optimal set of design parameters which satisfy a target set of performance metrics. Finally, for the scenarios in which parametric CAD models are used, it is possible to automatically parameterise a series of CAD files to generate new, performance-optimised designs.

As an example, numerical simulations of the performance of wind turbine designs may be used. They are complex engineering products which present interesting design optimisation challenges. Their main function is to convert wind energy into electricity as efficiently as possible. However, many constraints (structural dynamics, materials, maintenance cost, etc.) force aerodynamics to make trade-off decisions.

A similar workflow can be used with many other datasets, such as physical tests or datasets involving different types of data (material properties, raw sensor data, time series data, etc).

The dataset used in these tutorials contains two types of simulations. The first is a Computational Fluid Dynamics (CFD) simulation calculating the 3D pressure field, the axial velocity of the flow and the power coefficient of different wind turbines tested under different boundary conditions. The second is a structural dynamic simulation which captures the stress distribution along the turbine blades, due to centrifugal acceleration. This stress value is normalised to only depend on geometric parameters (mass distribution). Each row of data corresponds to a different blade design. As shown in FIG. 52, the input parameters are mostly the geometric parameters from a parametric CAD model: the twist angle (Alpha), chord length and NACA profile at both the tip of the blade and at the thickest point along the blade. There are also two boundary conditions: the speed of the incoming flow (windspeed) and the tip speed ratio, which is the ratio between the speed of rotation of the tip of the blade and the windspeed. Some outputs are geometric measurements (Volume, SurfaceArea and MomentOfInertia), and two last columns are the main scalar outputs: the power coefficient (aerodynamic efficiency of the turbine) and the peak stress (the single highest value in the structural stress field)

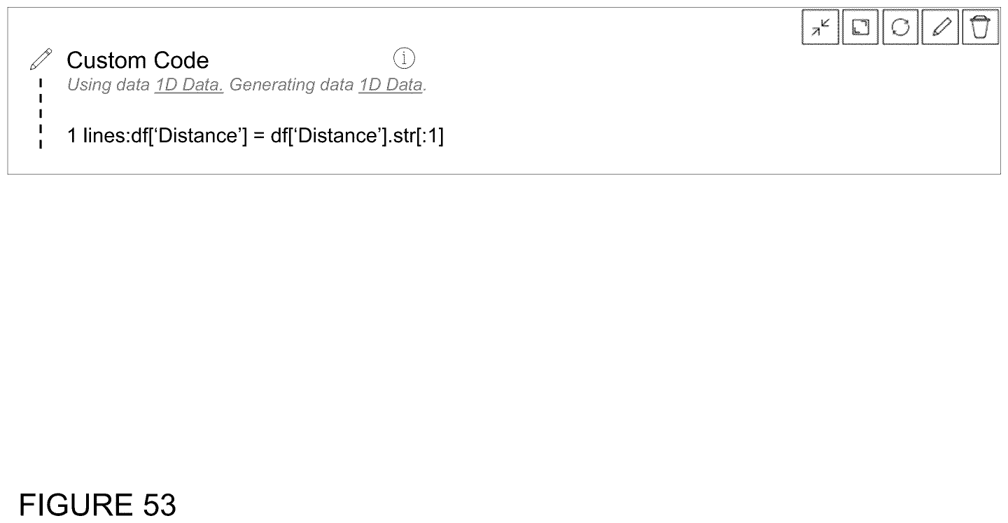

Data files are first imported, and the 1D Data is restructured to join it to the data of scalar variables. Within the ‘Transform→Wide-to-long steps’, the 1D Data and all variables from −12 m to 12 m for the Columns are selected. This will transform the data from having 27 columns to having only 3. Next, the distance values are converted to numerical parameters. The ‘m’ character which was in the original CSV files to indicate the units (meters) is first removed. This is done using the ‘Transform->Custom Code’ step as shown in FIG. 53. This Python code removes the last character of each string in the distance column.

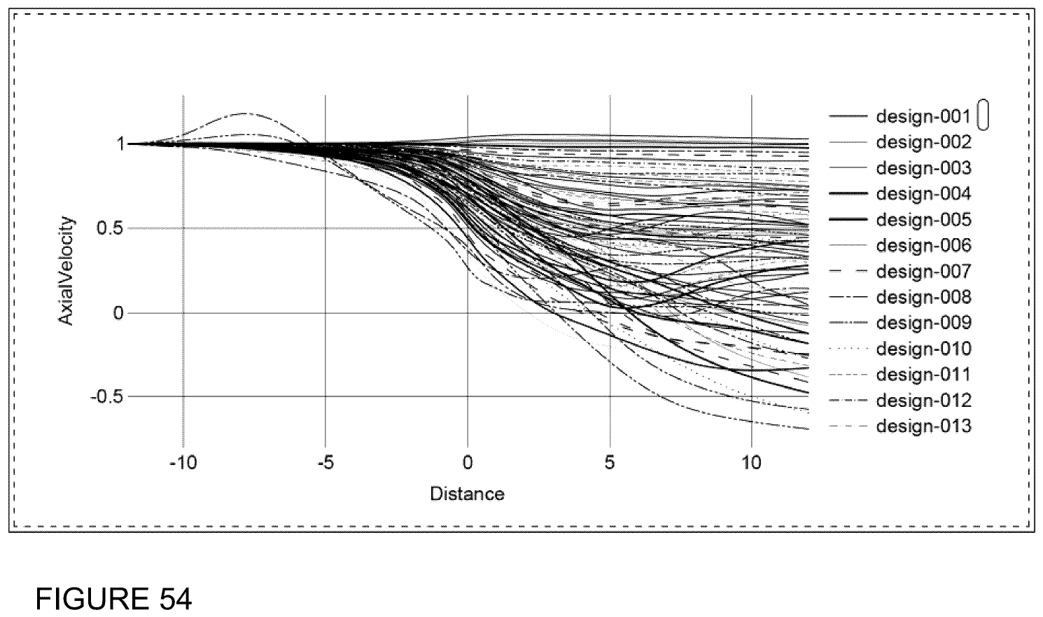

FIG. 54 shows the output of the line plot tool in which the axial velocity is displayed as a function of distance. The plots obtained show the deceleration of the flow as the air approaches and passes the turbine (located at Distance=0). Note that the values are normalised against the initial windspeed.

Two different models are now trained: one to predict the scalar performance metrics, and the other to predict the axial velocity.

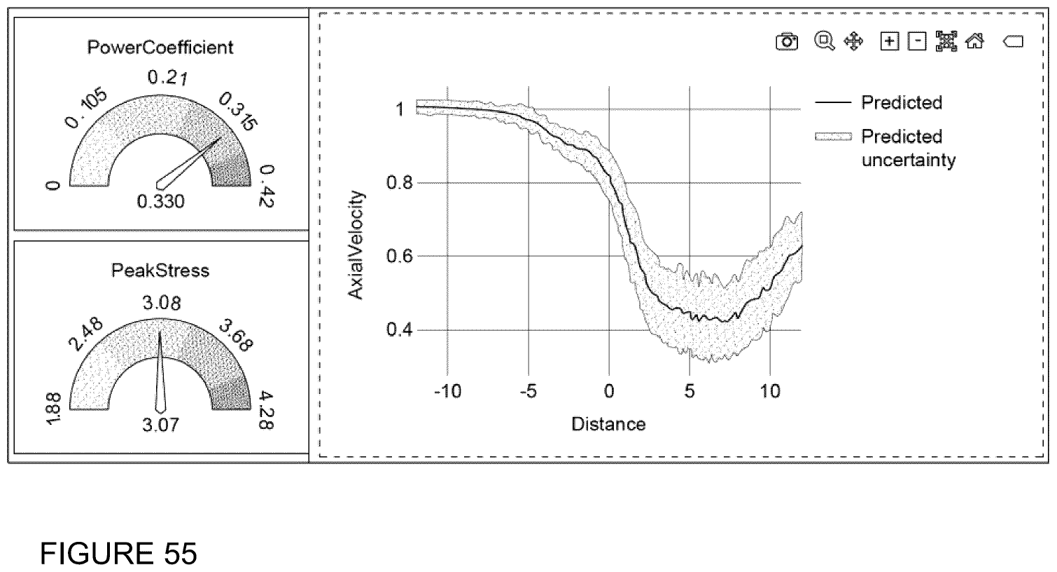

The following provides the sequence of steps applied by the end-user on the GUI:
‘Model→Gaussian Process Regression’ step, select the scalar data. For the inputs, the geometric parameters (X_ThickestPointLocation, Alpha*, Chord*, Naca*) and the boundary conditions (Windspeed and TipSpeedRatio) are selected. For the outputs, (PowerCoefficient and PeakStress) are selected.
‘Transform→Join’ step: since the Axial Velocity (1D Data) is an output dependent on the design variables and boundary conditions, tables are joined together in preparation for modelling. ‘Joined Data’ is created.
‘Model→Neural Network step’ is applied using the joined data.
Since both the models we trained are predicting outcomes from the same simulation, ‘Apply→Fix Parameters’ is selected to build a unique set of sliders to fix input parameters for predictions. This will create a set of sliders which can be used by subsequent steps.
Predictions from the models can then be viewed. Within ‘Apply→Scalar Prediction’, the fixed Parameters series are selected, and the Gaussian Process Regression model is selected.
‘Apply→Curve Prediction’ is then used; the fixed Parameters series are selected, and the neural network model is selected. The design selection can be varied in the Fix Parameters step and the instant prediction of performance is provided in the two subsequent steps, as shown in FIG. 55.

A trained model can also be used with a dataset prediction step to perform virtual testing. Looking at engine calibration data as an example, the platform may be used to assess if reducing the charging loss (due to friction within the gas chamber) by 5% would impact the fuel consumption. As it would be expensive and time consuming to make it happen, knowing in advance if this improvement would result in 0%, 0.5%, or 5% reduction of the fuel consumption is extremely valuable. It will enable to know whether more time and money should be spent to do research in this area. Thus, a model is first trained on an existing test campaign, and a virtual test campaign is generated by changing the value of the charging loss and a new fuel consumption is calculated. Finally, the two campaigns are compared to gain quantitative insight on the effect of the charging loss.

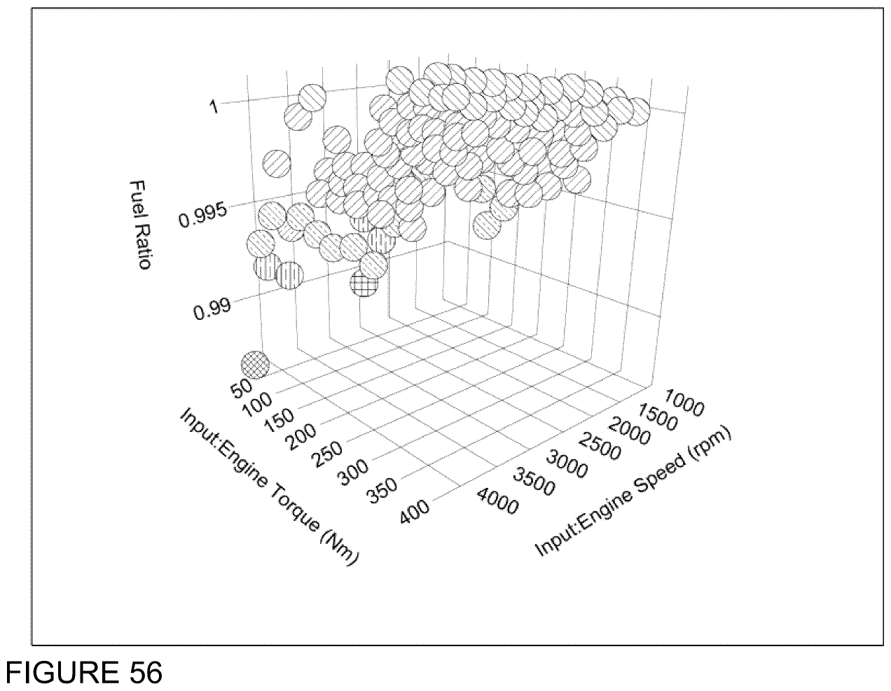

The results are provided in FIG. 56 in which the output of the ‘Explore→3D Point Plot’ step is provided. The 3D plot displays fuel ratio as a function of engine torque and engine speed. For low-speed values, the fuel ratio is close to 1, meaning that lower charging loss has a small impact. However, for higher speed, the 5% reduction in charging loss can result in a fuel reduction of around 0.5% and up to 1%.

Engineers frequently work with 3D data to evaluate the performance or quality of products. They design their products in CAD environments, before setting up numerical simulations or physical tests on prototypes.

As seen previously, historical data may be used to build machine learning models for predictions and optimisations. To build such models, the data needs to have a consistent set of parameters: a quantitatively comparable set of test conditions and test results. Machine learning models can then learn to extract physical correlations in the data. Unfortunately, CAD designs are often not parameterised, as they may be created independently from each other, and their data structure is not tabular. Engineers have therefore traditionally found it difficult to use AI with CAD designs.

The platform addresses this problem. The deep learning AI models can predict entire 3D fields of simulation data from 3D CAD designs. In the following example, only CAD files are used as the geometric inputs to AI models, instead of tabulated parameters.

A dataset of 3D simulation results of wind turbines is first loaded, along with a dataset of corresponding simulation boundary conditions. Using the ‘Transform→Attach Operating Conditions’ step, each 3D simulation result is then linked to the corresponding set of boundary conditions, which will be needed when training AI models since the 3D fields of data depend not only on geometry, but also on test conditions.

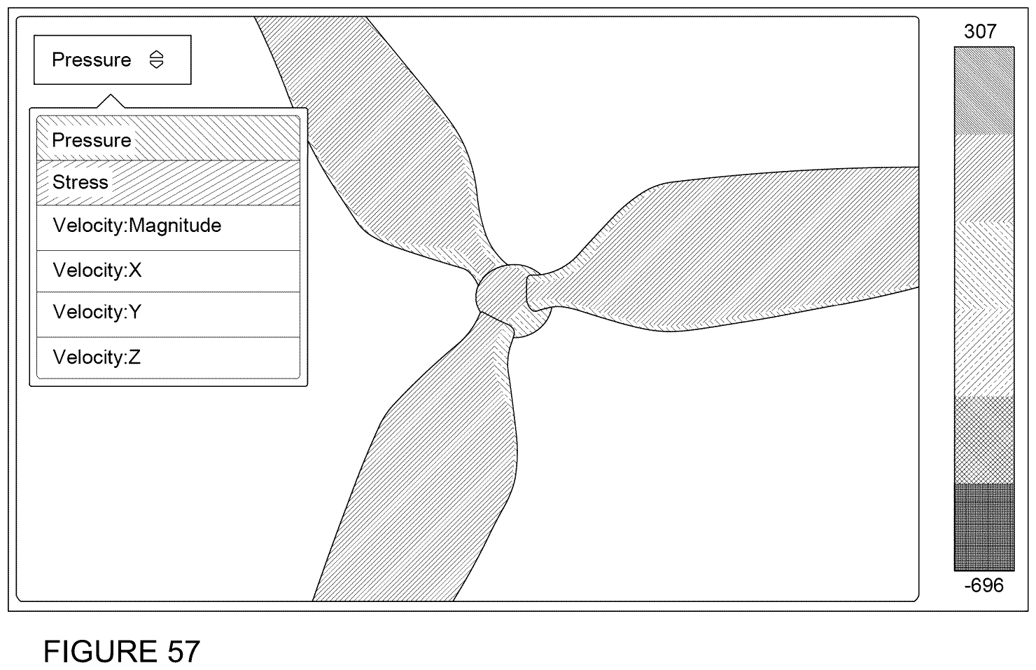

FIG. 57 shows a visualisation of this 3D Data. Different 3D fields may be viewed. Pressure is the surface pressure from the aerodynamics simulation, and stress is the stress field of the structural dynamics' simulation.

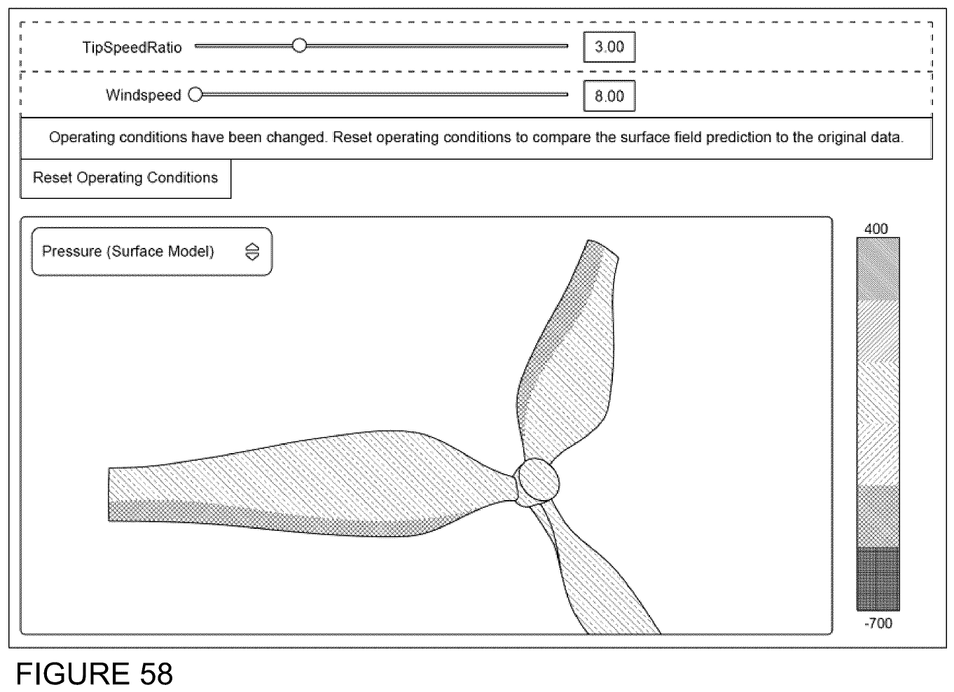

A surface field model may then be trained to predict 3D simulation fields for any new 3D design tested under new conditions. As it's training, the Surface Field model will ‘scan’ the dataset of 3D designs to ‘learn’ the distinct 3D design parameters which yield different 3D simulation fields. The output of the surface field prediction is provided in FIG. 58. 3D viewers are provided, with a side-by-side comparison of real simulation data vs. a prediction of the 3D field for the same design tested under the same conditions.

Using sliders, instant predictions may be made for what the 3D simulation results would be if the design was tested under different conditions.

Historically in engineering, parameterisation relied on being able to edit and tune tabular information. However, when a geometry is too complex, an autoencoder model may be used.

### AI Generated 3D Designs

The autoencoder model learns design DNA for historical CAD data. It automatically ‘scans’ polygon meshes, to extract the distinct design parameters, such as geometric features which characterise each design. The two main benefits of this feature are to compress an existing design into a set of design parameters to predict its performance, and to generate optimised designs which satisfy target variables and/or constraints.

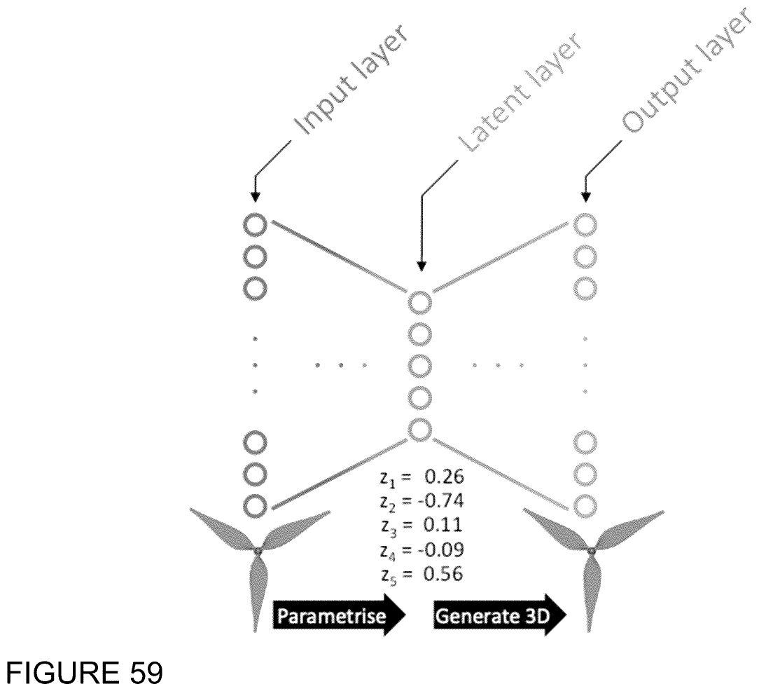

The structure of an autoencoder reflects these concepts of encoding data (parameterising designs) and decoding data (generating new designs). The latent layer is the centrepiece of the autoencoder. It contains a compressed representation of the data, which we call latent parameters. After training an autoencoder, two separate models are provided: an encoder which transforms a 3D design into a set of latent parameters, and a decoder which generates new 3D designs for any new set of latent parameters, as shown in FIG. 59.

As an example, a 3D dataset is uploaded in the platform. Using the ‘Transform->Train/Test split’, the 3D data may be first transformed into user-defined ratio such as a 80/20 split. This step randomly splits the 3D dataset in two smaller datasets that can be used to train and test models separately.

An autoencoder may then be trained. In the case of the wind turbine use case, we're working with 3D meshes which represent a structured grid of points, meaning that each mesh in the dataset contains the same number of vertices. Here, an autoencoder model specially built for this type of 3D data is used. More generally, the autoencoders can handle any type of polygon mesh, but the training time may be much longer for unstructured meshes.

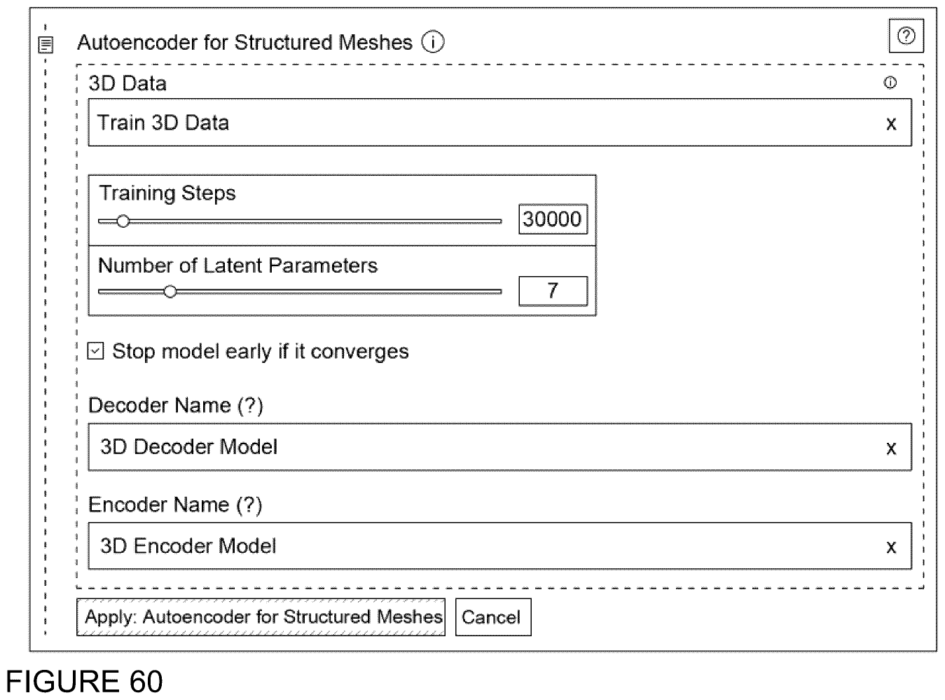

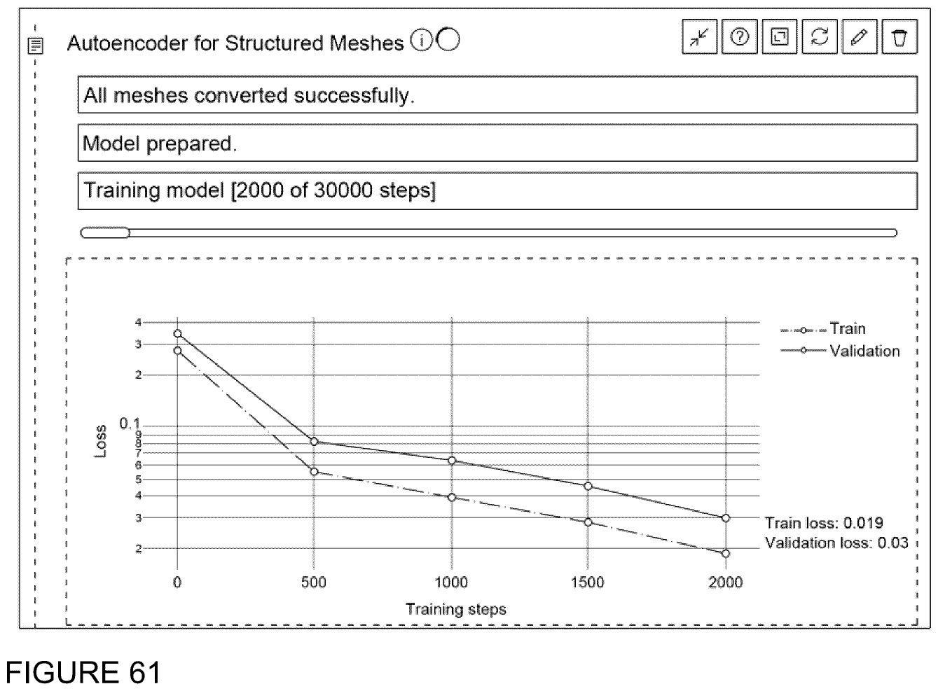

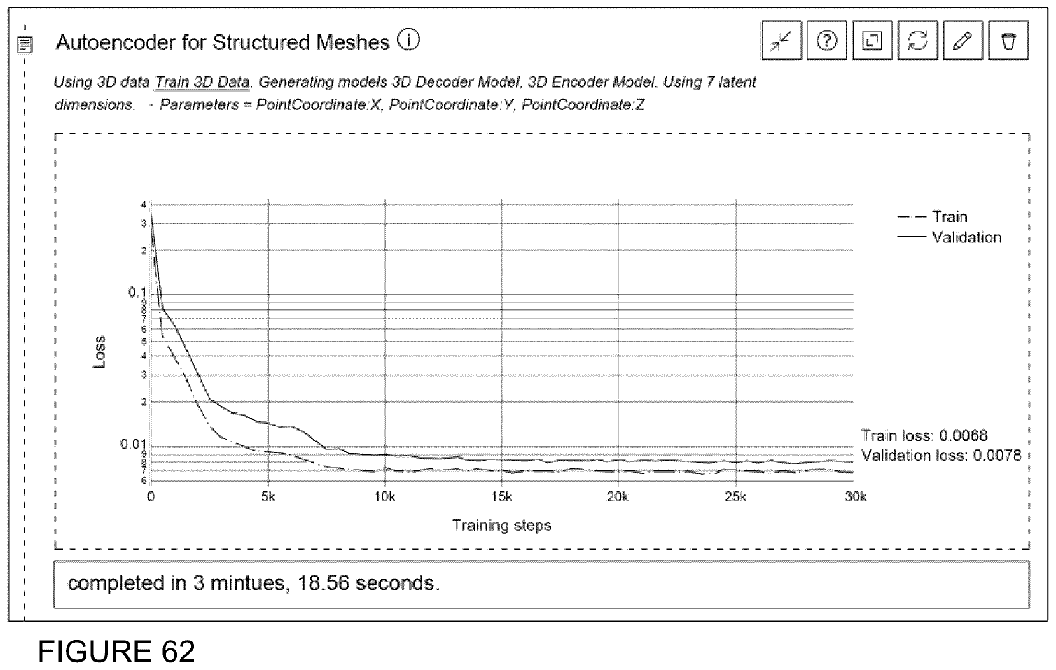

The 3D data is trained using the ‘Model→Autoencoder for structured meshes’ step as shown in FIG. 60. The autoencoder automatically parametrises a series of structured 3D meshes into a set of latent parameters and creates an encoder model as well as a decoder model. As shown in FIG. 60, 30000 training steps and 7 latent parameters are chosen in this example. As described above when training a neural network model, plots indicating the evolution of the model's scoring metric are also displayed in real-time, as the model learns to parameterise, and accurately regenerate geometry as shown in FIG. 61. The final output is shown in FIG. 62.

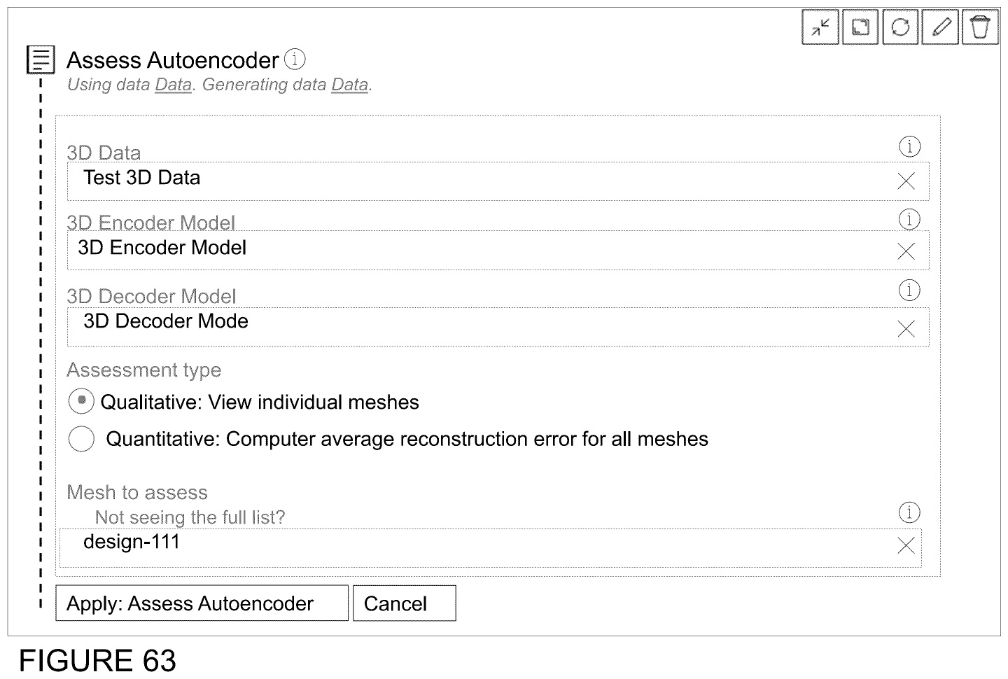

The quality of the autoencoder is then evaluated using the ‘Apply→Assess Autoencoder’ as shown in FIG. 63. A qualitive or quantitative assessment may be chosen.

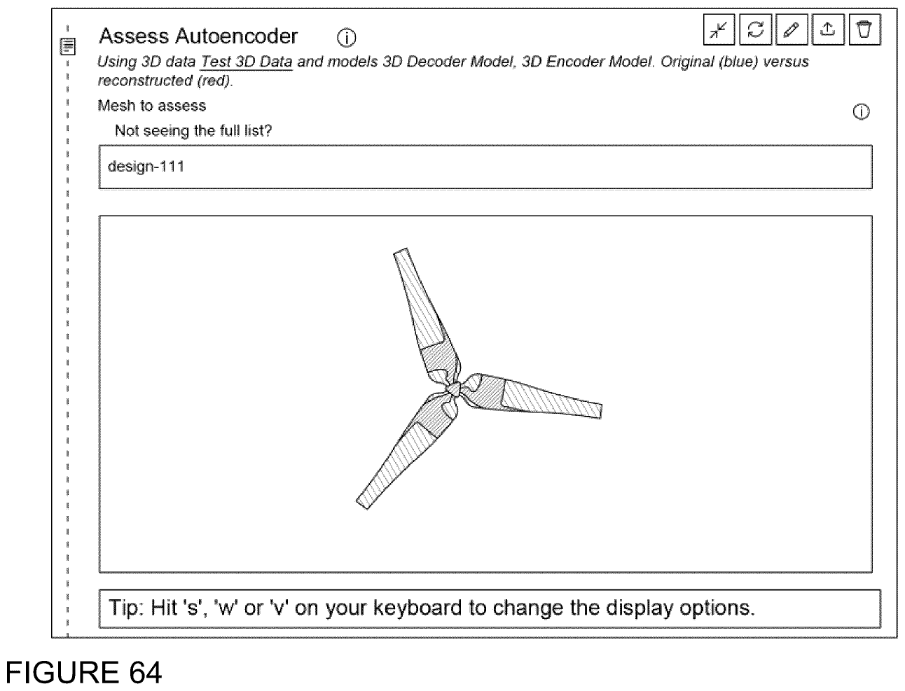

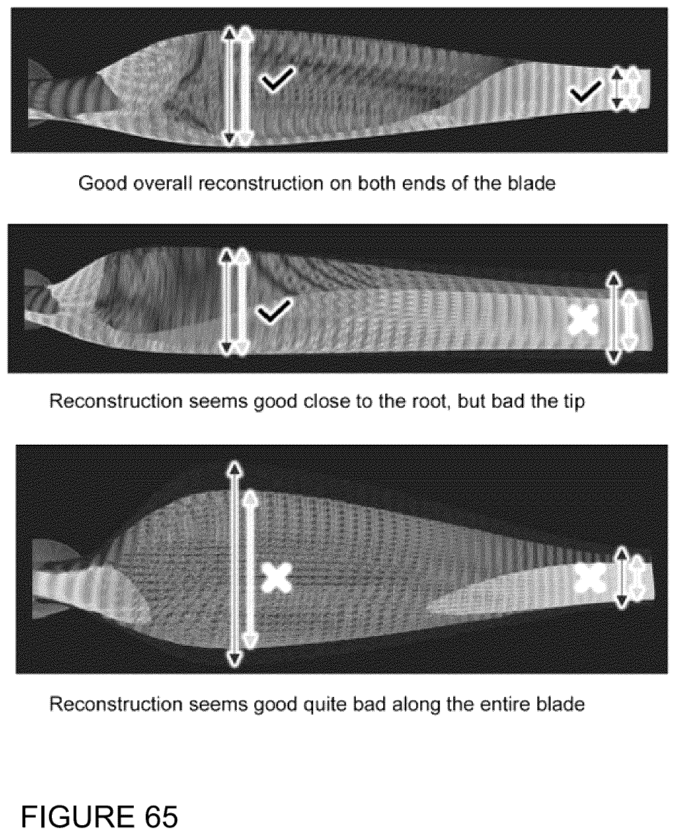

FIG. 64 shows the output of a qualitative assessment, with the original mesh overlaid with the same mesh which has been encoded and decoded. It is therefore a visual assessment of the ability for the autoencoder to regenerate 3D designs. Further details are provided in FIG. 65.

In this case, the model was not trained for many steps, and a longer training time would improve the reconstruction accuracy. Quantitative assessments to compute the average distance between original and regenerated meshes in the dataset may also be performed.

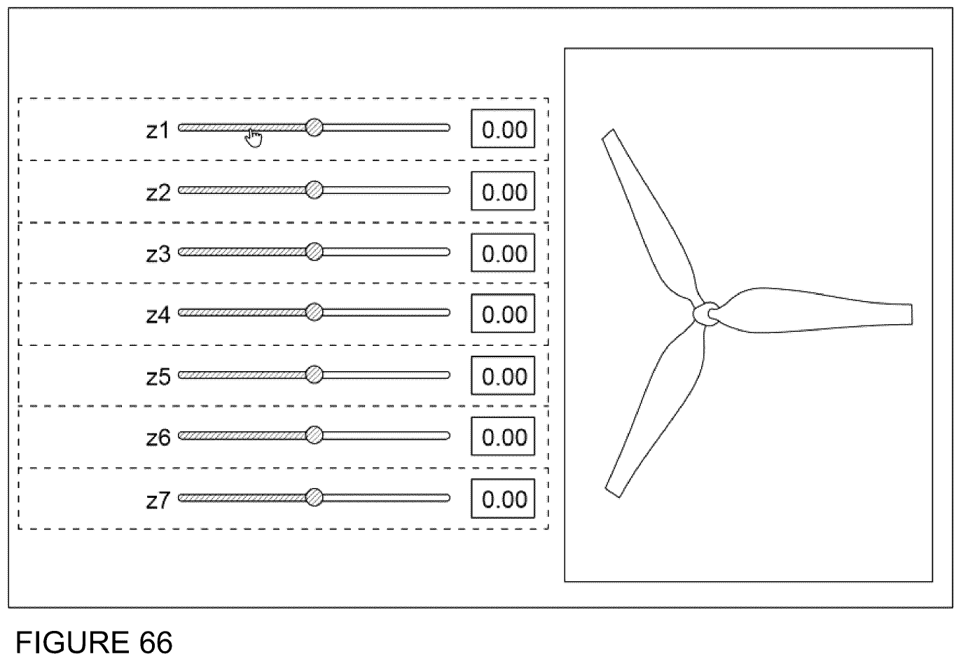

The model can link geometry to latent parameters and can be used to generate new geometries with different combinations of latent parameters. FIG. 66 shows the output of the ‘apply->view decoded designs’ step. The latent parameters can be varied using the sliders, and the resulting geometry will be automatically updated.

Automated parametrisation means that the autoencoder might find parameters that a human wouldn't have thought of. The autoencoder is a dimensionality-reduction algorithm which compresses complex 3D information into the most representative set of parameters. In doing so, it might have combined parameters that we would intuitively look at separately. All this means that it can be harder to interpret the meaning of the automated parameters.

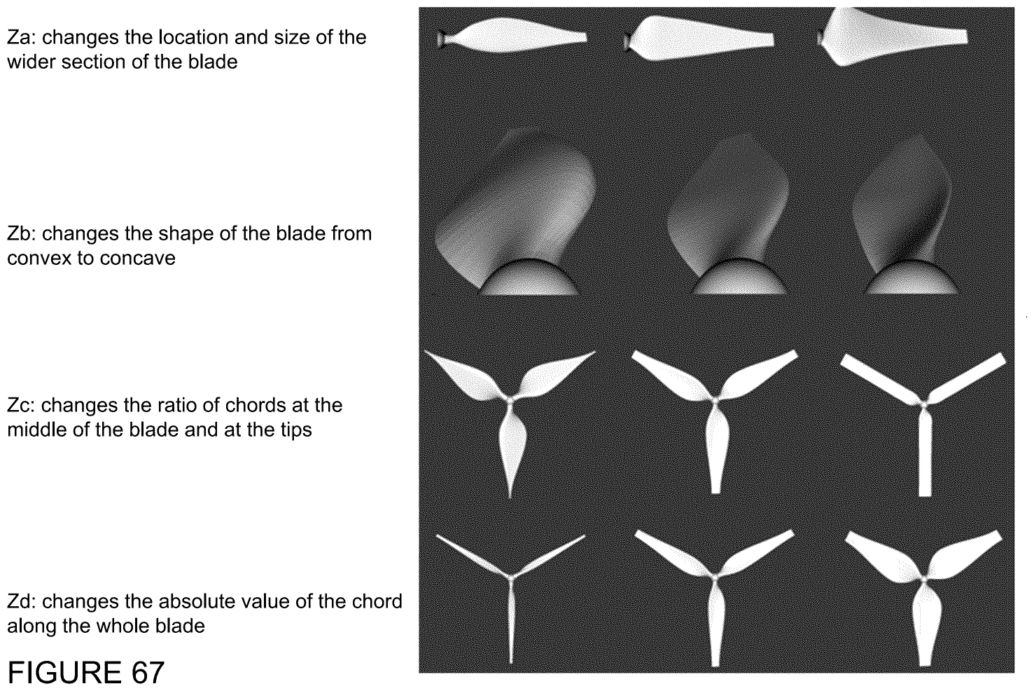

However, the latent parameters might still have an interpretable effect on the geometry, such as variations in the shape or the size of the geometry. FIG. 67 shows the effect of varying some of the latent parameters on the geometry of the wind turbine dataset. Their effect can be easily identified as changing the shape or the size of some parts of the wind turbine.

3D Design Optimisation

Another workflow example is provided to generate performance-optimised 3D designs with AI. The autoencoder described above is used to compress a series of CAD files into a set of latent parameters. Using this parameterisation, a neural network model is then used which predicts simulation outcomes for any new design. After the neural network model has finished training, the optimal set of input parameters is found for a target set of outputs.

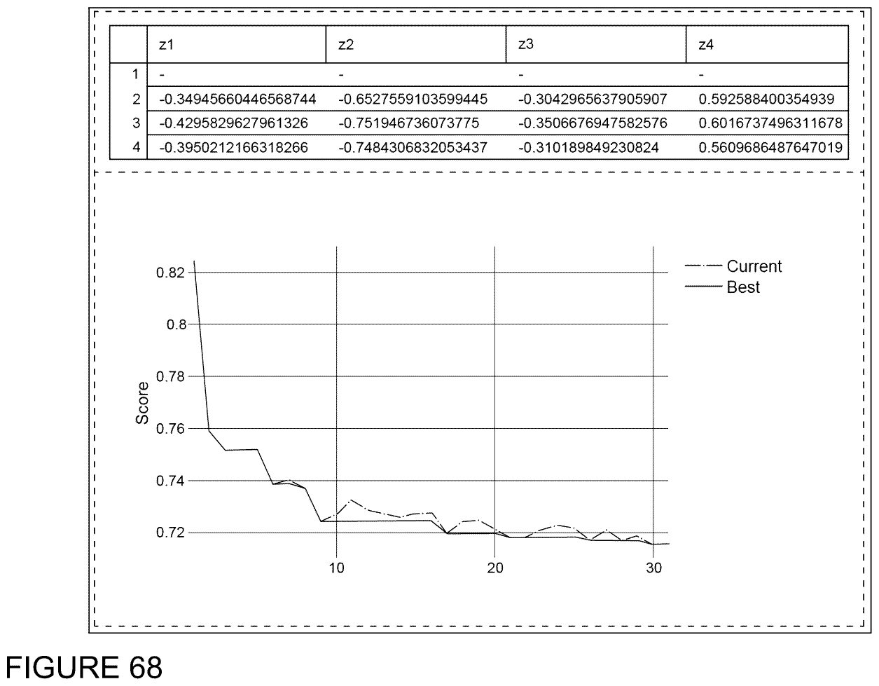

The output of this optimisation step is shown in FIG. 68 with the 3 best results. The optimal set of input parameters which satisfy target simulation results is determined. This set of optimum parameters will then be used to generate an optimum 3D mesh, for which 3D simulation fields of data can also be predicted.

Once the optimisation step has finished, the optimal set of latent parameters to regenerate 3D meshes are generated. The results are performance-optimised 3D designs which have been generated with AI.

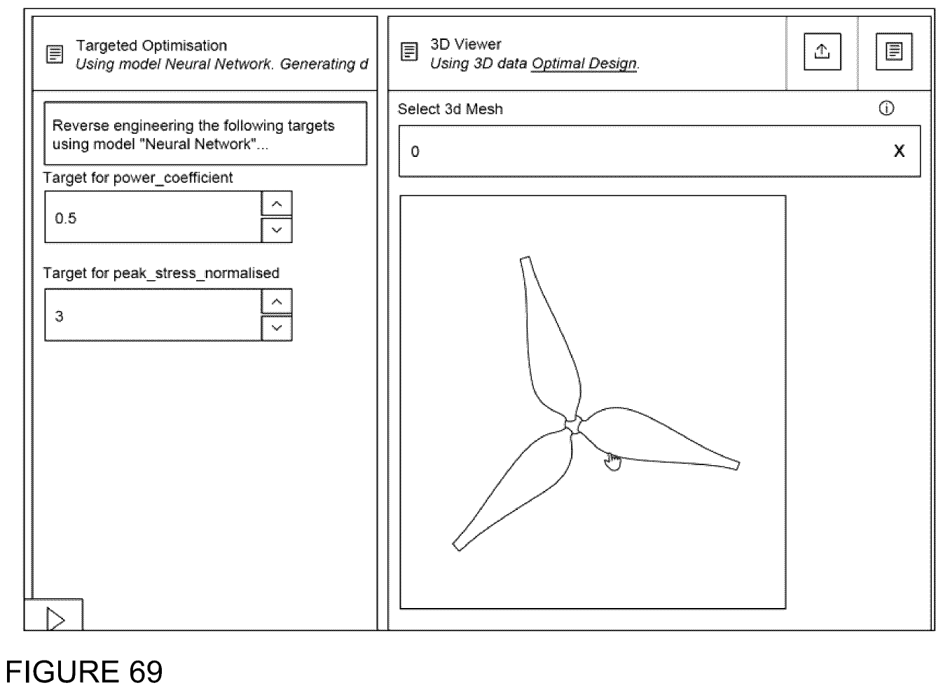

It is interesting to analyse how the shape of the optimum 3D designs changes as the target of the performance metric changes. As shown in FIG. 69, the end-user can now scroll up to the Targeted Optimisation step results, change the target values for PowerCoefficient and PeakStress, and the subsequent steps will refresh automatically to find and generate a new optimum design. For example, if the target PeakStress value is varied from 3 to 1, the optimal geometry will have a much smaller blade width, which will change the weight and the mass distribution of the blades to reduce the peak stress due to centrifugal acceleration. Consequently, the PowerCoefficient will also decrease.

Inputs may be restricted, for example by editing the target optimisation step. The possible ranges which optimal input parameters will be able to adopt may be imposed, or even fix certain input parameters.

This is a highly beneficial feature for the scenarios and optimum designs may be found for a known set of input conditions. For example, if a wind turbine may be designed for an environment in which the known windspeed will be 13 m/s. The input parameter can therefore be fixed and the most efficient wind turbine for a specific condition may be found.

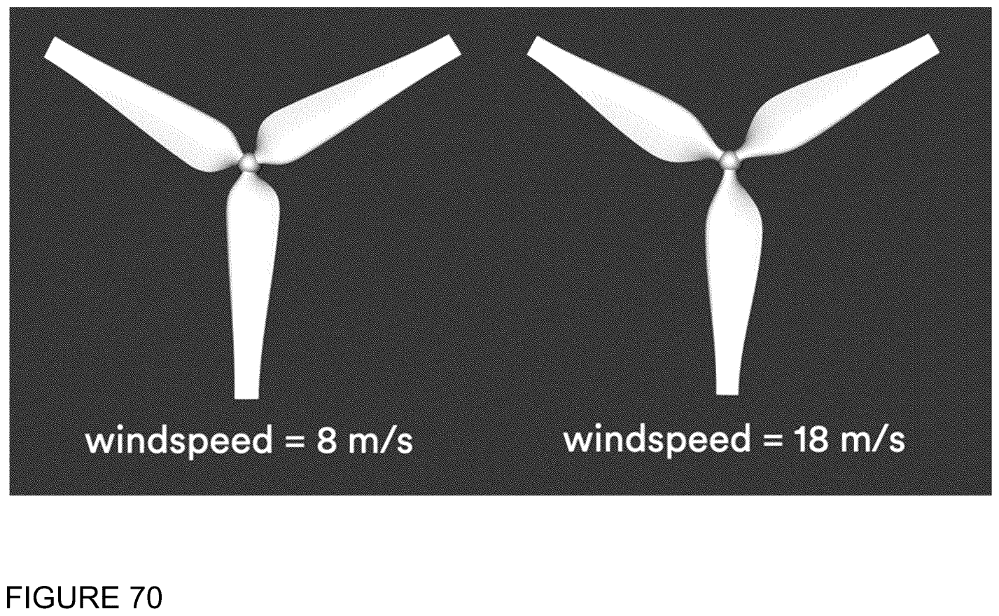

As shown in FIG. 70, an optimal turbine blade design for a low windspeed condition has a high surface area and small twist angle close to the hub, as it needs a higher frontal area to capture more wind energy.

### The Impact of Quantity

Engineering data is often either time consuming and/or expensive to gather, and as a result, the quantity of data available is often quite restricted. The impact of the number of input parameters and the complexity of the problem on the quantity of data needed to obtain a good AI model is now described.

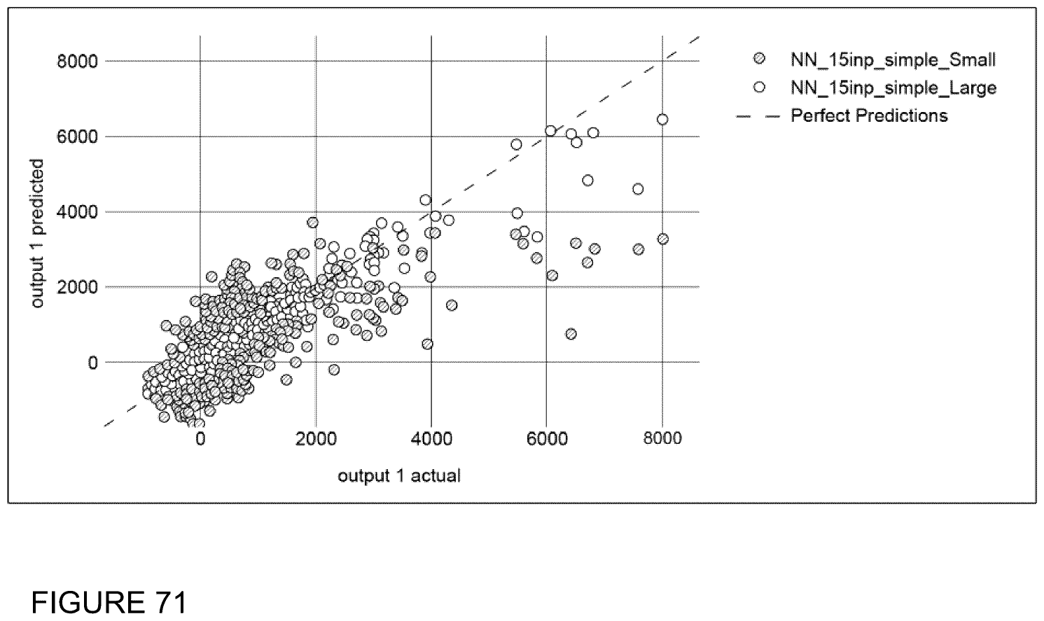

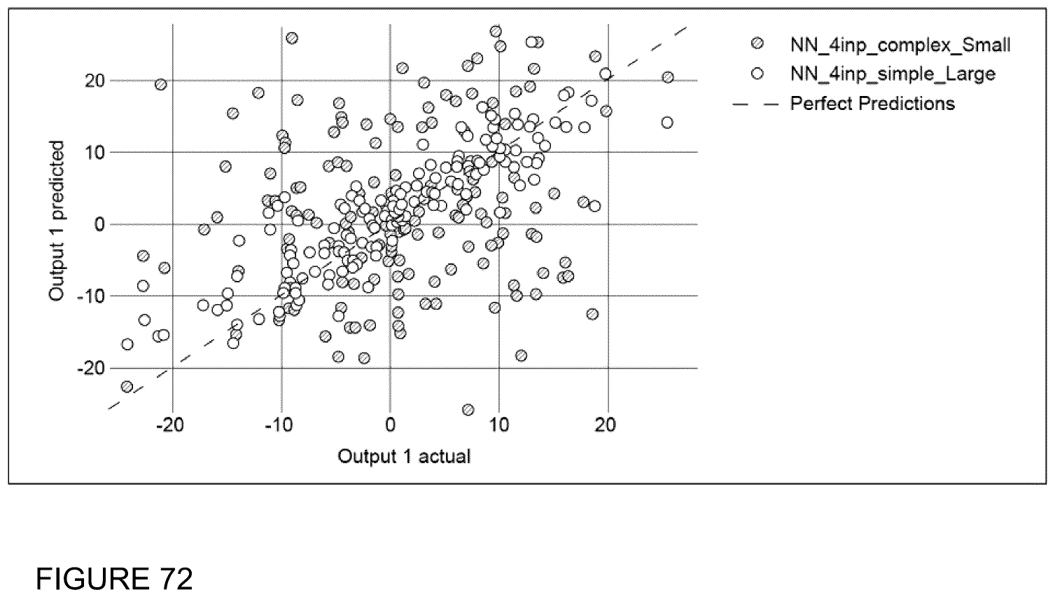

A neural network model trained on a small data set is compared to the one trained on a large dataset (with 50 times more data than the small dataset), as shown in FIG. 71. The model trained on the small data set is not accurate and the model trained on the large data set has a much better accuracy. FIG. 72 also shows a comparison of a neural network model trained on a small data set and of a neural network model trained on a large dataset (with 50 times more data than the small dataset) for a different, more complex problem. Once again, the model trained on the small data set is not accurate and the model trained on the large data set (with 8 times more data) has a much better accuracy.

### The Impact of Sparsity

A lot of the time, datasets aren't perfect. Sometimes, data will be missing, either it is not known, or not filled, or because of other human errors. The impact of missing data on the quality of a model is now described. We will also see how the exploration of the data, and of the missing data, can enable the end-user to get more accurate models.

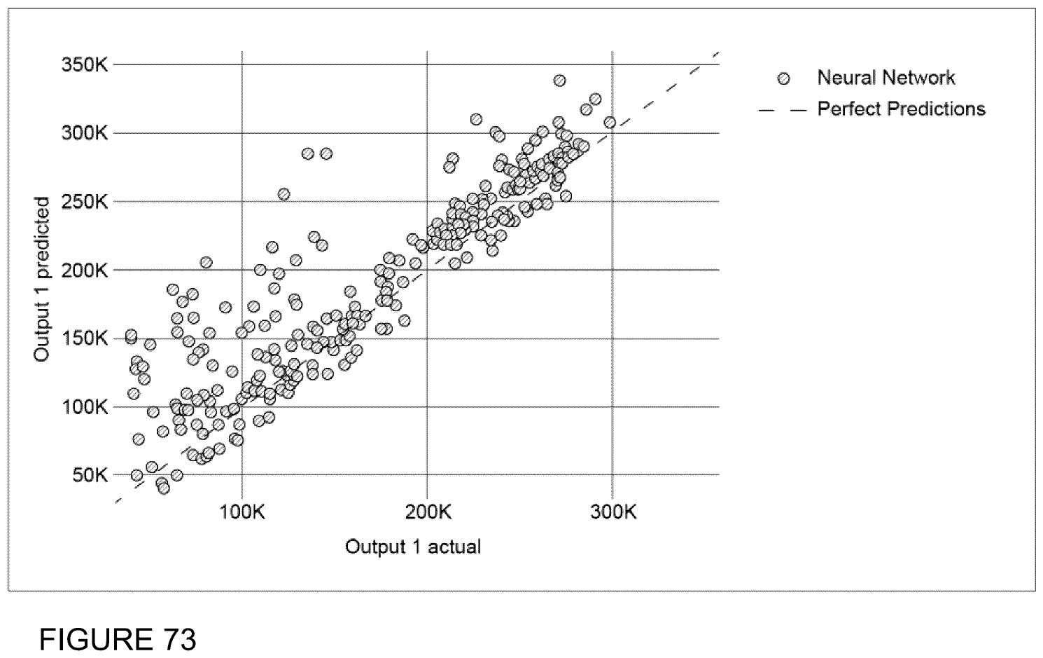

Once a model is trained, if data is missing, a warning may appear below the training curve, such as: “WARNING: 446 of 524 rows were silently dropped due to missing or bad data . . . ”. Although the dataset contains 524 rows, only 78 of them contain all the information. As a result, the model will perform poorly, as shown in FIG. 73.

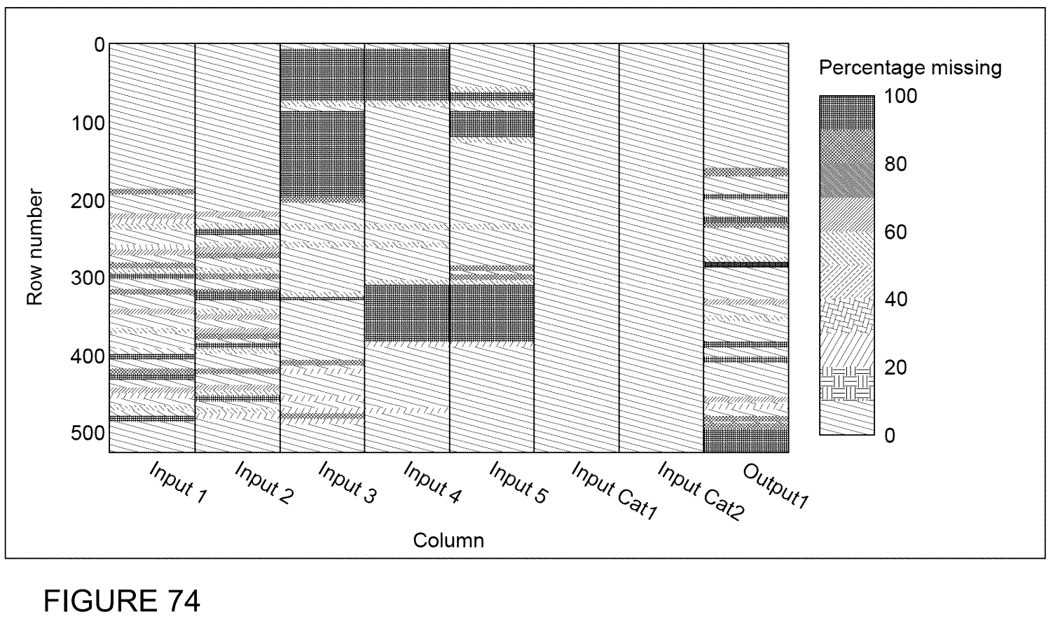

FIG. 74 shows the output of the ‘Explore→Plot Missing Data’ step. This plot shows how much data is missing for each selected column. Most inputs (and even the output) have data missing here and there. But it is quite obvious that Inputs 3. 4 and 5 have a lot of missing data, which explains why so much data was dropped in the first model.

Removing these inputs would enable the end-user to have much more data available to train the model. The end-user then clicks on the ‘Transform->remove missing’ step, and only selects Input 1, Input 2, Input Cat1, Input Cat2 and Output 1, chooses the method any (meaning that if data is missing for any of these columns in a row, the row is removed) and saves the output under a different name (such as “Train data processed”). The step will indicate that 233 of 524 rows are removed, meaning that 291 rows are available to train a model, which is much more than the original 78.

A new model may therefore be trained using the “Train data processed”, and only Input 1, Input 2, Input Cat1 and Input Cat2 are selected as inputs (and Output1 as output).

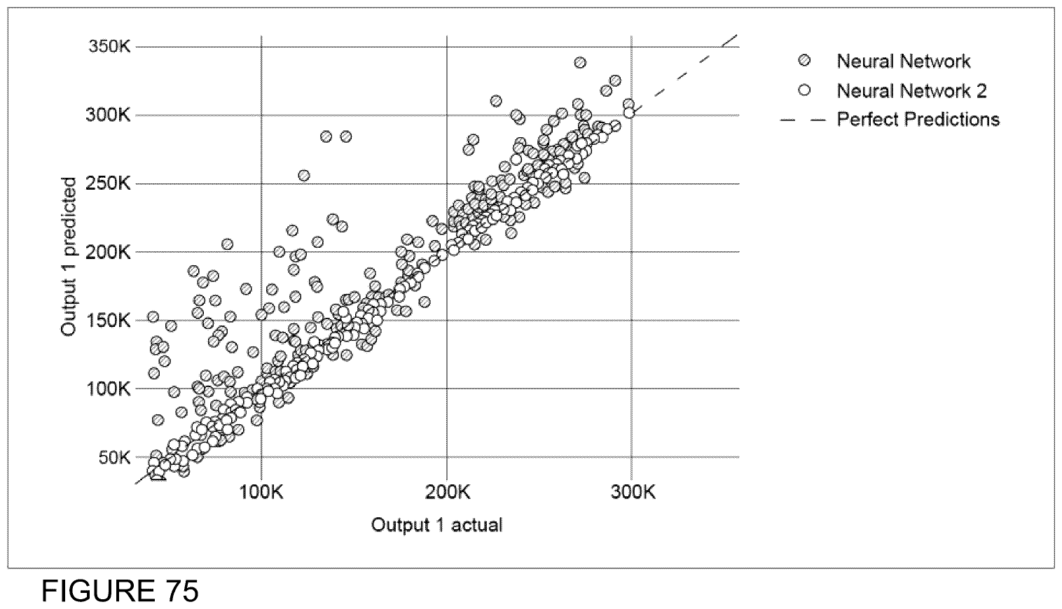

FIG. 75 shows a comparison of the two models. The new model is much more accurate than the first one. Model performance may also be compared. For example, the R-squared value of the model trained on processed data is around 0.99, which is much higher than for the first model without any processing (around 0.75).

### The Impact of Noise

In theory, equations describe the functional dependency between parameters very neatly resulting in smooth curves or surfaces if plotted against each other. Results may also be superimposed with noise. The level of noise in the data may mostly depend on how the data was generated.

We are now looking at how noise in the data affects the quality of the models and their predictions. Three different datasets with different levels of noise (none, medium, strong) are used to train machine learning models. We evaluate the performance of these models and compare them to each other.

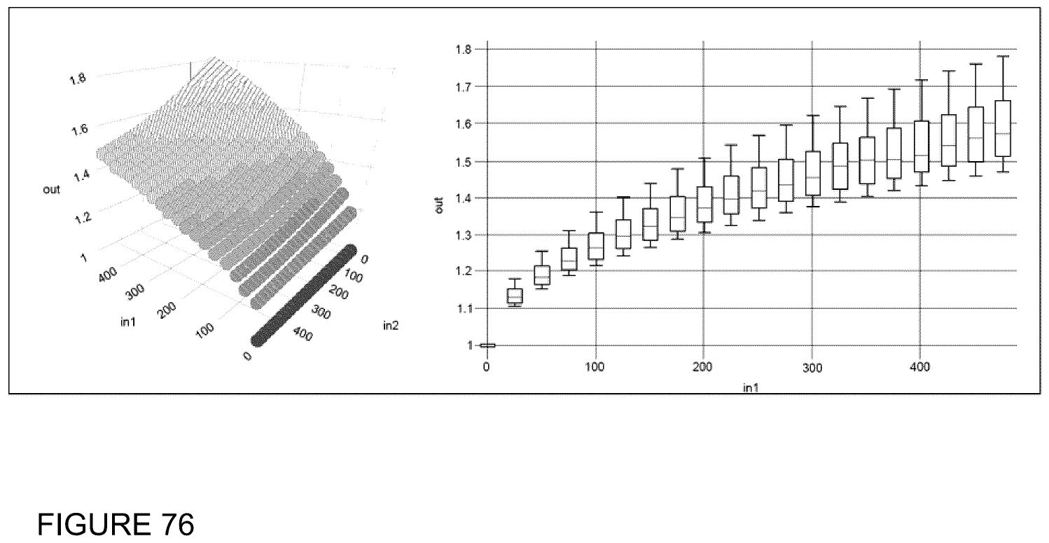

FIG. 76 shows the data without noise. A 3D point plot is displayed to visualise that the data points span a smooth surface. A ‘box and whiskers plot’ is also shown. A smooth trend in the data along an input (in1) is shown. Here again, a smooth increase in the output value is observed.

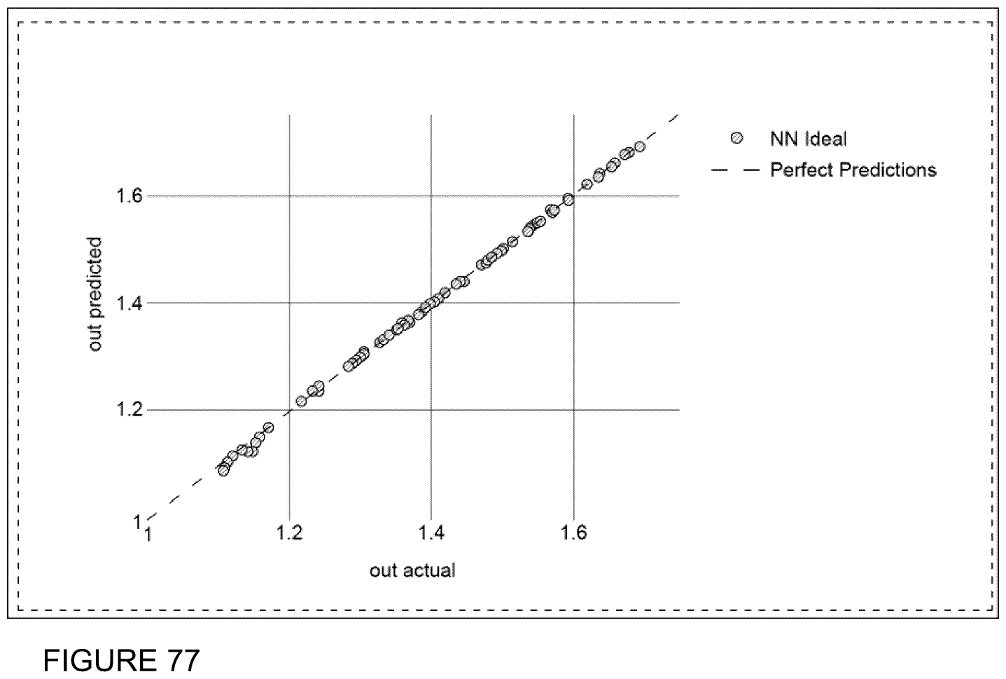

FIG. 77 shows a plot of the model performance when trained with the data without noise. The resulting plot shows that the trained model yields a very high accuracy.

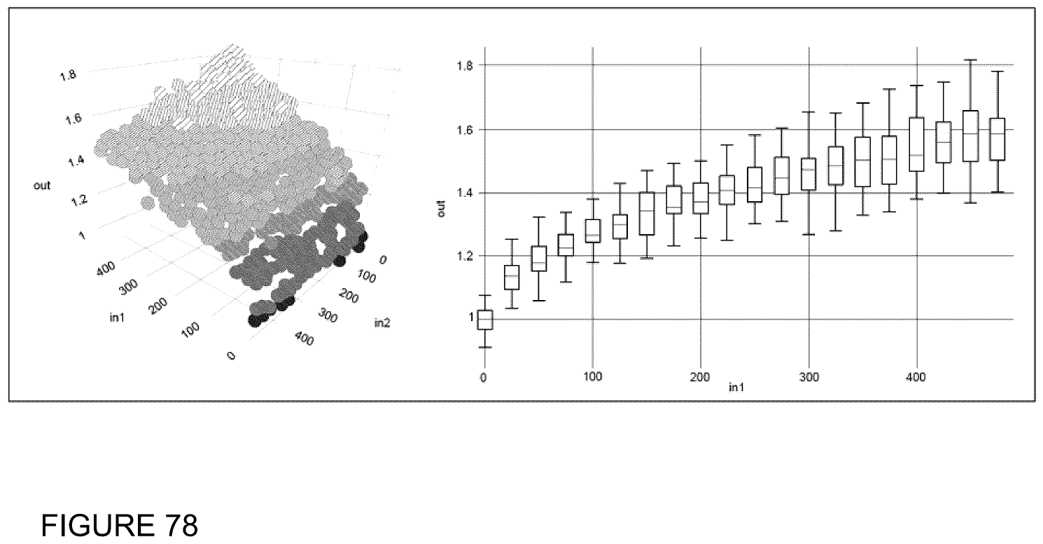

FIG. 78 shows the data with medium noise. A ‘box and whiskers’ plot is also shown. As seen, the dataset sill represents the trend in the data very well, but noise already starts to distort the data.

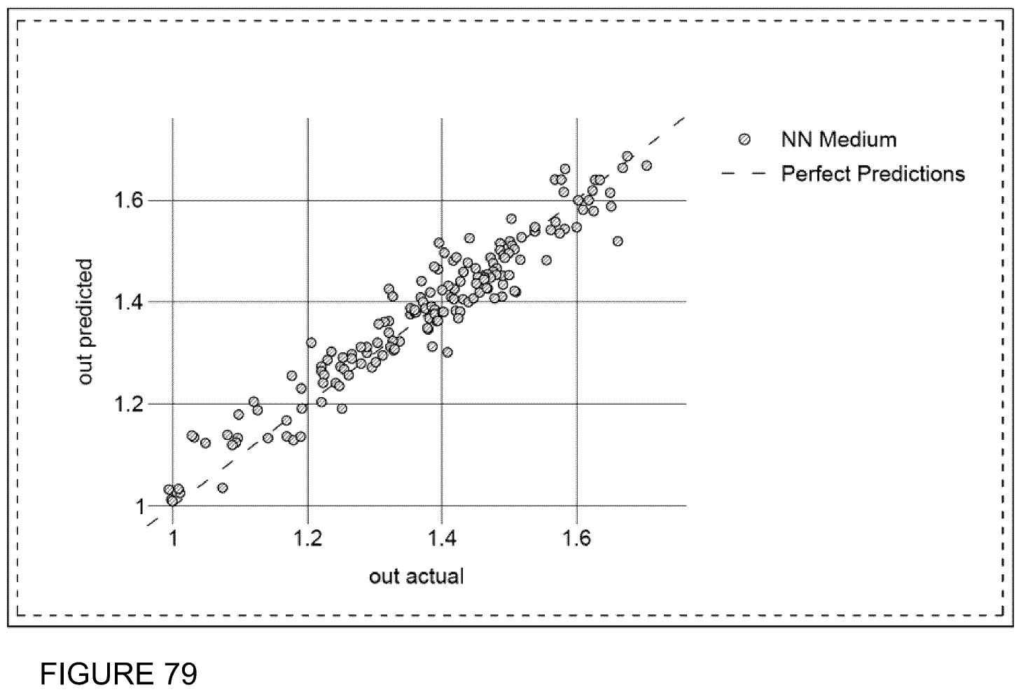

FIG. 79 shows a plot of the model performance when trained with the data with medium noise. The resulting plot shows that the trained model is still able to capture the trend in the dataset quite well, but the accuracy has dropped visibly.

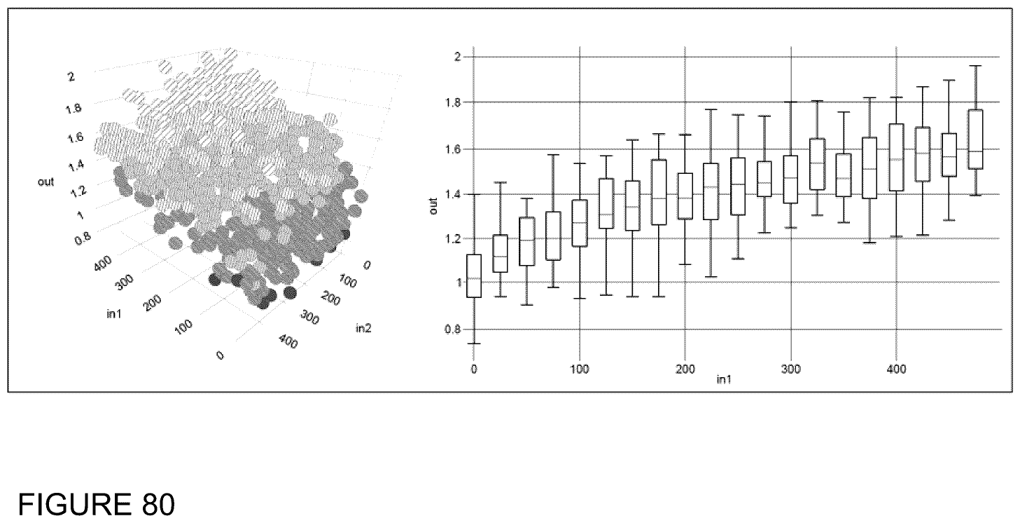

FIG. 80 shows the data with strong noise. A box and whiskers plot is also shown. The initial smooth surface is now very distorted and almost not recognizable anymore. The box and whiskers plot shows how the range within each bin increases and the overall trend becomes distorted.

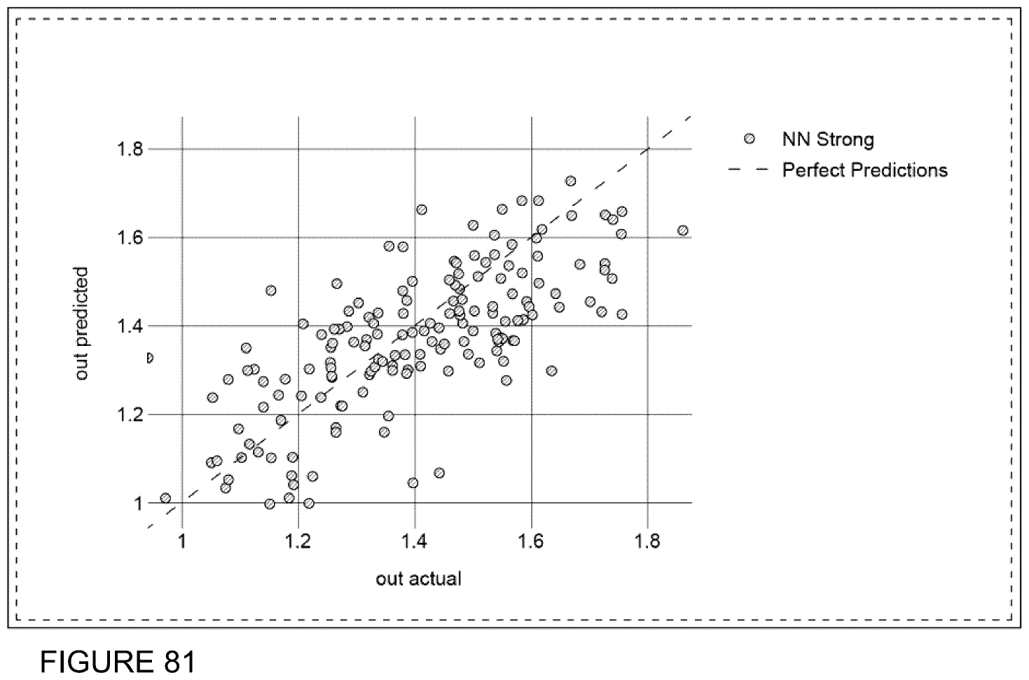

FIG. 81 shows a plot of the model performance when trained with the data with strong noise. The resulting plot shows that the model predictions are now very bad. The strong noise superimposed on the data prevents the model from finding a model which fits the data.

In this case, the model performance may be improved for example by tuning the model parameters or by choosing a model more appropriate for the noisy data.

However, the problem may also lie in the data itself. Advantageously, the platform is configured to predict and compare the performance of different machine learning models.

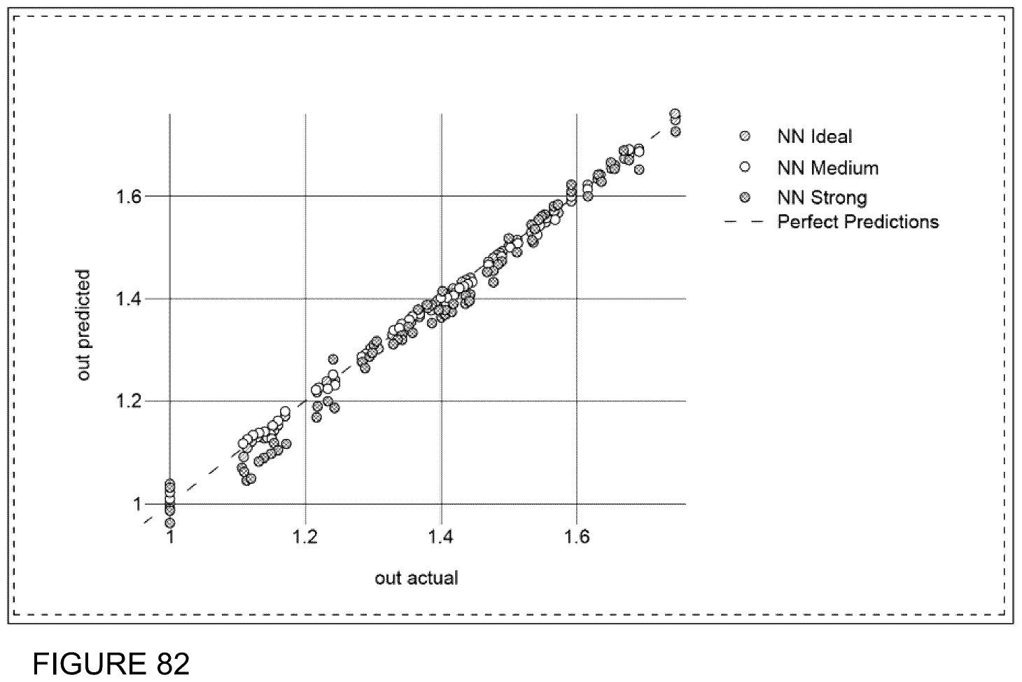

FIG. 82 shows the performance of the three neural network models (NN Ideal, NN Medium, NN Strong). The model NN Ideal predicts the data very well as it is trained on ideal data. The model NN Medium which was trained on noisy data is still able predict the ideal data very well. However, the NN Strong shows deviations from the actual values at many points. This shows that the level of noise was so high that even ideal data can't be predicted properly anymore.

When comparing the performance metrics, the NN Ideal and NN Medium are very close to each other in terms of model errors and Pearson Coefficient or R2. In contrast to that the absolute error of the model NN Strong is one magnitude of order higher; R2 drops by 4%.

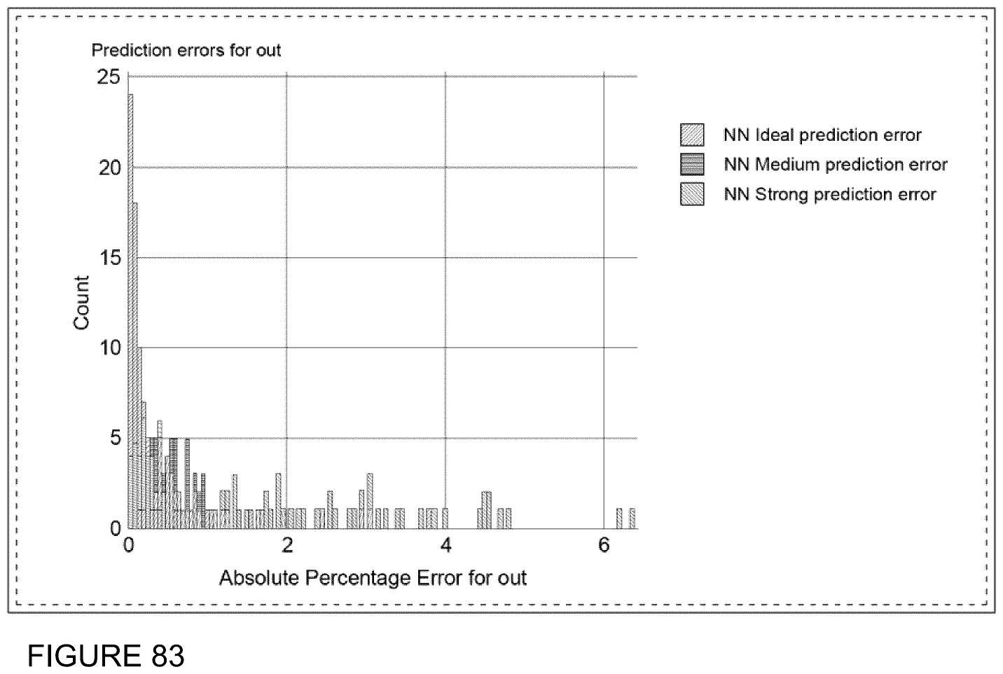

The errors of the different models are now compared using the ‘Model→Error Distribution’ step. A histogram plot of the prediction error for all three models is generated, as shown in FIG. 83. This plot clearly shows that the prediction quality drops when the training data suffers from an increasing level of noise.

### Choosing Key Design Parameters

Key parameters needed to enable a good model performance may be identified. Lots of variables are typically recorded during an engineering test, but it is important to determine which ones are valuable and which ones are only contributing noise.

The platform is configured to identify key design parameters and to understand how to use these key parameters to improve the performance of the model.

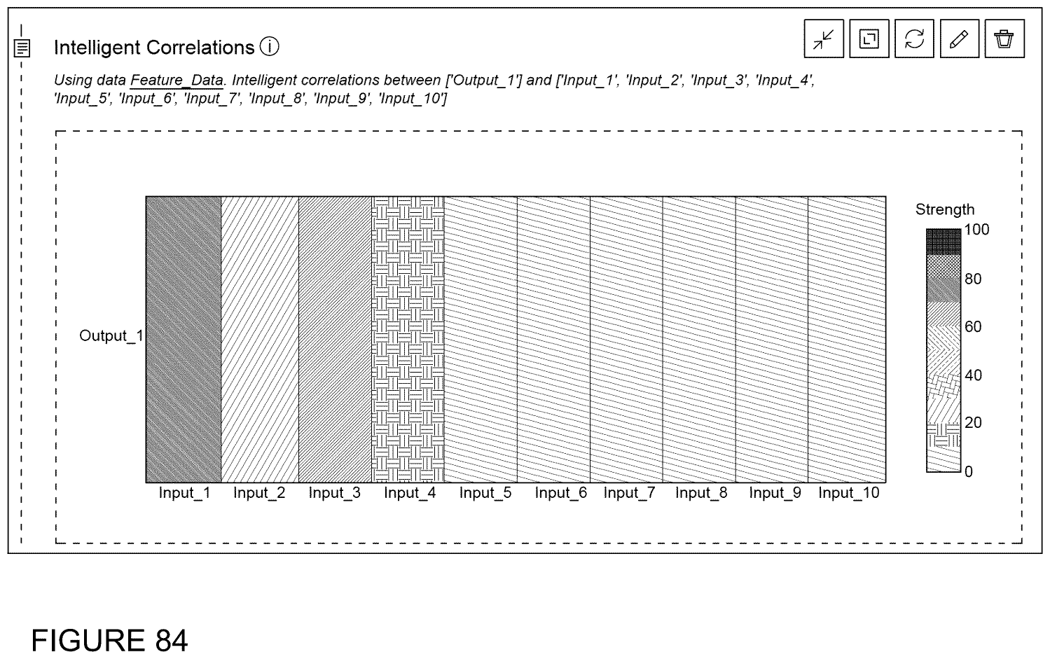

A dataset containing 10 input features and only 1 output feature is first uploaded on the platform. As shown in FIG. 84, the dataset is explored using the intelligent correlation step. Input_1, Input_3 and Input_4 show a correlation of circa 40% to the output variable, whilst the other inputs do not show a correlation. This is an early indication that these parameters might be beneficial to include as Inputs to the model whilst the others might not provide helpful information for the model to learn from.

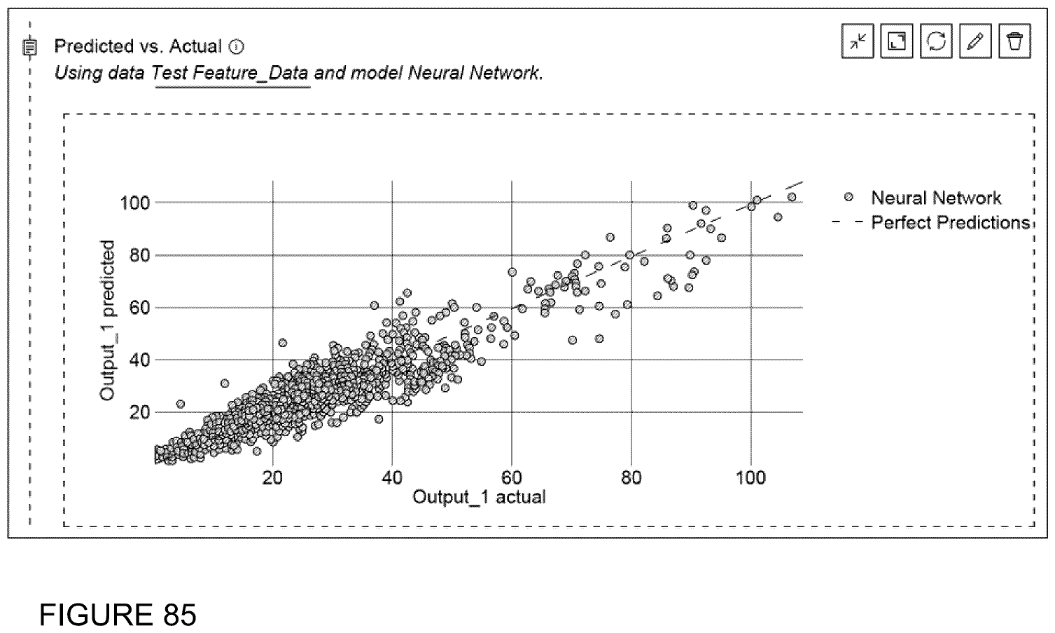

A neural network model is then trained on the training dataset and the performance of the model is shown in FIG. 85. The Neural Network model is performing well, the Pearson Coefficient is 0.93 and most of the data points lie along the dotted line for the predicted vs actual plot. This helps an end-user understand that the machine learning model has captured the relationship.

To understand which of the design parameters is having the biggest influence on the output, a sensitivity analysis step is performed. This step identifies the strength of the response of the output for each input.

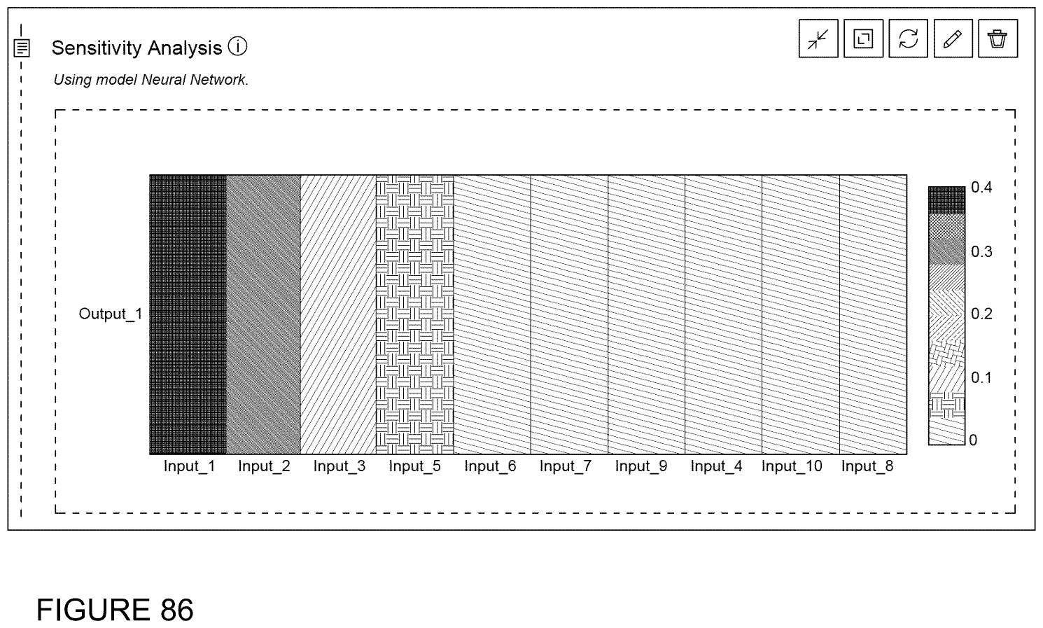

FIG. 86 shows in a visual way how much impact each input of a model has on the different outputs of this model. This plot indicates that Input_1, Input_2 and Input_3 are having the biggest influence on the output. This helps an end-user understand efforts should be focused on recording data about these inputs in future tests or simulations and still get a good prediction of a desired output.

The step ‘Apply→Explain predictions’ is now used to understand the relative importance of input parameters in affecting design performance by quantifying the relative ‘impact’ of input parameters. This may be done either as an average across the design space in which the model was trained, or for a specific new design. This step helps build confidence in models by for example confirming engineering intuitions and get an understanding of where to concentrate the design/engineering efforts to improve product performance.

Whilst Input_1 and Input_3 may be common with the conclusion from the ‘Intelligent Correlations’ plot. The ‘Intelligent Correlations’ plot suggested Input_4 was an important feature but it discounted Input_2. Whilst these plots based on a trained model suggest Input_2 is important. This is because the model can account for interactions between variables and non-linear relationships whilst the ‘Intelligent Correlations’ plot only investigate 1-to-1 relationships that are linear, polynomial, or exponential so if the relationship does not fall into that category, it will be missed by the early exploration.

A new neural network model may be trained using only the important features, such as the features input_1, input_2, input_3 as the inputs of the network. An increase in the metrics of the new network model can be seen only using the important features.

### Section 2—Explainability

Machine learning based techniques may be implemented for making models applied to 3D data explainable. Explainability may refer to the knowledge of what a machine learning model node represents and/or the importance of a machine learning model node to the model performance.

Explainability also may be used to better evaluate machine learning models or investigate what is happening “inside”. For CNN architectures, feature visualization may be used to visualize activations in hidden layers or to find patterns that cause high activations in hidden layers. Influential training samples that would change prediction significantly if removed from training data may also be found.

A surrogate model is an approximate model that can be constructed to mimic the input-output behavior of a complex simulation model as closely as possible. A surrogate model is computationally cheaper to evaluate and easy to setup as meshes are not used. Results of surrogate models are instantaneous or near instantaneous. Hence surrogate models may be used to simulate the complex models in several additional scenarios, thereby multiplying the number of data points available.

However, trusting a surrogate model may prove difficult as it is a black box and downstream effects are hard to see. A pure optimisation model may also be less trustworthy if you just get a single design and don't understand how you got there.

As described in more details in the following, several features in the Monolith platform enable an end-user to gain a better understanding of how complex black-box models applied to 3D data are working.

Uncertainty: as described in the previous section, within the Monolith platform, one option is to enable an uncertainty to be output for a particular model, such as neural network model. The uncertainty is also displayed. Uncertainty may also be displayed alongside error prediction.

As an example, if a model was trained with uncertainty and is now evaluated on a test set. for each prediction, there may be the following possible options:
The model has a low error and low uncertainty: This is the ideal situation. The model is right and is sure of itself.
The model has low error and high uncertainty: This is also a good situation. Although the model is not as sure (higher uncertainty), the prediction is still very good.
The model has high error and high uncertainty: This is not ideal, but still relatively good. The prediction of the model is wrong, but at least the model is aware of it and calculates a high uncertainty. Therefore, the user knows not to trust the model too much in this region (maybe more data is needed).
The model has high error and low uncertainty: This is not a good situation. The model makes a wrong prediction but thinks that it's sure of itself and might convince the user to trust this wrong prediction.

Simple models: simple models such as linear, polynomial regression or other physics-based models may be interpretable and/or explainable if the user can understand them. However, they may sometimes provide less accurate results as compared to deep learning models, especially when large datasets and more complex problems are available.

Reduction of complex models to simpler ones: we may train a deep learning (DL) model and approximate by simple model locally, such as for a subset or subspace of the design space. As an example, a few inputs may be fixed, and the rest of the variables may be approximated by polynomial function.

As an example, say we have 10 inputs (x0, . . . , x9), 1 output (drag coef.) and about 1000 data points. A DNN model is then trained to predict the drag coef. output. The DNN model may be accurate but not interpretable. From physics knowledge, it is known that the prediction should be a polynomial function of first two inputs. Hence, for given inputs (x2, . . . , x9) we generate polynomial function p(x0, x1): we sample (z0, z1) randomly and generate predictions for (z0, z1, x2, . . . , x9) using the DNN model and generate about 100 samples, using for example a polynomial regression approach. The resulting model can then be used to interpret relationships between x0, x1 and the output (polynomial function). In this case, the mapping between (x2, . . . , x9) and coef. of the polynomial function may still be a black box.

### Similarity Learning

Similarity learning may be combined with DNN to train a DNN for a given problem. With each prediction activations of the last hidden layer may be determined or taken and example from training data with similar activations (can be done in linear time using locality sensitive hashing) may be found.

### Disentangled Representations

Disentangled representation approach may be used to disentangle features of a model into narrowly defined variables. Latent parameters may therefore be separated and then encoded as a separate dimension. For example, parameters for each car part may be separated, such as wheel, spoiler, window, or any other car-related parameter.

### Concept Effects

It may be desirable to link high level design concepts with physical performance. Instead of predicting the target variable directly, we can predict intermediate “concepts” that are designed by human using a DL models and then fit a simple interpretable model to predict the final variable for concepts. Concepts or sub-concepts may be arbitrary defined, user defined, or computed.

As an example, an end-user may want to predict drag coefficient for a given car shape. One or more user configurable concepts may be designed. A machine learning model may then be used to quickly identify specific parametrisations of a 3D object that can be expressed in terms of the user configurable concepts. A simple interpretable model may then be used to predict draft coefficient from the one or more user configurable concepts.

Additionally, surface pressure field for each car may also be provided. A deep learning model may then be trained to predict surface pressure field, and an interpretable physics model may then be used to predict drag coefficient from the surface pressure field.

### Evaluation of Explanations

The platform is also configured to provide an evaluation of explanations. Evaluating machine learning explanations is achieved to determine if the offered explainability achieves a defined objective.

This may be done for example using the following:
Hybrid human evaluation: for each input, the platform computes n different explanations and then evaluate them by a human expert.
Quantitative evaluation: This includes for example: efficiency, stability, or perturbation analysis.
Perturbation analysis: heatmap quality may be determined by perturbation analysis. Relevant inputs according to explanations should influence prediction more when randomly changed.
Comparison to human explanation: heat maps that provide a correct explanation are manually created and then compared with the produced or computed explanation.
Stability: for non-deterministic explanations: deviations between explanations for the same input are compared for non-deterministic explanations.
Efficiency: the efficiency of the explanation may be evaluated by determining how long the computation of the explanations has taken.

### Explainability Methods

For all datasets, we can use visual explainability to highlight regions of the input with the highest importance. For the structured autoencoder (SAE) the regions are either individual points or groups of points.

Advantageously, the explainability methods are implemented in a simple fashion such as only few lines of code are needed for example in tensorflow. The platform also provides direct access to an easy-to-use library, such as SHAP library.

The explainability methods may also be applied to any AI machine learning models, including but not limited to regression or classification tasks.

The platform can implement multiple explainability methods. The explainability method includes currently available methods, such as LIME, Grad Cam, guided gradient, deepLIFT or Deep SHAP. Explainability methods may also include any other gradient, backpropagation, or perturbation-based method.

Technical details, implementation, and modifications of current explainability techniques are now provided.

LIME: to explain a model on a given point cloud, the point cloud is segmented using k-mean clustering. Perturbations are generated by replacing selected segments with average values from training data. Alternatively, any other reference point cloud may also be given.
point segmentation may be implemented as follows:
   aggregate them using voxels;
   use unsupervised learning (e.g. k-means on points+normals, DGCNN, . . . );
removing segments may be implemented as follows:
   replace a group of points with their centroid (i.e. remove the local pattern);
   replace with average coordinates from the dataset;
   swap with randomly selected sample;
   unwanted segments may be kept and noise may be added.

Deep SHAP may be implemented as follows: an SAE encoder and a (differentiable) downstream model may be converted into a single tensorflow model. A SHAP library may then be called to give use explanation (i.e. 3 numbers for each point).

Alternatively, SHAP may be used on PCA vectors and the explanation may then be transformed into the input space. This may provide faster results for some cases.

Deep SHAP and ExpectedGradients: a SHAP library may be used for both methods. The corresponding functions have a similar interface, they require:
a single trained tensorflow/keras model
an example to be explained
reference values to compare the given example (e.g. a sample from training data)

In order to use SHAP library, the whole model pipeline may be converted into a single tensorflow model (including normalization, PCA, encoder and downstream model) so that the input is a raw point cloud, and the output is a predicted target variable.

Use case examples, applied to a dataset representing a wind turbine and to a car, are now described in which an autoencoder is trained and a downstream model is then used to encode meshes. The model then outputs a predicted target variable from the latent representation.

For the wind turbines, the autoencoder uses 3 latent parameters and for cars, the autoencoder uses 8 latent parameters. A neural net with a single hidden layer is used as downstream model. For wind turbines, the hidden layer has 20 neurons, and for cars, the hidden layer 50 neurons. The quality of explanation may also depend on the quality of the model.

Several explainability methods are now evaluated, namely LIME, Deep SHAP and ExpectedGradients.

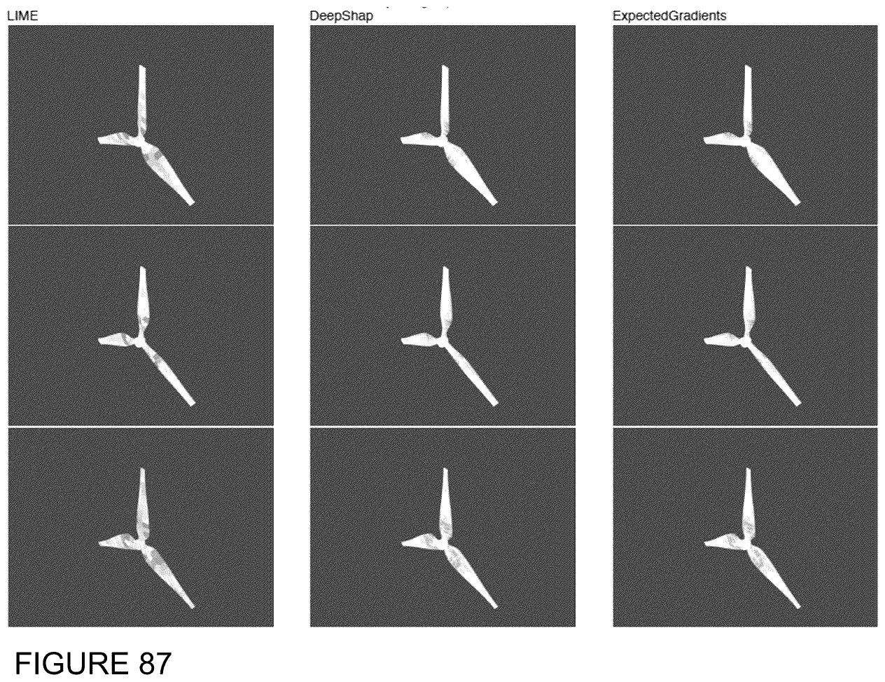

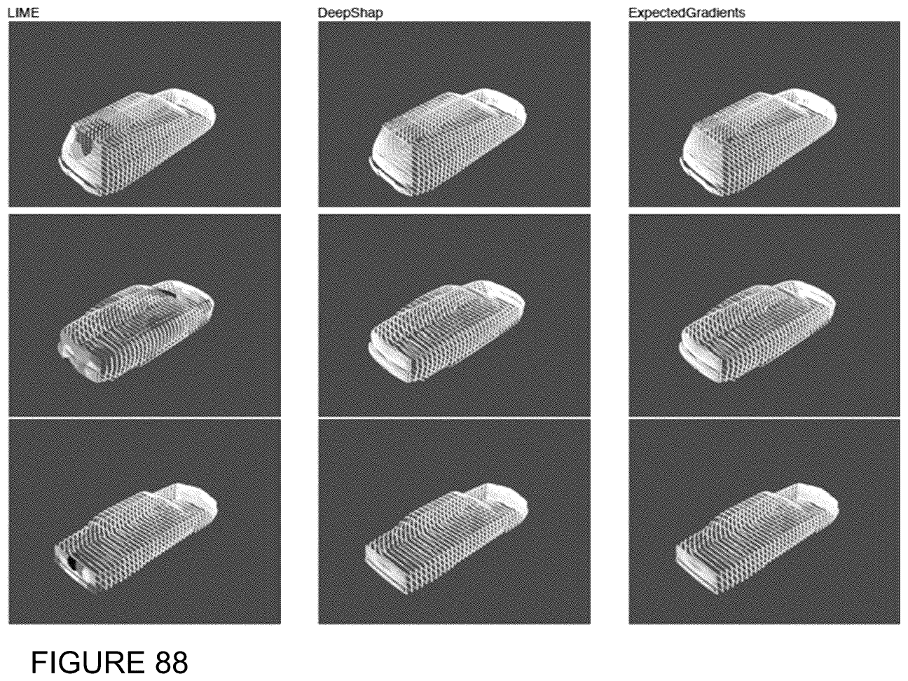

FIG. 87 provides results for the wind turbines and FIG. 88 provides results for the cars. The figures indicate if a region positively contributes, negatively contributes, or has zero contribution with regards to a target variable. For example, a region that positively contributes may be automatically highlighted by a specific colour that differs from the colour for regions that negatively contribute to the target variable.

For the wind turbines, Deep SHAP and ExpectedGradients give similar explanations, while LIME produces a slightly different explanation. According to all explanations, the most important part of the wind turbine seems to be part of the blade close to the center.

For the cars, Deep SHAP and ExpectedGradients also give similar explanations, while LIME produces a bit different explanation.

Time to compute explanation for a single mesh differs for different methods. Times estimated on the same laptop are the following:

LIME: estimated time to compute is about 15 s (using 300 perturbations), for both the cars and turbines datasets.

Deep SHAP: the estimated time to compute for turbines is between 0.4 and 1.2 s when called for the first time and about 0.1 s each following mesh. The estimated time to compute for cars is between 1.5 and 2 s when called for the first time and about 0.3 s each following mesh.

ExpectedGradients: the estimated time to compute for turbines is between 0.6 and 0.7 s when called for the first time and about 0.35 s each following mesh. The estimated time to compute for cars is between 1.2 and 1.5 s when called for the first time and about 0.12 s each following mesh.

Different methods may therefore be faster depending on the datasets. This may be for example due to a different number of points or different number of PCA components for different datasets.

We now use perturbation analysis to compare different explainability methods.

The steps of the perturbation analysis may be simplified as follows:
we segment point clouds using k-means clustering;
we remove top k % of segments with the highest importance (according to a given explanation);
this should give a higher loss value compared to random selection of segments (as we remove segments that are most important for the prediction);

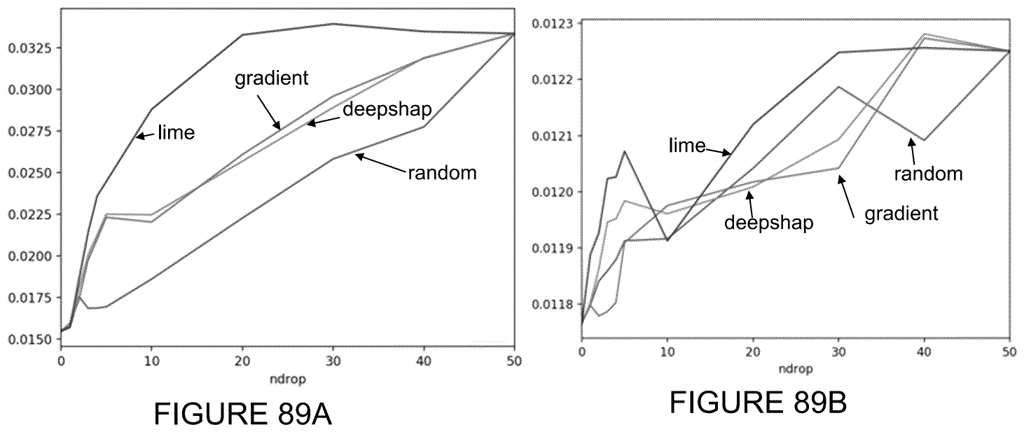

Results are provided in FIG. 89A for the cars, and FIG. 89B for the wind turbines. The methods are compared on the same sample of 30 test meshes. The plots provide the loss (higher is better) as a function of how many segments are dropped (out of a total of 50 segments).

FIG. 89A shows that the best explanation for the car's dataset is LIME according to this specific metric. Deep SHAP and ExpectedGradients are comparable for small ratio of dropped segments, which indicates that they may also find the most important segments. For larger numbers of dropped segments LIME is superior (though roughly 500× slower to compute, 1 min vs 100 ms per mesh).

On turbines the results are noisier, which may be due to small training data and overfitting. Note that if the model is bad then the explanation method generates explanations for the bad model.

Several features in the Monolith platform enables an end-user to understand why a model has made a specific prediction, for instance the platform includes a sensitivity analysis feature and an explain predictions feature.

### Explain Predictions

Explain predictions analysis enables the understanding of the relationships between inputs and outputs of the machine learning models.

This can help finding errors in a model if unexpected relationships are met; these findings may then be used to improve a specific model. It may also enable to find patterns that the end-user was unaware and improve the understanding of the data behind the model.

The end-user may configure the manipulator as follows:
Choose or select a Model on which the analysis should be performed;
Choose or select the output for which the end-user wants to run the analysis in the field Output to explain.
Choose or select if the analysis should be run on all the training data points or on a single newly defined design.

This step produces a bar plot which shows the importance of each input on the output which was selected above. This plot shows the importance of the input parameters of the selected design towards affecting the output parameter value. Green bars indicate that the input value is causing an increase of the output while red bars indicate that the input value is causing a decrease. Please note that Impact is measured as an arbitrary value for comparative analysis.

### Global Explain Prediction:

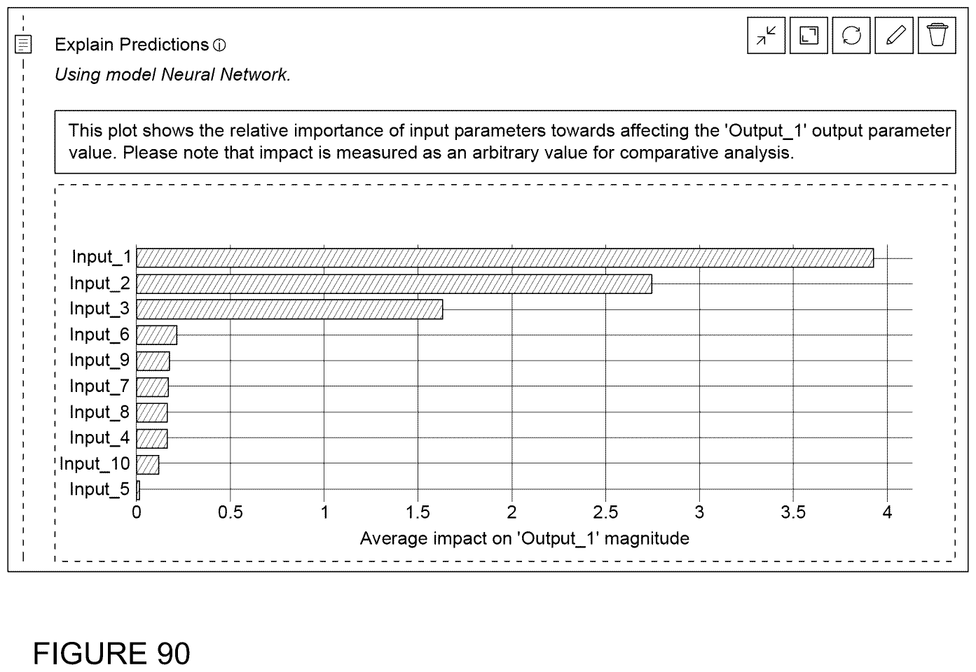

The analysis is performed on all training data points with the option ‘all the training data points’ as shown in FIG. 90. The explain predictions plot shows the importance of the inputs on the output as an average value for the entire input design space.

### Local Explain Prediction:

The platform provides the option for the analysis to be only done on a single newly defined design (a specific set of input parameter). A set of sliders (numerical inputs) and dropdown menus (categorical inputs) appears below the bar plot. With these controls the design for which the local analysis should be done may be defined. The option for only a single design may provide faster results.

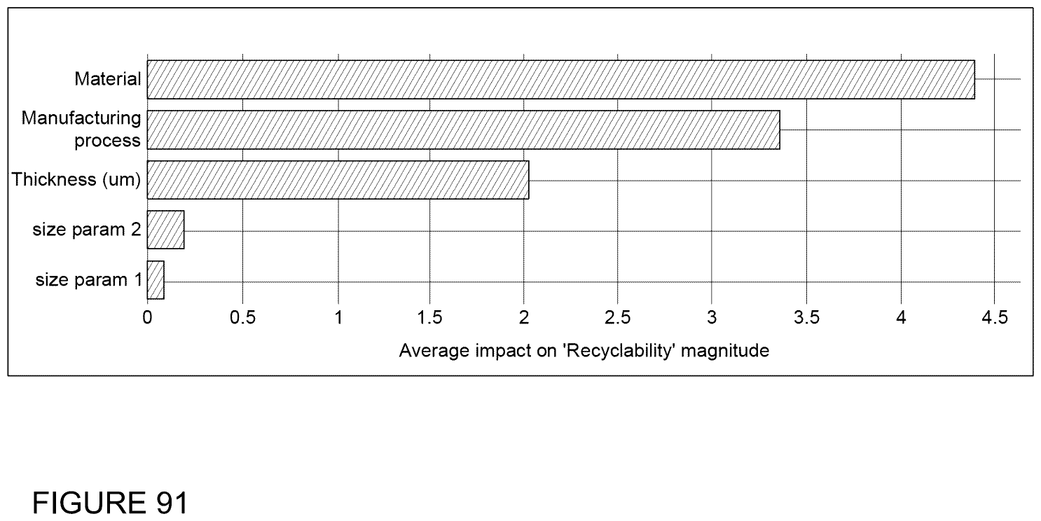

In the example shown in FIG. 91, the size param 2 has a much greater impact on the product recyclability, which was not captured by the global analysis. That is, for this specific design the input is making a significant contribution to the output while that is not the case globally.

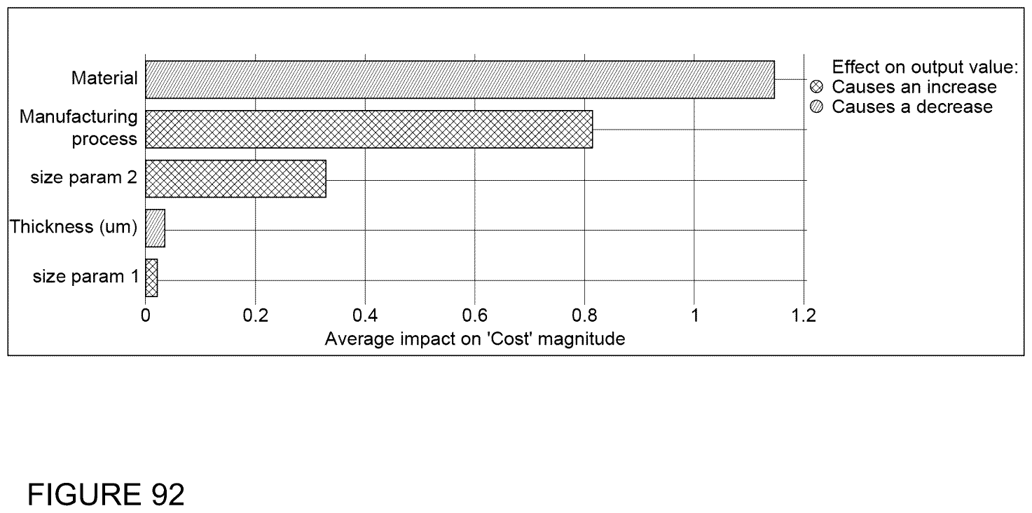

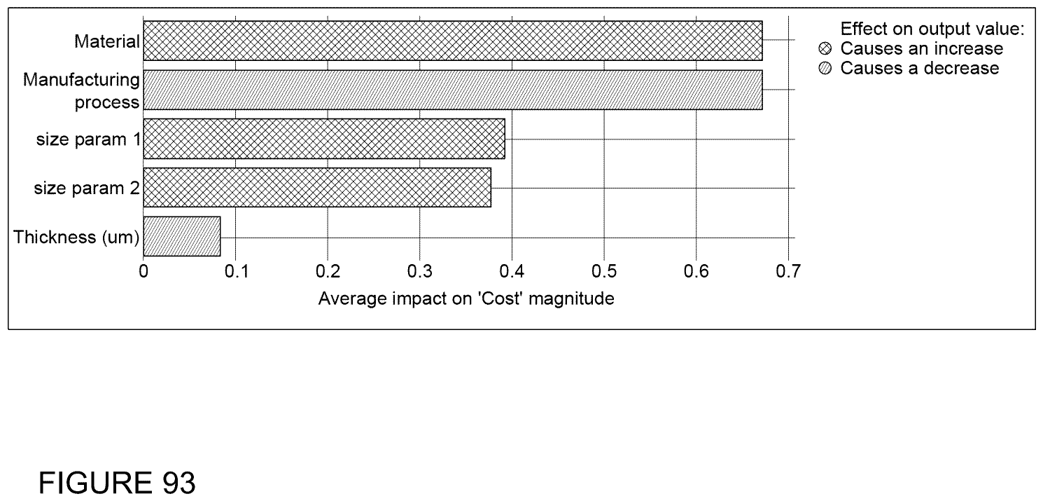

For another design, results may be completely different, as shown in FIGS. 92 and 93.

This also shows why a local analysis might be important. The global analysis gives a clue which inputs are overall (un-)important. Decisions may then be made on which inputs should or shouldn't be considered for a model. But inputs which are globally unimportant could have a significant effect in some regions of a design space. Therefore, the design space may be checked locally in regions which are of high importance for a specific engineering problem.

The explain predictions manipulator may for example use the SHAP algorithm. This algorithm is significantly different from the algorithms used for sensitivity analysis. The sensitivity analysis chooses random samples in the design space, evaluates them with the trained models and breaks down how much of the changes in the output(s) can be explained by the different outputs.

The SHAP algorithm takes a completely different approach. Instead of asking “How much do changes of my input cause changes of my output?”, the question here is “How much does my model prediction change if I use or don't use this feature as input?” Hence for this analysis different models with all sorts of input combinations are trained and the overall impact of each input is figured out from these combinations.

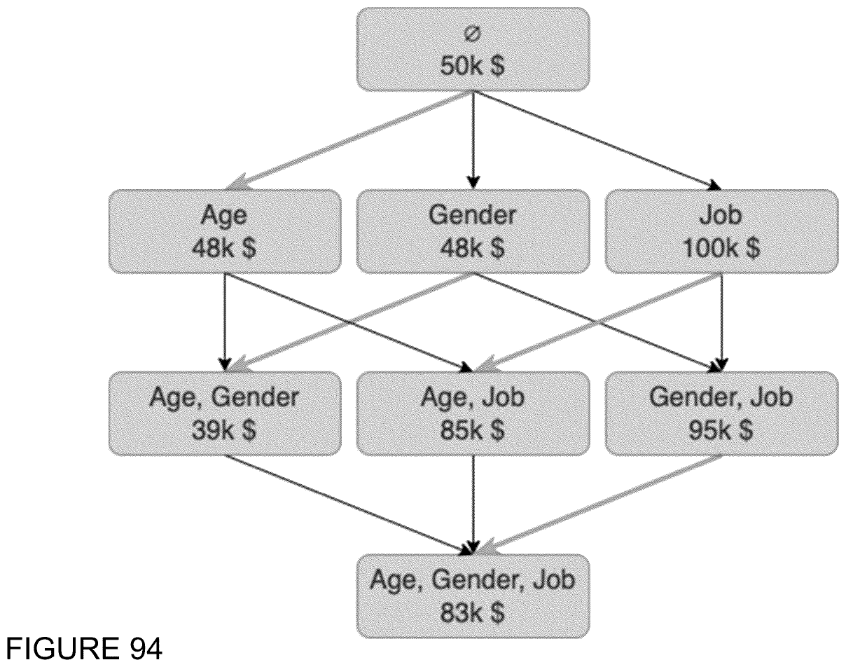

An example is provided in the diagram shown in FIG. 94. A database with information about age, gender, job and salary of people is provided. The three first ones are used as input to make a prediction on the salary. To figure out the importance of the three inputs on the output “salary” the SHAP algorithm may start from the average value of the output in the training dataset (which is 50 k $ in our example). Starting from that the SHAP algorithm evaluates how the average model prediction changes if certain variables are used as input (or aren't used). In the image below, all connections are highlighted in red which are relevant to figure out the importance of the input feature “age”. The arrows always start at models which don't use “age” as input and then compare how the model prediction changes if “age” is added as input. The overall importance would be a weighted average of all highlighted connections in the graph shown in FIG. 94.

For this example, “age” is obviously a significant input and on average is decreasing the predicted salary. In the bar plots the input “age” would appear with a red bar.

### Sensitivity Analysis

The sensitivity analysis step shows in a visual way how much impact each input of a model has on the different outputs of this model.

Sensitivity analysis helps to increase the understanding of the relationships between inputs and outputs of the machine learning models. The end-user is then helped in finding errors in a model if unexpected relationships are encountered; these findings can be used to improve the model in an iterative process. It might also help the end-user to find patterns they weren't aware of so far, improve the understanding of the data behind the model, and provide guidance on where to concentrate the design/engineering efforts to improve product performance.

The following parameters may be taken into account:
Model on which to perform the analysis;
Inputs for which analysis should be done to the field varying inputs;
Outputs for which to see the results to the field outputs;
Sensitivity analysis method, such as Sobol, Morris and Fast;
Whether only the most sensitive inputs should be shown: the manipulator uses a heat map to show the results. The number of parameters that are shown with this parameter can be limited;
Number of samples (N): the number of data points which are used to calculate the sensitivity. The higher the number the better the statistics of the analysis but the longer the step takes to finish the calculations. 1000 is the pre-filled default value.

Sobol is a variance-based method. The design space is randomly sampled with N points as specified. All these samples cause a variance in the output results. This variance is decomposed and attributed to the input variables (First order) and combination of variables (Second order). The sensitivity of the output to an input variable (or a combination of inputs) is therefore measured by the amount of variance in the output caused by that input. Therefore, the attribution of all inputs and all input-combinations add up to 1.0. Variance-based methods allow full exploration of the input space, accounting for interactions, and nonlinear responses.

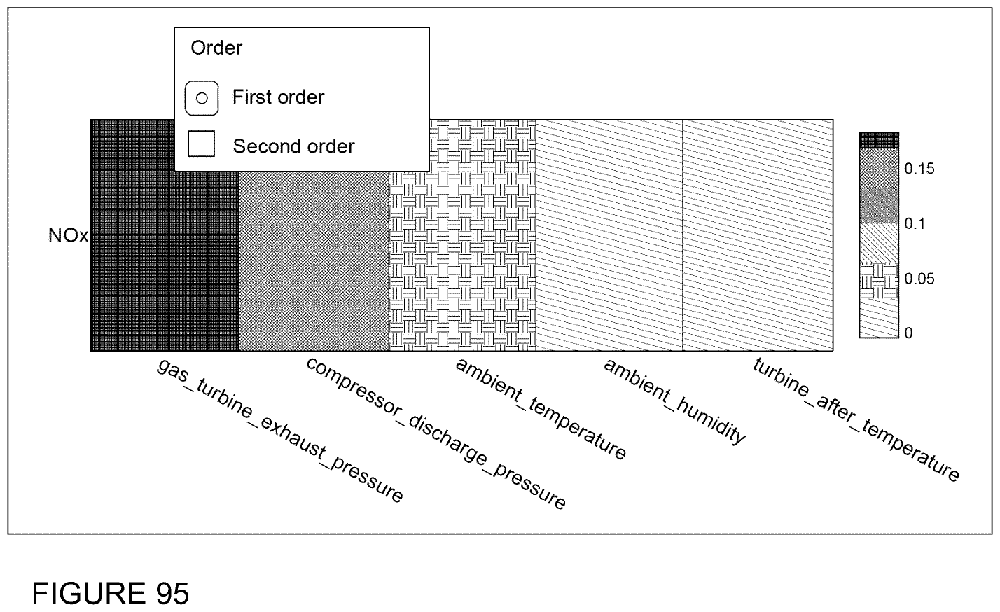

FIG. 95 shows the heat map generated after selecting to run Sobol with first order in which each row corresponds to one output and each column to an input. The colour of a box indicates how strong the sensitivity of the output regarding the input is. The deeper the red the higher the sensitivity. The numbers in the legend are the fraction of the total variance in the output attributed to an input (combination).

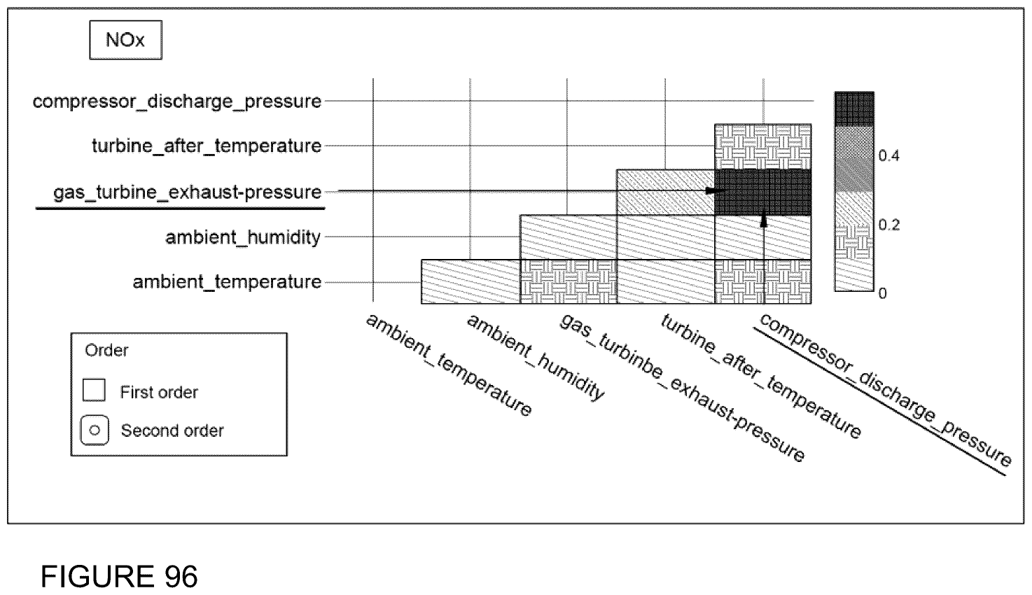

FIG. 96 shows the heat map generated after selecting to run Sobol with second order. The heat map looks different. A heat map is provided for each output separately. On the x- and y-axis are all inputs which are used for the analysis. The plot is a matrix of all possible input combinations. As the combination a-b and b-a are the same, only half of the matrix is filled. Also, the diagonal isn't filled which would be the combination of an input with itself. In the example below the dark red field is the variance in the output caused by the input combination gas_turbine_exbaust_pressure and compressor_discharge_pressure (the contribution would be roughly 0.5=50%).

The Morris method is a one-step-at-a-time method (OAT). The method starts from N random points in the design space. OAT means that starting from one of these points one input variable is changed and the resulting delta in the output is calculated. Starting from that point the next input variable is changed. This way starting from each of the N points the method moves through the design space on random paths, varying only one input at a time. For each input the average change of the output is given. That is, for Morris the legend gives absolute values in the dimension of the output.

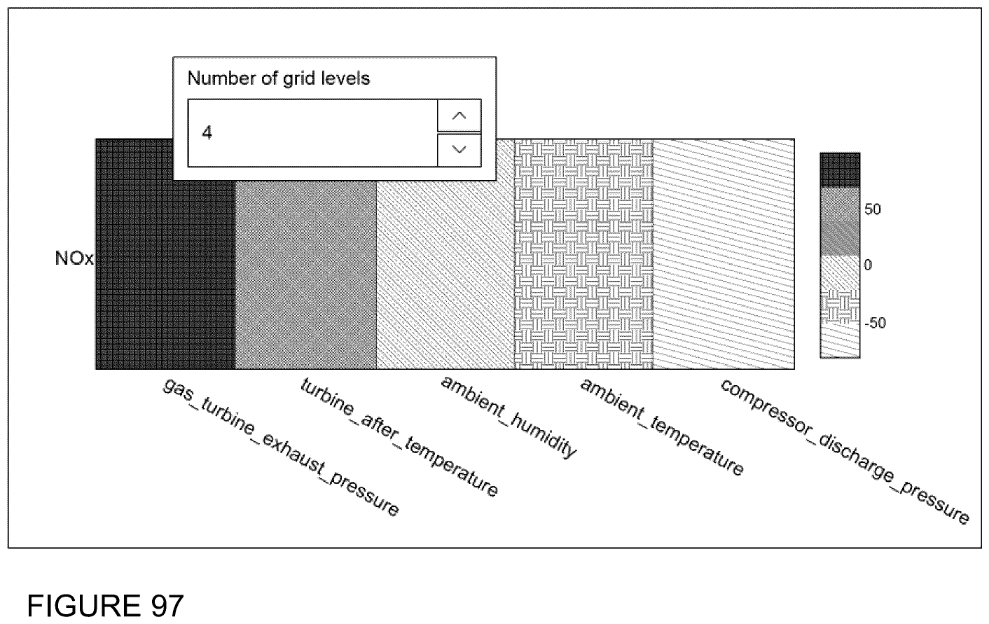

The delta values in the output can be positive or negative values depending on the direction of the output change. If positive and negative values occur for a certain input (that is, the model is behaving non-monotonic) the average value as calculated by Morris can be very small as negative and positive contributions cancel out each other. That is one of the main drawbacks of the Morris method. Additionally, as the OAT approach doesn't change multiple variables simultaneous it can't detect interactions between input variables (second or even higher order effects). An example of the output of the Morris method is displayed in FIG. 97.

The parameter ‘Number of grid levels’ controls the step size the algorithm uses when varying the inputs.

The FAST (Fourier Amplitude Sensitivity Test) method is a variance-base method like Sobol. Based on N random samples the contribution of each input to the output variance is calculated. FAST uses Fourier series to solve the problem. This is computationally more efficient than for example Sobol but limited to first order effects. The generated heat map is looking like the Sobol-generated and the numbers are to be interpreted the same way.

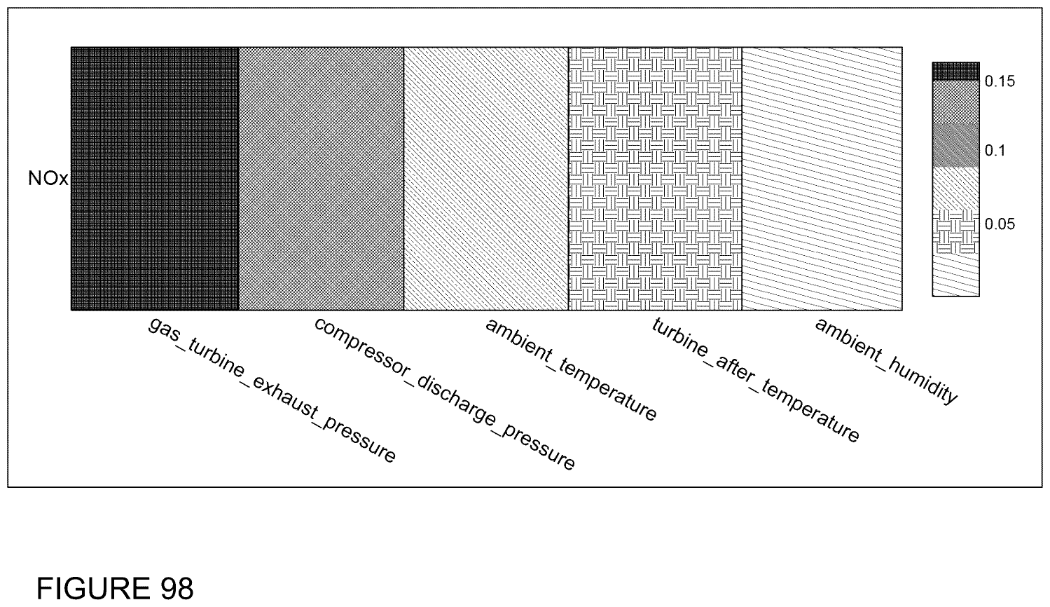

The Interference parameter (M) controls the number of harmonics to sum in the Fourier series decomposition. In practice M is frequently set to 4 which is also the pre-filled default value. If M is increased the method becomes more accurate but the computational effort is also going up. See FIG. 98.

### Section 3—DGCNN (Dynamic Graph CNN)

The Monolith platform is configured to process 3D data and to generate 3D surface field predictions using a DGCNN approach. DGCNN is a surface model that can be used for variety of problems on meshes or point clouds, such as surface pressure prediction.

Advantageously DGCNN are easy to understand, can be implemented in tensorflow and are trainable in a reasonable time.

DGCNN (Wang, Yue, Yongbin Sun, Ziwei Liu, Sanjay E. Sarma, Michael M. Bronstein, and Justin M. Solomon. “Dynamic graph cnn for learning on point clouds.” Acm Transactions On Graphics (tog) 38, no. 5 (2019): 1-12.) may be used for many mesh related problems.

Examples of applications are, but not limited to:
Surface pressure field prediction for a given shape;
Shape optimization (when combined with autoencoder);
Mesh classification or prediction of a scalar value (Od) value per mesh (requires larger training data);
Mesh segmentation (e.g. determine which part of the mesh is wind, fuselage, etc);
Problems on 2D meshes/curves;

DGCNN requires training data large enough otherwise it might overfit. The size of training data may be for example equal to roughly 1000 meshes (for some dataset 100 is enough for another 1000 is not enough). If only a single scalar is predicted per, much larger training data may be needed, for example about 10 000. If complex surface fields are predicted, about 100 meshes might be enough.

The input of each DGCNN layer may be a point cloud and the output may also be a point cloud with the same number of points, but possibly different number of features.

### DGCNN Layer:

find k nearest neighbors for each points p (using Eucl. distance);
create edge features (difference between x_p and it's neighbors, i.e. x_neighbor−x_p);
apply edge convolutions;
aggregate features to get a points cloud again ({h_p|p in P}, h_p in R\hat{ }m);

KNN: the slowest part with O(npoints\hat{ }2) complexity. O(n) version may be implemented using LSH when GPU is not available. As default 1024 points may be used to provide a compromise between accuracy and speed.

Edge features: The difference between points features and their neighbors. More precisely eᵢⱼ=concat(xᵢ, xⱼ−xᵢ). This makes part of features invariant to translations while the second part depends on the position.

Edge convolutions: two fully connected layers with shared weights across all edges (i.e. convolutions with kernel size one) may be used.

Aggregate: max-pooling over neighbors of each points may be used to aggregate features back to points.

There are several changes with available methods, including, but not limited to:
regression instead of classification;
reduced model size: leading to faster training and size reduction of training data needed;
averaging multiple models for prediction;
points clouds with different numbers of points used;
improved speed.

Further, 3D data may also be processed multiple times using multiple subsets of the training data, resulting in an improved DGCNN technique for higher-fidelity meshes.

When the number of points in the mesh is prohibitively large, multiple random subsets of training data may also be sampled to create manageable sized training batches.

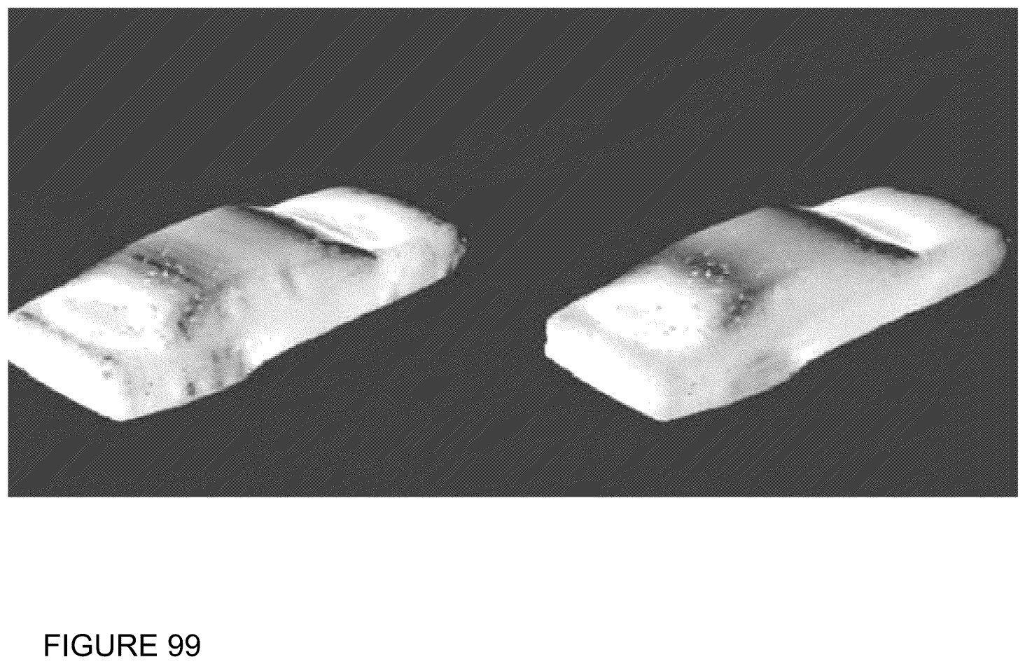

FIG. 99 provides the results in which actual (left) and predicted (right) surface pressure on the test set are compared using mean squared error (MSE).

### Averaging and Uncertainty

The problem with DGCNN is that we need to have a fixed number of points for the model input that is not too large (currently 1024). To make it work with larger meshes we sample a random subset during the training (can be seen as a data augmentation). Then for prediction we evaluate the model many times for subsets of points, so we end up with at least k evaluations per point. Finally, we average the predictions per point. This can be also used to estimate uncertainty or risk by computing standard deviation for each point. Alternatively, stochastic dropout or bootstrap may also be used.

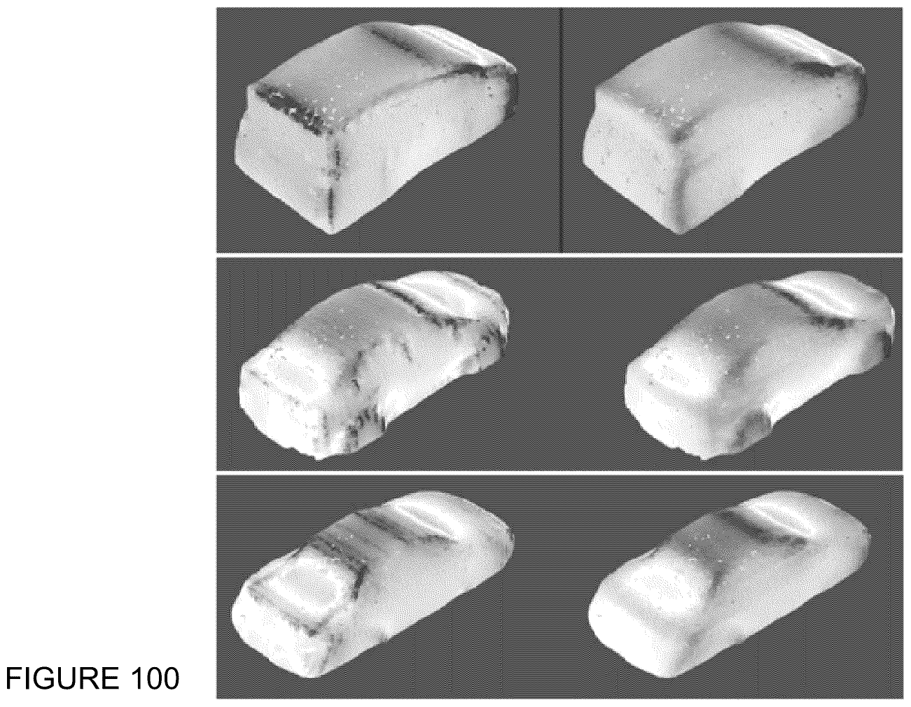

FIG. 100 provides further results in which actual (left) and predicted (right) surface pressure on the test set are compared.

Training data may also be augmented by applying random transformations. Advantageously augmenting the training data results in a more efficient DGCNN. Accuracy may also be improved on smaller datasets.

The method may also be used to estimate uncertainties by making predictions for different subsets of input points and estimating the standard deviation of prediction for each point.

### Section 4—Structured Autoencoder (SAE)

Autoencoders are AI models which automatically parameterise a dataset of 3D designs (Umetani, Nobuyuki. “Exploring generative 3D shapes using autoencoder networks.” In SIGGRAPH Asia 2017 technical briefs, pp. 1-4. 2017). The autoencoder learns to compress the geometric shape information of the design into a small number of latent parameters. The latent parameters are then like the DNA of the 3D designs: every design has a specific set of latent space values; and similar unseen designs can be generated by exploring new sets of latent space values.

Autoencoders have a wide range of applications, including for example design space exploration, shape optimization, interpolation between two shapes, parameterisation, or clustering.

In the Monolith platform, autoencoders may be used for at least the following applications: generating new 3D designs along with instant performance prediction and/or finding an optimal 3D design.

The autoencoder for structured meshes is more restrictive and can only be used on meshes which have the same structure. As an example, the meshes may have the same number of vertices per mesh, and the vertices may be sorted in the same order.

As described previously, the Monolith platform includes an autoencoder for structured meshes. The geometries of a 3D dataset can therefore be encoded on a latent space. The platform then returns both an encoder model (to parametrise a geometry) and a decoder model (to generate a geometry from numerical parameters).

An auto-encoder is a mathematical tool that shares some similarities with a neural network as it contains different layers. When training an auto-encoder, the main aim is to be able to “compress” the data from the full geometry (X, Y, Z for every point) to a relatively small set of parameters, and then being able to “decompress” the data back to the initial geometry. As a result, an auto-encoder will be made of 2 parts: (i) an Encoder, which transform the geometry into parameters, and (ii) a Decoder, which transforms the parameters into geometries.

As shown in the diagram in FIG. 59, the main layers are:
an input layer (in blue), which gathers all the inputs (generally X, Y, Z coordinates) of the design;
a latent layer containing the latent parameters (in red). The size of this layer corresponds to the number of desired parameters to represent all 3D designs;
an output layer (in yellow), which is similar to the input layer.

If the latent layer is too small, it won't be able to “compress” the designs properly, and the reconstructed designs (output) will not be similar to the initial design (input layer). The aim is to find a number of parameters as small as possible, but big enough to contain all the information of the design. These parameters can then be used for new predictions or optimisation, as shown in Section 1 above.

The monolith platform provides a simple interface in which the parameters of the structured autoencoder are easy to setup. While the structured autoencoder model learns to parametrise and accurately generate a geometry, the model's scoring metric may also be displayed to the end-user in real time.

As shown in FIG. 60, a screenshot of the setup of the structured autoencoder platform is shown. The following parameters may be entered or inputted by the end-user:
the number of “Training Steps” defines the length of the training phase. More steps means a longer training time, but the model will be likely to converge and be more accurate.
the “Number of Latent Parameters” is the number of parameters chosen to compress the geometries. There will be a trade-off here as a higher value will probably provide better accuracy, but the model will require more data to be trained properly.
there is an option to “Stop model early if it converges”. It might be that after a number of steps, the model already converged. However, the model will continue to train for longer while it's not necessary if asked for more steps. Hence, ticking this option will stop training a model when it has converged and will prevent from waiting unnecessarily.

Once trained, the model may consist of an encoder and a decoder:
the encoder can be used to transform a geometry in a list of latent parameters.
the decoder can be used to generate a new geometry from a list of latent parameters. These parameters can be set manually or identified through an optimisation process.

To assess the quality of an autoencoder, an “Assess autoencoder” step can be used to calculate and look at the reconstruction error. The autoencoder can also be used for the “View Decoded Designs”, where new geometries can be created instantaneously by modifying the latent parameters, as described in Section 1 above.

Input data of the autoencoder may be a structured point cloud.

Pre-processing: for a given structured point cloud we first concatenate x, y, z point coordinates into a single vector of length input_dim=3*n_points. Input vector is then transformed using Principal Component Analysis (PCA) to reduce its dimension to few hundreds numbers (typically from say 60 000 to say 500).

Advantageously, the algorithm uses PCA has a pre-processing step which reduces dimension before training. Additionally, smoother shapes may also be generated.

More PCA components may be used to reduce reconstruction error.

An improved Wasserstein Auto-encoder is used, in which an extra regularisation term has been added to have roughly multivariate standard normal distribution of latent vectors. The same WAE is used for stacked AE.

Evaluation: MSE reconstruction error (distance between points). For interpolation, generative properties, etc manually by looking at results. Note that for training we minimize MSE in PCA space (sensitive to the number of pca components).

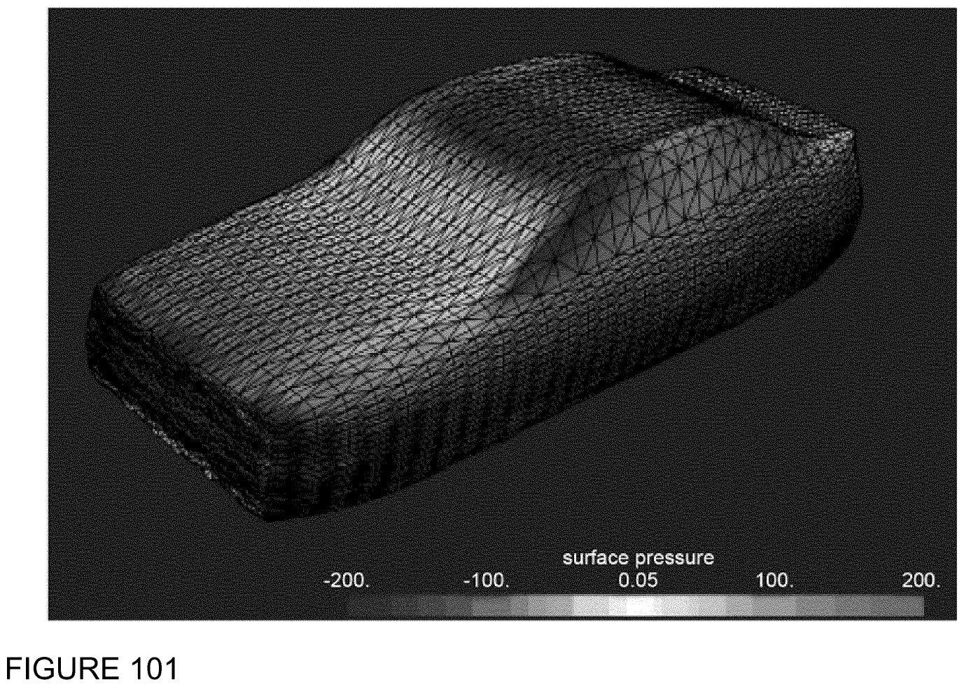

FIG. 101 shows results from shapenet cars. Interpolation between randomly generated cars (older model without pca)

### Principal Component Analysis (PCA)

A problem with structured autoencoder before adding a PCA as pre-processing step was that when a given structured meshes had too many points (say more than 10000) training would become slow. This is because training time scales linearly with the number of the points in a mesh (i.e. n×more points→n×longer training). This may be explained by the number of weights between input/output and hidden layers, where input_dim=output_dim=3*npoints.

PCA is then used as a pre-processing step to reduce the input_dim before training, thus training time does not depend on the number of points anymore. For example, a mesh with 20 000 points will have input_dim=3*20 000=60 000, which will be reduced to the given number of PCA components, such as between 300 to 500. As a result, speed may be increased between 10 to 100 times depending on the number of mesh points.

In addition to faster training, meshes generated with a model that uses PCA may be smoother, even if the model was not fully trained or if there is overfitting.

A potential limitation of the current implementation is training data size. If both number of meshes and the number of points are too large, PCA might not fit into memory. A possible solution may therefore be: 1) reduce the number of points before training, 2) only use a sample from training data or 3) use a memory efficient alternative of PCA.

The number of PCA components used may also be configurable depending on the datasets to be processed. For most datasets, 500 PCA components may be used. In case the size of the dataset is smaller than the requested number of components (n_pca), then the number of PCA components may be set using the following: n_pca=(1−k)*n_meshes as the number of PCA components may not be higher than number of mesh points. For more complex shapes (e.g. encoding multiple structured meshes at once), the number of PCA components may also be increased.

A suitable value for the number of PCA components may also be determined automatically.

The method may also be implemented to further split training data into a smaller training and validation set and then select the smallest number of PCA components with a reconstruction error low enough on the validation set.

To encode PCA vectors we train an autoencoder with a single hidden layer per encoder and decoder, as now described. Both encoder and decoder are fully connected neural networks with a single hidden layer. We use tan h as activation. Alternatively leaky relu may also be used.

```
encoder = tf.keras.Sequential([
  layers.Dense(nhidden, **dense_params),
  layers.Dropout(rate=rate),
  layers.Dense(latent_dim, **dense_params) ])
decoder = tf.keras.Sequential([
  layers.Dense(nhidden, **dense_params),
  layers.Dropout(rate=rate),
  layers.Dense(x_size, **last_dense_params) ])
```

Using a single hidden layer provides an improved solution that is more suitable for small datasets and that also allows faster training.

### Section 5. Unstructured Autoencoder (UAE)

Unlike SAE, UAE can work directly with unstructured meshes without the need to structure meshes. As a result, it can work with much general and complex shapes, possibly with a different topology. A prize for that may often be a more complicated model and longer training time.

In the Monolith platform, a number of variants are available, such as: 1) a non-convolutional variant and 2) a convolutional variant. The two variants differ only in a relatively small change in the neural net architecture. More generally, the convolutional variant may be more suitable for shapes with repetitive pattern while the non-convolutional variant may be more suitable for shapes with different scales.

The main idea is to represent shapes from a certain category (e.g. cars, spoilers, . . . ) using a vector of parameters (latent vector) with the following properties:
latent vectors of similar shapes are close to each other,
latent vectors have roughly multivariate normal distribution,
all latent vectors represent realistic shapes similar to the training data.

### 5.1 Model Overview

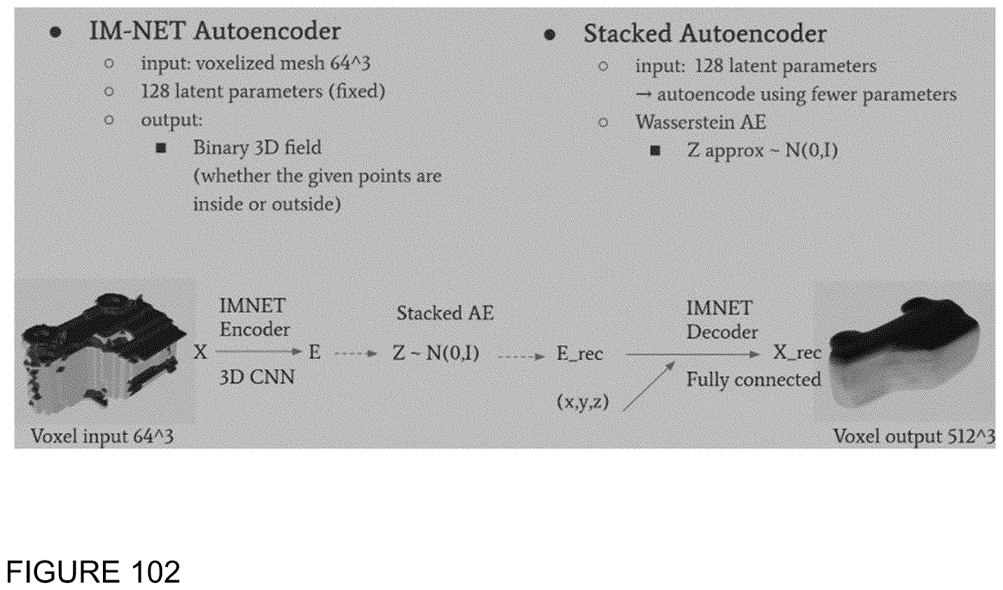

FIG. 102 describes the architecture of the UAE. As shown, to train an Unstructured Autoencoder (UAE) meshes are first voxelized in 64\hat{ }3. Then an autoencoder, such as IM-NET (as provided in Chen, Zhiqin, and Hao Zhang. “Learning implicit fields for generative shape modeling.” In Proceedings of the IEEE/CVF Conference on Computer Vision and Pattern Recognition, pp. 5939-5948. 2019), is trained and encodes the voxels into a vector E of fixed length 128 numbers. Finally, a stacked autoencoder is trained that further encodes a vector E into the latent vector Z with given number of parameters.

A voxelization algorithm, as described in more detail below, converts the given mesh into a binary 3D array of size n\hat{ }3, where 1 indicates interior and 0 indicates exterior. This may be challenging for complex meshes where it may be difficult to determine whether a location or point is inside or outside. This may especially be true for meshes that are not watertight, where it is needed to fill small holes (e.g., a car with open window).

Another implementation may also use a point-based architecture without requiring voxelization.

An IM-NET encoder is given 64\hat{ }3 voxels that are encoded into a vector E using a 3D convolutional neural network (CNN). Each consecutive layer reduces spatial dimension and increases the number of features. Note that the voxel resolution may be limited by GPU memory.

An IM-NET decoder can be seen as a binary classifier that for a given the latent vector E (that represents the shape) and point P with coordinates (x, y, z) predicts a probability of the point P being inside the generated shape. Advantageously, an implicit decoder may compute a prediction for any (x, y, z) coordinates and thus with a trained model generate voxels in higher resolution than the training data (e.g. 512\hat{ }3).

An algorithm to generate a mesh with a trained implicit decoder may also be used.

A latent GAN may also be used to generate meshes. This generates more realistic meshes than sampling E directly, but does not include an encoder. Hence the latent GAN may also be replaced with a stacked Wasserstein autoencoder (WAE) that shares many required properties (e.g. normal distribution) and that includes an encoder.

Meshes are first normalized so that point coordinates are inside a unit cube (i.e. [0,1]\hat{ }3). Two variants may then be implemented: 1) cube normalization, in which each mesh is scaled independently or 2) minmax scaling, in which all meshes are considered, or for larger datasets only a sample of the mesh.

Before voxelization, meshes are pre-processed so that there are no triangles larger than a given threshold. Finally, meshes are voxelized and exported as for example a NumPy array or in HDF format.

The main IMNET autoencoder is then first trained. Then the stacked AE is trained using the trained IMNET encoder from the previous step to generate latent vector E for each voxelized mesh from the pre-processed data. Then the model is trained to encode E into latent vector Z.

A non-convolutional model training time for stacked AE is negligible compared to IMNET training (and GPU is not needed). As a comparison, with the convolutional UAE we use a different SAE architecture, and the training time is substantially comparable to IMNET training.

After training, the model is optimized for inference and exported together with the whole model pipeline including pre-processing and voxelization. The optimized model may only be used for inference.

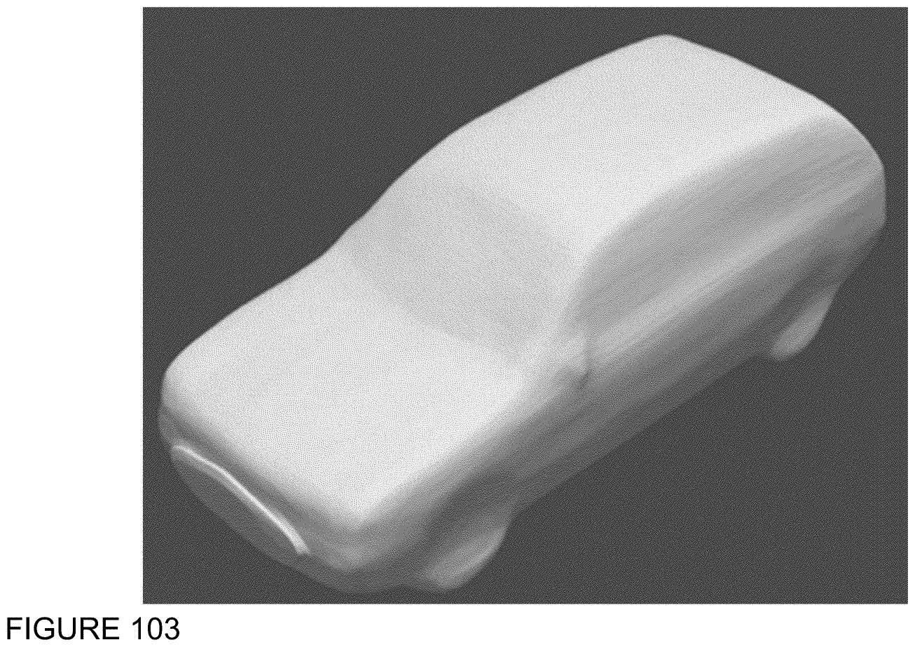

FIG. 103 shows an example of a 3D object exported using the above UAE model.

In comparison with current UAE techniques, an improved UAE technique is provided. Key aspects of the improved UAE technique include one or more of the following:
A stacked autoencoder architecture is used, such as a Wasserstein stacked autoencoder, in which a first autoencoder is used to encode a 3D input data into a first set of latent vectors, and a second autoencoder is then used to encode the first set of latent vectors into a second set of latent vectors;
Wasserstein loss function is implemented;
Wasserstein regularization is implemented to provide a pre-determined dimensions of the latent vectors;
Improved method to extract mesh from implicit field in O(n\hat{ }2);
A different voxelization algorithm is implemented;
The UAE has been written and optimized for Tensorflow 2, which provides another performance gain;
Improved mesh optimization algorithm is implemented to refine the generated mesh.

In particular, the second ‘stacked auto-encoder’ may be configured to be much faster to train than the first. A decoupling of these stages in the software platform allows important hyper-parameters like the latent dimension to be varied and tested quickly without the need to retrain the whole auto-encoder.

An hybrid DGCNN may also be implemented, in which a DGCNN is followed by 3D CNN. As a result, this approach does not require voxelized meshes. It is also memory and computationally efficient.

An extra regularization term may also be added to achieve smooth surfaces.

Further optional features may include any one or more of the following:
An optimum number of latent parameters are automatically determined;
Multiple stacked AE are trained, and one is selected based on a target variable or downstream application;
Progressive training is implemented;
The encoder is frozen and only the decoder is trained;
Multiple GPU training is implemented.

### 5.2 Voxelization Algorithm

A voxelization algorithm may also be used to generate training data. There may also be a different algorithm to extract a mesh from a trained implicit decoder.

Before voxelization, meshes are first scaled into a voxel space [0,n]\hat{ }3, where n is the voxel resolution (such as n=64). This is followed by mesh pre-processing to make sure there are no faces smaller than a single voxel. Finally, a multi-scale voxelization algorithm is used to generate voxels (a binary 3D array), where each value indicates whether the given position is located inside or outside.

Meshes are first normalized such that all points are inside a unit cube (i.e. [0,1]\hat{ }3). Either minmax or cube scaling may be used. Some datasets may also require a custom normalization.

As loading thousands of meshes to compute min and max may take too much time, an estimated min and max on a smaller sample (e.g. 200 meshes) may be determined. Min, max are computed for each x, y, z coordinate. A possible problem with using smaller sample is that some meshes may contain points outside the unit cube (these points are ignored later).

Minmax scaling is invertible and generated meshes may be unnormalized to the original scale. For minmax, meshes are assumed to have the same position and substantially similar scales. Minmax is sensitive to large outliers, such as for a mesh with twice the size of an average mesh, thus large outliers may be automatically removed from the training data.

Cube normalization may also be used. Each mesh is scaled to the unit cube independently. As compared to minmax, the voxel space is used more efficiently. A disadvantage is that this normalization is not invertible and for the generated meshes the exact scale may not be known. However, in some application the scale may be known by the end-user.

Before voxelization a normalized mesh is first scaled to the voxel space of the given voxel resolution, i.e. points are scaled into [b,n−b]\hat{ }3, where b is the border size to make sure that meshes do not touch the borders of the voxels space, i.e. voxels on the borders are all/mostly empty as having voxels predicted as inside on borders of the voxels space causes problems (holes) after running Marching cubes algorithm.

After normalization, when needed, faces may be subdivided so that there is no face larger than the size of a voxel.

The main problem with voxelization is that we may encounter meshes with holes (e.g. car with an open window) that would cause that the interior would not be filled properly. In order to smooth such shapes, a multi-scale voxelization may be used that combines multiple voxelization in different resolutions.

The base volexization and multi-scale voxelisation algorithms are now summarised.

Algorithm: Base Voxelization
given: pre-processed point cloud P, voxel resolution n;
create n\hat{ }3 voxels with zeros (marked as exterior);
for each point from P round its coordinates to integer value and set the corresponding voxel to one (marked as interior);
fill the space between:
   iterate over all y,z values (n\hat{ }2 values):
find the first (x_min) and the last (x_max)×voxel coordinate with filled voxel;
if x_min<x_max, fill all voxels between two voxels;
   do the same for y and z;
   compute an intersection of 3 fillings in x, y, z directions.

Algorithm: Multi-scale voxelization
given: pre-processed point cloud P, voxel resolution n;
if n>n_min:
   compute multi-scale voxelization for n/2:
   up sample voxels into n\hat{ }3 resolution;
   smooth voxels (using binary erosion);
compute base voxelization for resolution n;
compute union or two voxelizations;
smooth voxels (using binary dilation and erosion).

The generated voxels may be visualized either directly using a library that can plot volumetric data or by extracting a mesh using for example a marching cubes algorithm.

### 5.3 Stacked WAE

Stacking autoencoders includes: 1) training an AE to encode input X into latent vector Z followed by 2) training another AE that encodes latent vectors Z into different latent vectors Z′ with lower dimension.

A stacked autoencoder approach may be used instead of latent GAN due to one or more of the following:
normal distribution of latent vectors;
Wasserstein regularization may be used;
generating random shapes to enable design space exploration;
number of latent parameters can be easily adjusted;
a latent dimension can be changed by retraining only the stacked AE with negligible training time compared the full model;
better generative properties;

Further, as compared to latent GAN, a more stable training may be available. GANs are often difficult to train and suffer from various problems such as mode collapse that would be highly unwanted for design exploration.

Wasserstein AEs (WAE) are superior to Variational AEs (VAE) in several aspects: 1) they can be generalized to various prior distributions (not restricted to normal distribution), 2) instead of KL-divergence they minimize Wasserstein distance, which is a weaker distance, 3) they allow deterministic encoders and 4) they are easier to implement (no need to change the training, just adding an extra regularization).

Assuming we have a trained IMNET model, we use it to encode the whole training data into latent vectors E. Once they are exported, we train the stacked AE to further encode latent vectors E into latent vectors Z of dimension given by the user.

Training may be performed in two steps: 1) encoder in pretrained, such as with only Wasserstein regularization loss, so that latent vectors are close to a normal distribution and 2) the entire AE is trained with both reconstruction and regularization loss.

Unlike latent vector E, Wasserstein regularization gives roughly k-dim. normal distribution. This may be useful for generating random shapes (sampling) or exploring the design space. Without prior knowledge of the distribution of the latent space this may not be possible.

A different architecture is used for non-cony and cony UAE.

### Non-Conv UAE

A simple fully connected neural net with a single hidden layer is used for both encoder and decoder.

encoder=tf.keras.Sequental([layers.Dense(nhidden, **dense_params), layers.Dropout(rate=dropout_rate), layers.Dense(z_dim, **denseparams)]) decoder=tf.keras.Sequential([layers.Dense(nhidden, **dense_params), layers.Dropout(rate=dropout_rate), layers.Dense(x_size, **last_dense_params),])

### Conv UAE

Conv UAE is a modification of a previously proposed architecture (Peng, Songyou, Michael Niemeyer, Lars Mescheder, Marc Pollefeys, and Andreas Geiger. “Convolutional occupancy networks.” In European Conference on Computer Vision, pp. 523-540. Springer, Chain, 2020). A less deep architecture that more suitable for the complex engineering problems and the datasets of the Monolith platform is used. As conv. UAE is less deep and overall latent dimension is higher, we use a deeper stacked AE to compensate this: encoder with 3D CNN followed by two dense layer and decoder with three dense layers. Note that more experimentation is needed to find the optimal architecture for conv. UAE.

encoder tf.keras.Sequential([layers.Reshape([zres, zres, zres, conv_zdim]), layers.Conv3D(4*conv_zdim, [2, 2, 2], [1, 1, 1], padding=‘same’), layers.Reshape([−1]), layers.Dense(nhidden, **dense_params), layers.Dropout(rate=dropout_rate), layers.Dense(z_dim, **dense_params)]) #decoder z=Input(shape=[z_dim]) d1=layers.Dense(nhidden, **dense_params)(z) d1_drop=layers.Dropout(rate=dropout_rate)(d1) d2=layers.Dense(512, **dense_params)(d1_drop) d2_concat=layers.concatenate([z, d2], axis=−1) d3 lavers.Dense(zres**3*conv_zdim, **last_dense_params)(d2_concat) decoder=Model(inputs=z, outputs=d3)

The main idea of the convolutional UAE is that instead of encoding shapes into a single latent vector z, we can encode them into a 3D grid of latent vectors (latent grid). The latent grid is a tensor of shape [n, n, n, f], where n is the spatial (voxel) resolution (usually n=4 or 8) and f dim. of the latent vector z_ijk.

An implicit decoder then interpolates between latent vectors. To generate a prediction for the given position p=(x, y, z) and latent grid z_ijk, we take the corresponding voxel for the given position p and corresponding 8 latent vectors from the latent grid. Then we compute z by using trilinear interpolation of 8 latent vectors. The rest is basically the same as in “non-convolutional” implicit decoder.

Using latent grids has an advantage that each latent vector only encodes a smaller part of the whole shape, which is less complex, thus less deep architecture is needed. There is also possibility to encode more complex shapes (possibly whole scene with many shapes) as each latent vector from the grid represents only a small part of the whole shape, which is less complex compared to the whole shape. Most importantly, there is invariance to translations (to a certain degree), which makes it possible to use data augmentation methods, and apply the model to datasets with for example repetitive patterns.

### 5.4 Mesh Extraction Algorithm

To generate a mesh using a trained decoder a naive approach is: 1) create n\hat{ }3 voxel grid, 2) evaluate model for each (x, y, z) from the grid, 3) run a marching cubes algorithm to extract mesh from the voxels. A problem with this algorithm is that it requires n\hat{ }3 evaluations of the decoder, which is impractical for higher resolutions.

A faster algorithm replaces step (2) with more efficient iterative algorithm that requires only O(n\hat{ }2) evaluations of the decoder for voxel resolution n\hat{ }3 and uses a numerical algorithm to further refine the generated mesh (implemented only for non-conv UAE).

Algorithm: Generate Voxels from Implicit Decoder
1. Input:
   implicit decoder d(Z, x, y, z), where Z is latent vector and x, y, z point coordinates (0<=x, y, z<=1);
   required voxel resolution n (assuming n=2\hat{ }k) and full_grid_max_depth parameter.
2. Generate full grid:
   m=min(n, 2\hat{ }full_grid_max_depth):
   iterate over all m\hat{ }3 voxels and evaluate decoder for each x, y, z position.
3. if n<=m: return the generated voxels
4. for d in range(full_grid_max_depth+1, max_depth+1):
   generate voxels Vd initialized with zeros;
   find all voxels from V_(d−1) that are close to the implicit surface;
   evaluate decoder only on corresponding voxels in Vd.

Evaluating only voxels near the surface provides O(n\hat{ }2) evaluations of the decoder, which is a significant speed up for higher voxel resolution. This is further optimized so that evaluations are done in batches. The optimal batch size may also depend on the used GPU.

For very high-resolutions, part of the algorithm that runs in O(n\hat{ }3) may be dominant (allocating n\hat{ }3 NumPy array). In that case this could be further speed up using one or more of the following: 1) rewriting critical parts to another suitable programming language, such as Cython, 2) using multiprocessing, 3) using sparse voxel representation or 4) using a different algorithm to extract the mesh from the implicit decoder.

### Mesh Optimization

A postprocessing algorithm may also be implemented that further improves quality of the generated mesh.

### Algorithm:

input:
   implicit decoder d(Z, x, y, z)
   mesh generated from d(Z, x, y, z)
subdivide mesh faces to get smaller triangles
for i in range(n_iterations):
   for each point P:
   compute gradient of d(Z, x, y, z) wrt. (x, y, z) at P
   move point P closer to the implicit surface using a numerical method (implicit surface is given by d(Z, x, y, z)=0.5)

An advantage of this algorithm is that it can produce high-quality meshes from low-resolution voxels. Thus, overall time to generate mesh of the same quality is lower. A mesh after post-processing is smoother compared to meshes without the implementation of the mesh optimization algorithm.

### 5.5 Neural Net Architecture

To train Unstructured Autoencoder (UAE) meshes are first voxelized in 64\hat{ }3. Then we train an autoencoder (IM-NET) that encodes the voxels into a vector E of fixed length 128 numbers. Finally, a stacked autoencoder is trained that further encodes vector E into the latent vector Z with given number of parameters. This section describes the architecture of all model part for both UAE variants: non-cony UAE and cony UAE.

As shown in FIG. 102, an IM-NET encoder is given 64\hat{ }3 voxels that are encoded into a vector E via a 3D CNN. Each consecutive layer reduces spatial dimension and increases the number of features. Note that the voxel resolution is limited by GPU memory here.

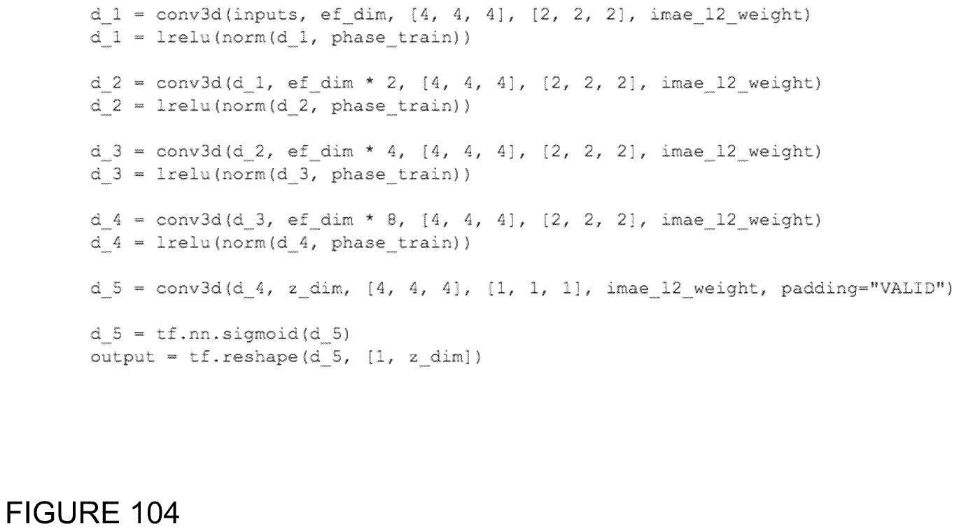

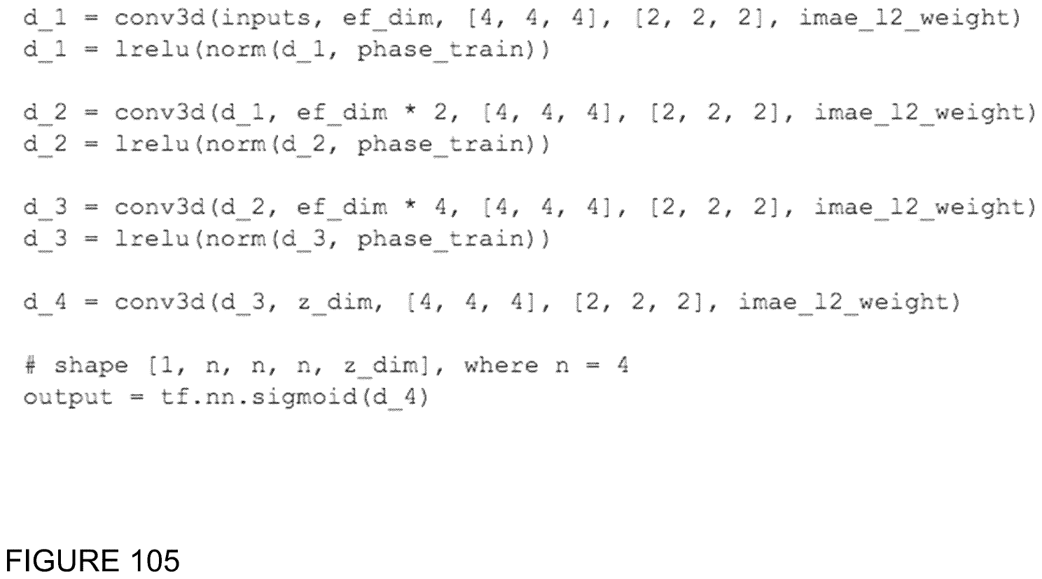

Encoder for both UAE variants is identical except that non-convolutional variant is one layer deeper. FIG. 104 shows an example of a script of a non-convolutional UAE encoder. FIG. 105 shows an example of a script of a convolutional UAE encoder.

IM-NET decoder can be seen as a binary classifier that for given the latent vector E (that represents the shape) and point P with coordinates (x, y, z) predicts probability of the point P being inside the generated shape. Implicit decoder has an advantage that we can compute prediction for any (x, y, z) coordinates and thus with a trained model generate voxels in higher resolution then our training data (e.g. 512\hat{ }3).

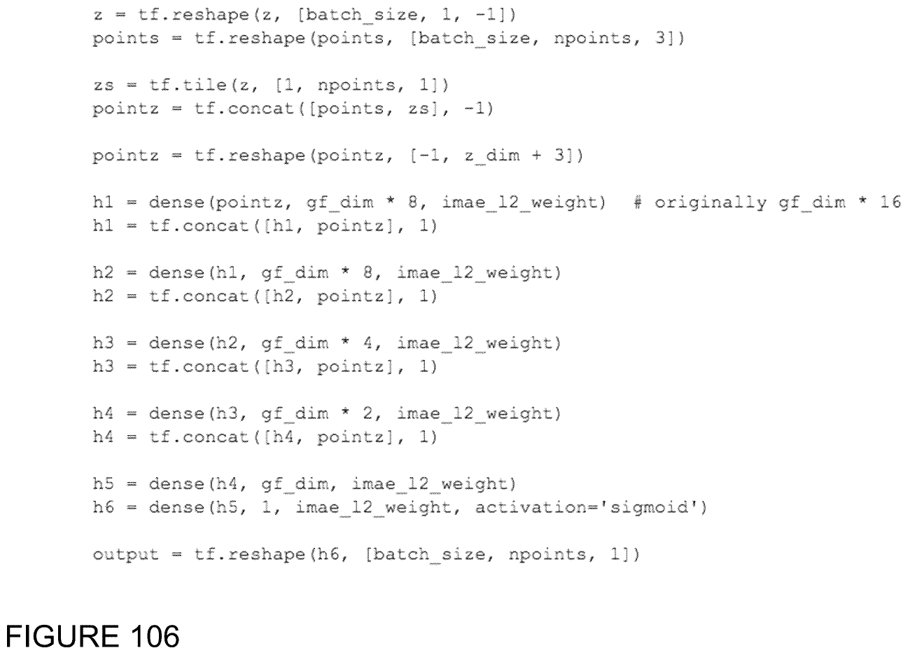

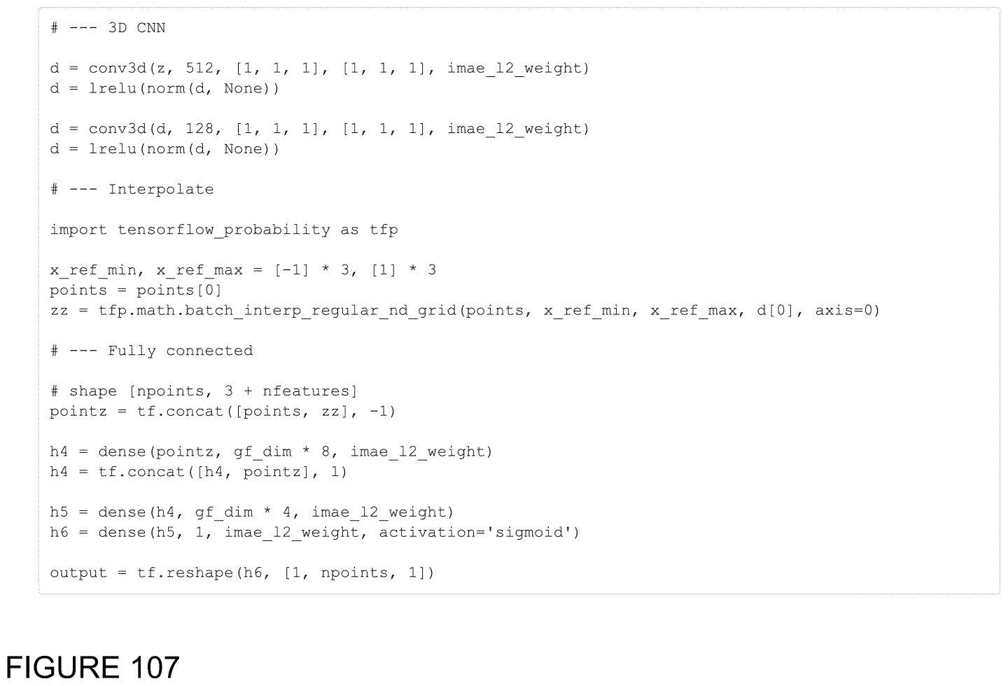

FIG. 106 shows an example of a script of a non-convolutional UAE decoder. As input we are given latent vector Z and point coordinates with shape [npoints, 3]. Both are concatenated and used as an input of a sequence of fully connected layers with skip connections. FIG. 107 shows an example of a script of a convolutional UAE decoder.

A problem with 3D CNNs is that they require a huge amount of (GPU) memory.

For training, we may use batch of sizes 1 to fit the whole training sample into memory. Encoder input is always 64\hat{ }3 voxels (input voxels). As implicit decoder can produce voxels in any resolution, we can use higher resolution for output voxels (e.g. 128\hat{ }3), but as default output voxels=input voxels. Using higher resolution would only make sense for large datasets, where we hope to achieve highly detailed generated shapes.

As evaluating implicit decoder on all output voxels would be slow, we sample k=16000 voxels. To make training more efficient, voxels close to the surface are sampled with higher probability. Unlike IMNET, we resample voxels after each epoch, which should give superior results and prevent overfitting on smaller datasets.

Training sample may be for example a tuple:
input: 64\hat{ }3 voxels (encoder input with fixed resolution)
points: (x, y, z) coordinates (scaled to [0,1]) sampled from output voxels
voxels may be in higher resolution than 64\hat{ }3, it was tested on 1283 (but training is slower)
values: a binary value for each sampled voxel (1=interior, 0=exterior)

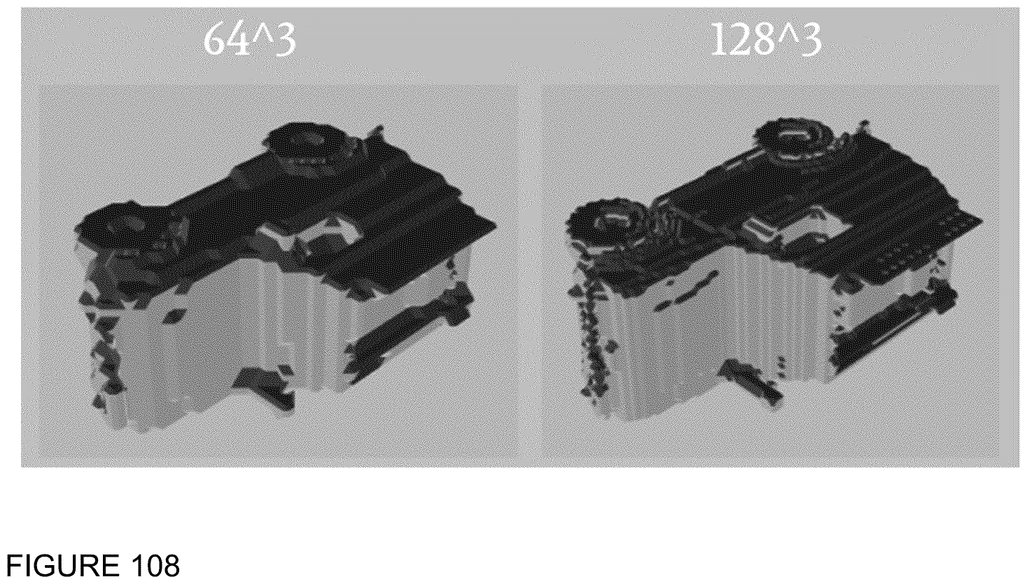

FIG. 108 shows results with the input data consisting of 64\hat{ }3 voxels and of 1283 voxels respectively.

For faster training point sampling from voxels may also run in parallel on CPU, while training is done on GPU. This makes training significantly faster. Multiple GPUs may also be used.

### 5.6 Results

### Evaluation

During the main training we minimize reconstruction error between voxel input and its reconstruction. Unlike structured AE, the reconstruction error is MSE between implicit fields, not point coordinates. To compare two different 3D autoencoders, we can compare 1) the original mesh and its reconstruction (this is the only property that can be measured though its not sufficient to compare two models as we can always design an autoencoder with zero reconstruction error) and 2) other properties that include quality of interpolated and generated meshes, there are not good metrics to measure this thus it requires manually looking at results.

For some applications we can also measure quality of the model on a downstream task.

### Reconstruction Error

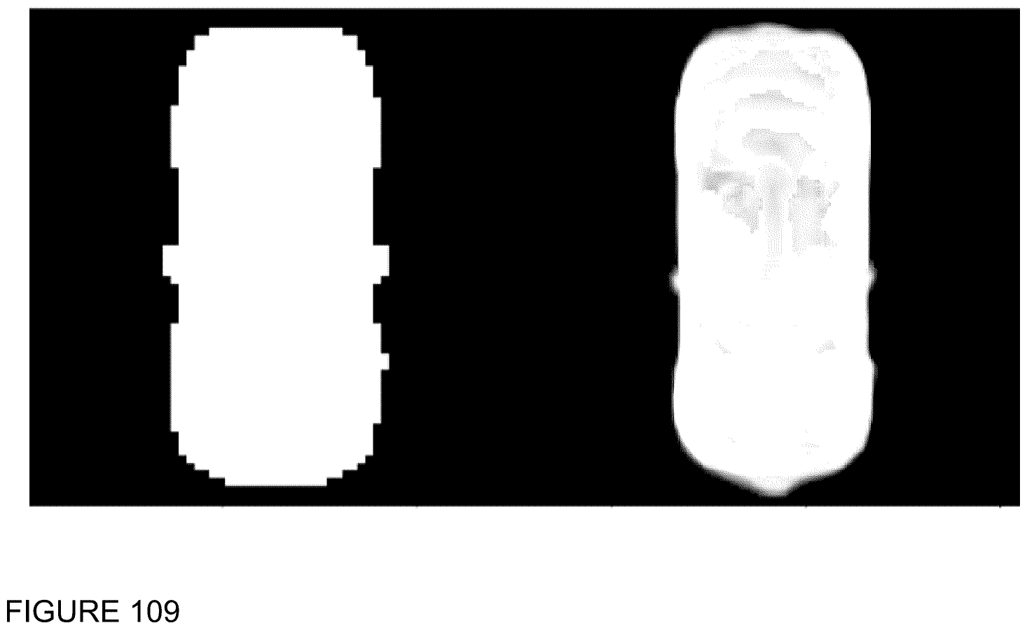

There are more ways to compare original and the reconstructed error. For different applications different measures may be more suitable:
Mean square error (MSE): minimized during the training. For inference we compare the original voxelized mesh (64\hat{ }3 or 128\hat{ }3) with the output field with values in range [0,1]. During the training MSE is estimated on a sample of points/voxels on usually −16 k points (instead of 64\hat{ }3=260 k).
   FIG. 109 shows the actual (left) and reconstructed (right) 2D slice.
Chamfer distance: distance between two points clouds. For each point find the nearest point from the other mesh and vice versa. Then use the average distance. This approximates the “average” distance from two surfaces.
Intersection over Union (IoU): Intersection volume over union volume of two voxelized meshes, also known as Jaccard Index, may be used. The intersection over union may be calculated by calculating an area of overlap between two voxelised meshes divided by the area of union of the two voxelised meshes. In our case this may be similar to MSE (if we rounded the prediction to 0/1 and normalized by volume of the union).

Several other metrics may also be used for the evaluation of the autoencoder, such as, but not limited to, the following:
Wasserstein distance or point clouds;
Light field descriptor (LFD).

### Experimental Setting

Datasets from Shapenet cars are used, including various car shapes: regular cars, sport cars, old cars, unusual cars or bus and different topologies, such as including spoilers. The datasets may include about 7 k raw meshes, not pre-processed. Spoilers may also include about 10 k raw meshes.

The datasets may be split into training and test input data, as described in Section 1. An extra validation dataset may also be used.

Meshes may be normalized into [0,1]\hat{ }3 cube either using: 1) each mesh separately or 2) MinMax scaling. Separate normalization may be more common and usually gives better results. The problem is that we loose information about scale that may be important for some use cases (e.g. surface pressure prediction). That is not a problem with MinMax scaling. On the other hand, MinMax may also not produce as good results and may cause problems with shapes of different scale (e.g. spoilers dataset).

We trained the model on roughly 300 k steps followed by 500 k for stacked autoencoder. For cars we used from 10 to 128 latent parameters and for spoilers 3 to 10 parameters.

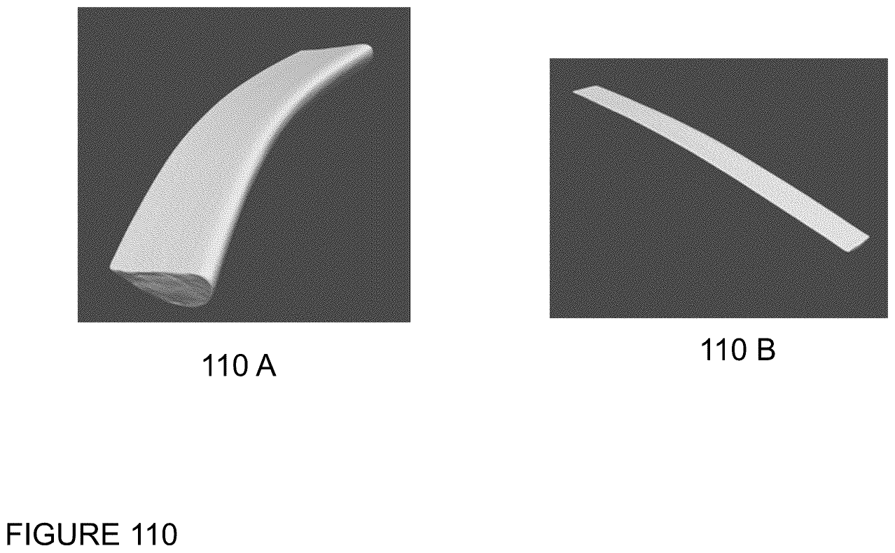

FIG. 110A provides an image of the results on spoilers with an interpolation between random shapes and FIG. 110B provides an image of the results on spoiler with an interpolation from large to small.

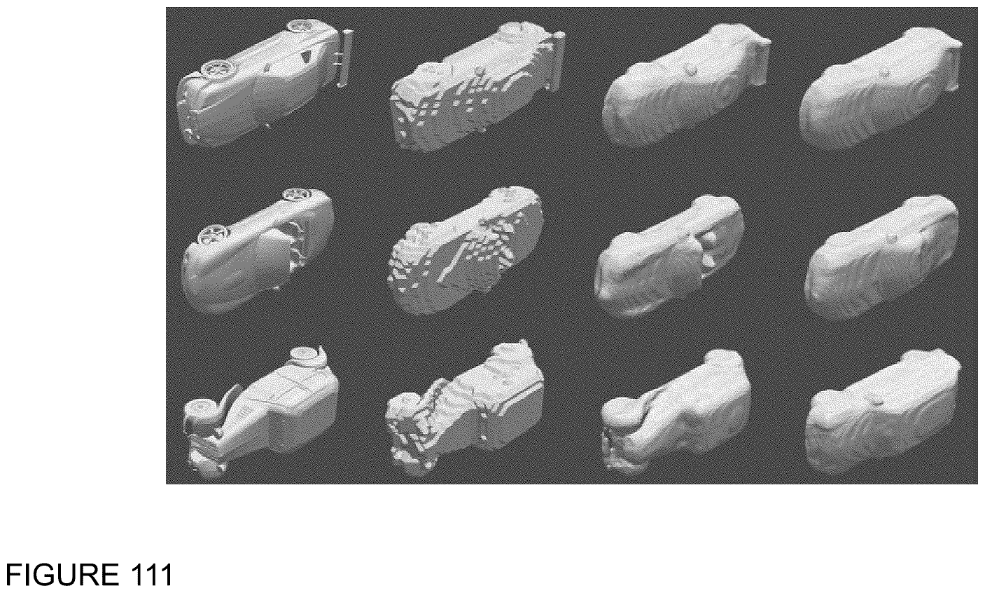

Results are provided in FIG. 111. Each row represents a different car: common car (top), less common car with no roof (middle) and very uncommon retro car (bottom). In columns the following results are provided for: the original raw mesh, voxelized mesh 64\hat{ }3 (AE input), reconstruction with 128 parameters and reconstruction with 10 parameters (in this order).

We can see that for the model including 128 parameters the reconstructed mesh is much more accurate compared to the model with 10 parameters. Even rare cars that have limited presence in the training set, such as only once in the training set, are able to be reconstructed.

The model including 10 parameters is able to represent the most common shapes. More uncommon shapes are approximated with more common ones. A closed roof is for example observed for the case of the middle car. This may be either wanted on unwanted, depending on the application (i.e. if we are interested in uncommon shapes/outliers or we want to get rid of them).

### Interpolations

Real shapes interpolation: To interpolate between car A and car B we first voxelize them and encode into z_a and z_b. Then generate a sequence z_t=t*z_a+(1−t)*z_b for the given number of steps. Finally, we decode each z_t to get the interpolated shape.
Random shapes interpolation: Unlike interpolation between real shapes, we generate z_a and z_b randomly.

Random sampling (128 parameters): random latent vectors and for each vector may be generated. As latent space has roughly normal distribution, a vector close to zero corresponds to the most common car, a vector with larger size to more uncommon shapes and too large vector usually does not represent anything similar to the training set. As an example, to generate more interesting/uncommon shapes, we may generate Z˜Uniform(Sphere_r) where Sphere(d,r)={z in R\hat{ }d: ∥z∥=r} and d=128, r=3.

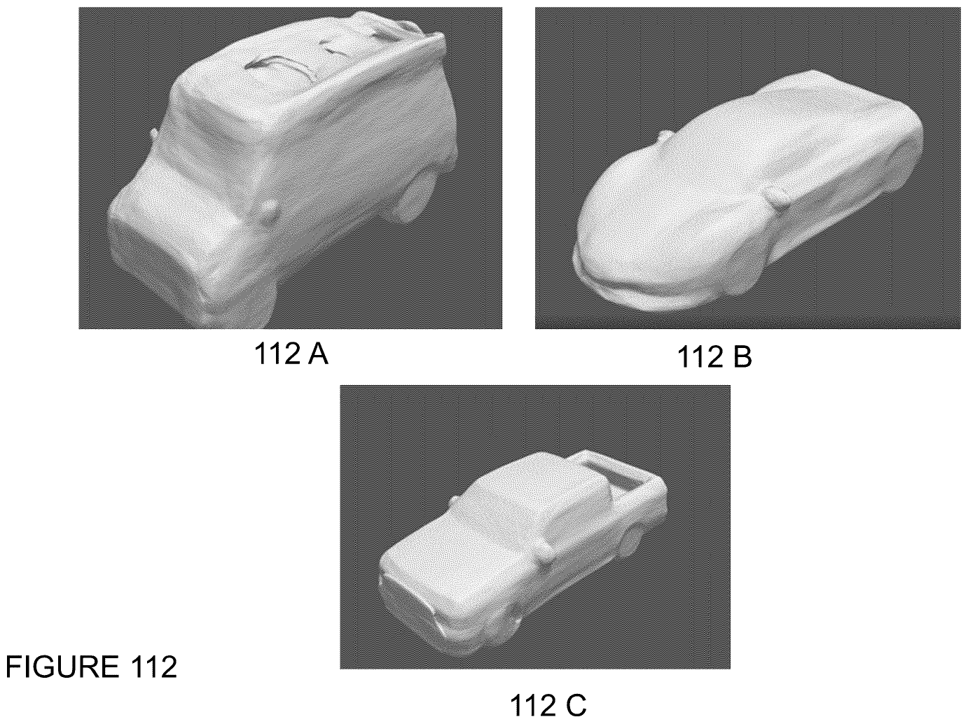

We can see that produces shapes are sometimes noisy/not realistic cars as shown in FIG. 112. This is caused by 1) setting r too high and 2) having too many parameters (so that often latent vectors do not represent any realistic car, see conclusions).

Design Space Exploration (10 parameters)

Here we trained a model with only 10 latent parameters. Unlike sampling with 128 parameters here we simulate “sliders”, where only a single parameter is changed at the time.

We can see that all generated shapes represent a realistic shape similar to the training data. On the other hand, with only 10 parameters the model is not able to represent more uncommon shapes (e.g. a bus or a retro car).

Reconstruction vs. generative properties trade-off: We can see that the quality of randomly generated shapes is not very high for large number of parameters. On the other hand, the reconstruction error is much lower with more parameters. The problem is that for high-number of parameters the latent space may be too sparse (i.e. for most of latent vectors z, there are not training samples anywhere near).

A higher number of parameters is usually better for accurate reconstruction and interpolations between real shapes. Smaller number of parameters is usually better for generating random shapes, design exploration and shape optimization.

Unstructured autoencoder may also be automatically tested on multiple datasets.

### Section 6—Shape Optimization

Shape optimization may be one of the ultimate goal for most engineering companies. The problem is finding the optimal shape for the given target function(s) and constraints. Practical examples are aerodynamic shape optimization (drag coef.) or box shape optimization.

The common approach is to start with an initial (e.g. random) shape and then iteratively improve it using gradient descent. Alternatively other optimization method may be used, e.g. genetic/evolutionary algorithms or Bayesian optimization.

Parametrization: First we need a parametrization (usually 5-10 parameters) that determines all possible shapes (design space). If such parameterization is not available, an autoencoder may be trained to find one. This may often be needed for more complex shapes.

Surrogate models: In practice, actual values of the optimized function are not known (as it would require running e.g. expensive physical simulation). Thus, instead of optimizing a given function, we may approximate a target function with a ML model or surrogate model. A problem with this approach may be that the surrogate model may not be accurate in some areas of the design shape and the optimization algorithm may produce arbitrary bad shapes. However this may be solved when considering model uncertainty or risk.

Surrogate Optimization with CNN Model

A first shape optimization is based on Shapenet cars autoencoder and a CNN to predict surface pressure for the generated shapes.

Structured car meshes are encoded using 10 latent parameters. The CNN predicted surface pressure only for the top part of the mesh that could be easily transformed into an image.

For optimization a stochastic algorithm is implemented. The idea is that at each iteration solution z_t is randomly modified to create a population of e.g. 50 candidates, then for each candidate we evaluate the CNN model and select the best solution.

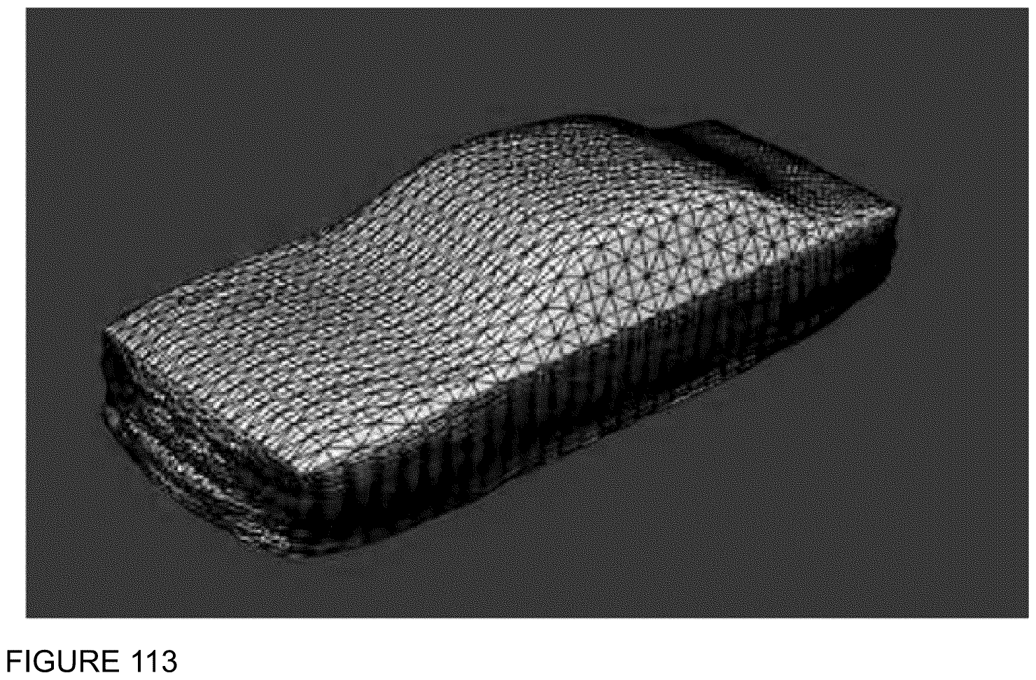

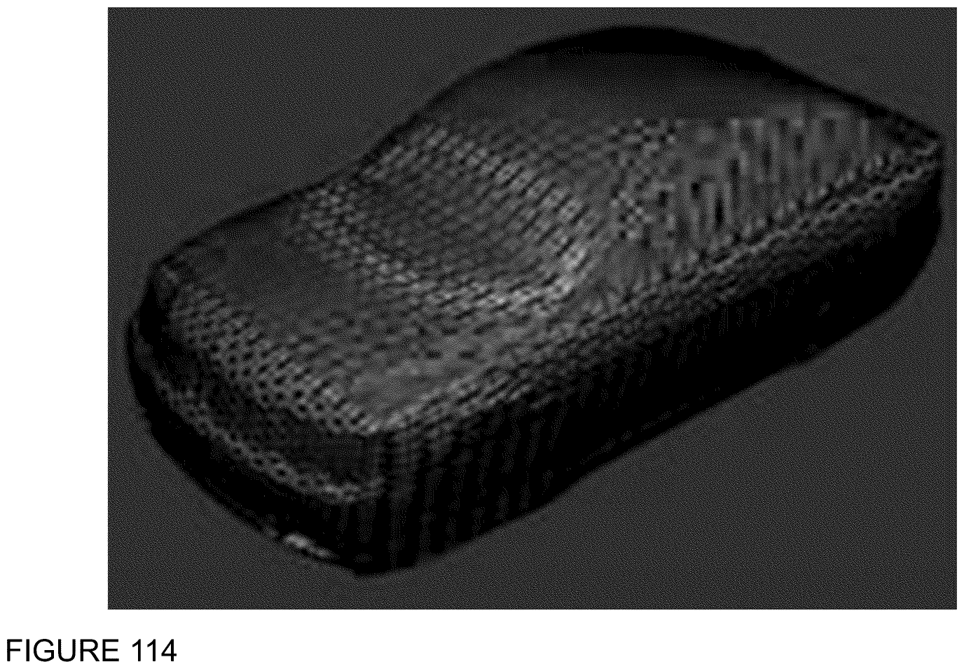

FIG. 113 provides an image of the reconstructed shape of a car. FIG. 114 provides the results of the surface pressure prediction.

Surrogate Optimization with DGCNN Model

An alternative method may also be implemented using DGCNN (Dynamic Graph CNN), where we used the same autoencoder and optimization algorithm, but instead of a CNN, a DGCNN with higher accuracy is used.

Surrogate Optimization with Latent Model

In situations when we do not have enough training data to train a DL model (e.g. CNN), an alternative approach is predicting the target values directly from the latent vector z instead of generating the reconstructed shapes and using CNN/DGCNN.

This may be much faster and more suitable for cases where a deep learning model may overfit, such as for small datasets or datasets in which the prediction of only a single scalar instead of a whole surface field is needed.

Multi-criteria optimization: a multiple target functions may also be optimized, such as by using pareto front optimisation approach.

Constraints: we may want to restrict all considered shapes, a projected gradient descent approach may be used.

The outputs of the machine learning models described in the earlier section, such as DGCNN, SAE, UAE, may be applied for optimizing the shape of a 3D design based on a few target variables.

The shape optimization algorithm may use a stochastic algorithm in which a 3D design is randomly modified to create a plurality of 3D designs. The plurality of 3D designs are then processed via the machine-learning model. The shape optimization algorithm may implement projected gradient descent. The shape optimization algorithm may also include uncertainty.

### Section 7. Further Examples of Use Cases

Some further examples of case studies are now provided.

### Gust Prediction for Aerospace

Problem: Any change in structure, requires a detailed analysis of the aircraft in all turbulent conditions. Millions of gust simulations must be run, requiring hundreds of engineers and costing millions of dollars.

Using the Monolith platform, advanced deep learning models are trained on legacy simulation databases. Machine learning models are then used to predict the results of simulations before they are run. The learnt relationship between past designs and turbulence response can be used to immediately predict the performance of unseen designs.

As a result, 20 Mn can be saved every year, instead of being wasted on unnecessary simulations. 75% reduction of the time spent on predicting gust outcomes. In this case 9 out of 12 months could be saved. 99% reduction of the size of large historical data, by storing the information within machine learning models.

### Enhancing Track Test Exploitation

Problem: A large number of track tests have to be performed to understand the behaviour of a car in all driving conditions. Current practise is to go through a long list of individual tests to analyse all conditions individually.

Using the Monolith platform, machine Learning models are trained to predict the complete car behavior from raw sensor data from a single test drive. Engineers then retrieve all the information they need from the machine learning models and avoid weeks of testing.

As a result, 1 Mn can be saved for each design, as numerous tests are not required anymore to understand the car. 6 weeks of track tests are saved per design as their results can now be found by AI in other compulsory tests. 3 months reduction in the time it takes to create a realistic simulator of a new car.

### Packaging Optimisation

Problem: Consumer Goods companies are under pressure to reduce the amount of packaging material used while maintaining a quality feel and shortening design cycles.

Using the Monolith platform, Machine Learning models are trained on existing design and test data to give designers an instantaneous prediction of quality feel how changes in design.

As a result, 442 tons saving in plastic every year, based on a production of 30 Mn boxes per year. 25% Reduction in the amount of material needed, while maintaining similar quality.

### Pharmaceutical Development Using Self-Learning Models

Problem: predicting the dissolution kinetics of corticosteroid particles emitted from a nasal spray from the size and shape distributions of those particles. The goal is to optimise a particle size/shape distribution from a target dissolution profile, in order to save development time. How quickly the corticosteroid particles dissolve relates to how quickly the product will get to work in the body after administration.

Using the Monolith platform, a random forest regression model was trained to predict the mass dissolved at different time points from the size and shape of the particles to a good degree of accuracy. The resulting Monolith dashboards enabled users to upload a target dissolution profile and return an optimised particle size and shape distribution that would produce that target dissolution profile.

Advantageously, the AI built a physics agnostic predictive model, with no information provided about the underlying physics or chemistry, coupled with a methodology that could be applied to other types of pharmaceutical lab data. The ability to optimise time-consuming measurements like particle size/shape from faster cheaper measurements like dissolution, is key to reducing development time and costs for their customers.

As a result, testing times are reduced from months to minutes. A significant cost reduction per development batch may also be achieved.

### Smart Meters Using Self-Learning Models

Problem: building reliable smart meter systems. Difficulties include an outdated smart meter infrastructure, fast urbanisation, and rising costs for testing and developing these devices, among others. Smart meter systems must fulfil complex regulations, operate in harsh climate conditions while also reducing non-revenue water losses, as well as fulfilling a carbon-neutral and sustainable future under mounting time-to-market pressure while increasing product performance.

When designing the next generation of smart meters, it is important to keep several key factors in mind. With higher reliability, utilities spend less on maintaining existing infrastructure and reduce overall operating costs. A lower power consumption ensures that meters can operate longer on a single battery and with smaller smart meter size, more sensors can be placed in more locations further increasing the “intelligence” and efficiency of the ‘grid’—whether water, gas, heat, or electricity.

To create more reliable, accurate or energy-efficient system designs, engineers can either retrofit existing products with IoT sensors or bring new, smarter products to market. Either way, they need to spend hundreds of hours testing to ensure the accuracy and reliability of the sensor under thousands of operating conditions to achieve certification.

For example, smart meters need to work for about 20 different flow rates, 30 different temperatures, and 10 different gases. That means these devices must go through at least 6,000 different test scenarios to make them work, each of which means analysing a significant amount of noisy time series data.

Whether gas meters are implemented as water solutions, heating solutions or sub-metering solutions, the Monolith platform is configured to be compatible with any data types and formats. As an example, engineers can easily understand time-series data for received upstream and downstream signal amplitudes which indicate the speed of the gas. By evaluating the difference in arrival times inside the Monolith platform, the volume flow rate can be derived, other physical phenomena can be investigated by performing “virtual tests”, and new design choices can be made without any additional real-life testing scenarios.

Advantageously, the Monolith platform may be configured to:
Create accurate, self-learning models to quickly understand and instantly predict the performance of the gas meter system under thousands of operating conditions.
Determine what smart meter designs give the best performance, while self-learning models learn from new data generated along the way, indicating which designs are most promising to investigate next.
Reveal missing data, systematic experiment errors, and mislabeled data before training additional models.
Understand intractable physical phenomena and compare complex relationships, and as a result. understand how different design choices affect the error curve.
Predict new error curves, giving instant feedback to make the optimal design choices for improved product quality and performance.
Predict error curve response for any new set of design choices, specified by dragging sliders which empowers any engineer to interact with the model and gain new insights, with no need for programming expertise, IT set-up, and minimal training to use the platform and build self-learning models. The performance of each gas meter design may be given by its error curve, giving the percentage accuracy for a range of flow rates and ambient temperature conditions.
Make predictions within their regulatory requirements and quickly generate new optimum designs for the meter setup and export those design parameters to the meter itself, but also inform their suppliers of corrections to the meter components.
Predict flow rates for multiple material types through devices such as valves with varying throughput capabilities such as radius, length, and other relevant device measurements.

Using the Monolith platform to investigate test data, end-users can combine, transform and build self-learning models inside a no-code or almost no-code AI platform. Generally, the Monolith platform is configured to empower engineers to spend less time running expensive, repetitive tests and more time learning from their engineering test data to help them find solutions of complex engineering problems.

### Section 8: Concept Activation Vectors for Generating User-Defined 3D Shapes

We explore the interpretability of 3D geometric deep learning models in the context of Computer-Aided Design (CAD). The field of parametric CAD can be limited by the difficulty of expressing high-level design concepts in terms of a few numeric parameters. In this section, we use a deep learning architectures to encode high dimensional 3D shapes into a vectorized latent representation that can be used to describe arbitrary concepts. Specifically, we train a simple auto-encoder to parameterize a dataset of complex shapes. To understand the latent encoded space, we use the idea of Concept Activation Vectors (CAV) to reinterpret the latent space in terms of user-defined concepts. This allows modification of a reference design to exhibit more or fewer characteristics of a chosen concept or group of concepts. We also test the statistical significance of the identified concepts and determine the sensitivity of a physical quantity of interest across the dataset.

### Introduction

Over the past half-decade, there has been spectacular success with deep learning to synthesize 3D shapes [1, 8-10, 24, 25, 27, 28, 42]. A common approach has been to use a latent space representation that can encode the 3D geometry using some non-linear transformations. This latent space can either be learned directly from the data through an autoencoder architecture [15,42] or implicitly by sampling from a known distribution (e.g., Gaussian) [1, 9, 11, 26, 40] and training a decoder network to replicate the samples from the dataset. Other latent representation approaches also include multi-view reconstruction [17, 22, 24, 25, 29, 32, 35, 37, 41], implicit neural representations [4, 5, 14, 34], auto-decoder models [27], etc. The general aim in all these approaches is to obtain a latent space whose dimension is much smaller than the input dimension, thus having a strong relation to the field of signal compression. The latent space representation has been interpreted as a deep learning analog of dimensionality reduction algorithms such as SVD and PCA; indeed, a network with a single hidden layer can be made equivalent to the UΣV formulation of SVD [21]. Thus, it is believed that the learned latent space should encode the most salient modes of the data and forms a low-dimensional manifold. Similar to their classical analogs, deep learning models discover the latent manifold in a self-supervised manner, where the objective function is determined by recreating the input distribution. Furthermore, either by construction or assumption, it is possible to linearly interpolate between points on this manifold and obtain synthesized data points.

To this end, some works impose regularising conditions on the latent space to encourage the network to discover a well-behaved manifold, such as sparsity constraints [23] or reparametrization to multi-variate Gaussian distributions [7].

One fundamental drawback of die latent space representation is its lack of interpretability. In the standard approach, there is no control over what each coordinate in the latent vector represents, and there is no canonical way in which the network can decompose the original signal. It is easy enough to encode two dataset samples and linearly interpolate between them: however, it is much harder to determine the changes required a priori. There have been attempts to condition the embedding space on a particular semantic feature in the input [20], thus allowing more principled exploration. However, these conditions need to be defined before training, thus restricting the range of possible semantic combinations that can be investigated. In the engineering context it would be highly desirable to link high level design concepts with physical performance. Usually this is done through simulations for an individual design, but quantifying the impact of a design choice across an entire database is a challenging task. We show that using the representation power of deep neural networks we can analyse the sensitivity of a physical quantity of interest with respect to user-defined design concepts and across an entire dataset.

The idea of explainable AI (XAI) is also emerging over the past half-decade. Very early approaches for XAI were gradient-based saliency maps [33]. class-activation maps [31, 45], and some recent approaches are Layerwise relevance propagation [6]. In the field of geometric shape understanding, several researchers have attempted to extend these interpretability algorithms to 3D geometric shapes represented by voxels [12, 43] or, more recently, point clouds. [16, 36, 38, 44]. However, these methods were mostly characterized by visual appearance and, in many situations, did not satisfying some of the sanity checks outlined in [2, 3, 18, 39]. Further, to the best of the knowledge of the authors, there are no XAI-based approaches for understanding the latent shape representation of the geometries.

An XAI method robust to these sanity checks with a lot of promise is Concept Activation Vectors (CAVs) [13,18]. CAVs allow the definition of semantic representations on the embedding space in a posthoc manner. It offers the freedom to define and explore the latent manifold in a human interpretable way, with concepts and inputs that were not originally part of the training dataset. In this work, we focus on whether we can use CAVs for 3D datasets. To this end, we eschew some of the more involved representation learning techniques and propose to learn a simple MLP auto-encoder on a point cloud dataset. We chose the dataset to contain shapes that are low resolution enough to be efficiently learned by an MLP and varied enough to allow interesting interpolations. Once the learning has converged for the reconstruction loss, we explore the latent space in terms of several hand-defined concepts. To create the CAVs, we gather examples within the dataset and from a synthetic distribution that can be interpreted as abstract examples of a style. We then show that it is possible to take a reference design and add or subtract varying amounts of each concept, allowing a potential designer to modify an existing design in a high-level, human interpretable way. To further take advantage of the XAI properties of TCAVs and test the statistical significance of the learned concepts, we also train a model to predict a physical quantity from the latent space.

The main contributions of our work are:
We introduce concept activation vectors (CAV) for interpretable 3D shape interpolation.
We demonstrate CAVs for a dataset of 3D cars similar to ShapeNet.
We introduce the notion of parametric concepts to parametrize designs using human-understandable concepts and regress through them.

While these contributions apply to general 3D shape understanding, we are mainly interested in an engineering design perspective. Hence, we chose a cars dataset and its corresponding drag coefficients in our experiments.

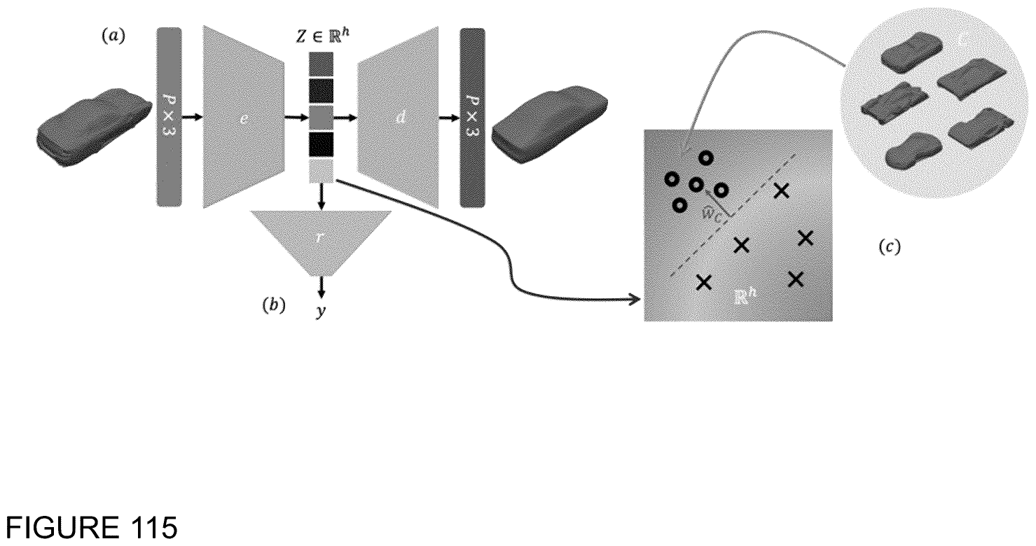

FIG. 115 shows a pictorial representation of the Method. (a) We train an auto-encoder to reconstruct point clouds of car shapes, (b) we then train another network to predict the drag coefficient from the latent space, Z. (c) Finally we collect examples from the dataset to define human interpretable concepts and then represent them in the latent space of the auto-encoder.

### Concept Exploration for 3D Shapes

In this section, we outline the various steps required to traverse a latent space in a human interpretable manner.

### Training an Auto-Encoder

We start with a dataset of point clouds Dₓ={xᵢ}ᵢ₌₁^{N} where each point cloud xᵢ∈R^{P×d} is a rank two tensor signifying a collection of points in 3D space with d features (d=3). In addition we can consider a set of vector quantities D_{y}={yᵢ}ᵢ₌₁^{N} related to the point clouds, where yᵢ∈R^{F}. We signify the combination of the two datasets as D_{x,y}={(xᵢ, yᵢ)}ᵢ₌₁^{N}.

An auto-encoder can be represented as a pair of maps AE:=(e,d) such that:

e:x∈ [symbol] ^{P×d}→z∈Z (1)

and

d:z∈Z→x∈ [symbol] ^{P×d} (2)

The maps e and d are known as the encoder and decoder, respectively. Z∈ [symbol] ^{h} is referred to as the h-dimensional latent space, and it represents the salient manifold of the data. In practice we construct the auto-encoder as a pair of deep neural networks AE_{Θ}:=(e_{θe},d_{θd}) where Θ={θₑ,θ_{d}} is the set of parameters from all networks. We train in an end-to-end fashion with the reconstruction loss:

[symbol]

(AE_{Θ},xᵢ):=∥xᵢ−d_{θd}(e_{θc}(xᵢ))∥_{F}² (3)

where ∥⋅∥_{F} denotes the Frobenius norm. We want to minimize the expectation of the loss across the dataset, for which we use stochastic gradient descent based optimization.

### TCAV Framework

Once the AE is trained, we can use the encoder to obtain latent vectors for any input that matches the dimensions of our original dataset. These new inputs are usually examples from a holdout dataset that follows the same distribution as Dₓ. However, as was shown in [18], we are not entirely limited by the input distribution, and we can obtain useful embeddings for shapes that are similar to the original input as well. We define a concept as a human interpretable collection of shapes that have some quality in common (e.g., a set of sporty cars).

C:={z(c):z(c)=e(x(c)),x(c)∈R^{P×d}} (4)

Conversely, we define a non-concept C as a random collection of inputs that have no particular common characteristic. We can use concepts and non-concepts to define multiway linear classification problems. Since linear classification learns hyperplanes that maximally separate the classes, we can take the normal to the hyperplanes to represent the direction of the concept.

$$\\ \begin{matrix}{ω}_{c} = {max}_{ω ∈ {ℝ}^{h}} [ {𝔼}_{z \sim C} ( {𝕀}_{ω \cdot z + b \geq 1} ) + {𝔼}_{z ≁ C} ( {𝕀}_{ω \cdot z + b \leq - 1} ) ] & ( 5 )\end{matrix}$$

Here I_{A} is the indicator function, and w_{C} are known as Concept Activation Vectors (CAVs). We would like to note that since CAVs are obtained as a result of a classification problem, they are sensitive to the other classes. For example, obtaining the CAV for concept C₁ against a non-concept C is not guaranteed to be the same as the CAV obtained by classifying against another concept C₂. In fact, this is a useful property that allows us to obtain relative and more targeted CAVs.

Testing with CAVs. Once we have recovered the CAV for our chosen concept, it is easy to determine the sensitivity of a network output to the chosen concept by performing the directional derivative:

Sᵢⱼ^{C}(x)=w_{C}·∇_{z}d(e(x))ᵢⱼ (6)

Having defined the sensitivity of a single input, we can extend it to test the sensitivity of an

entire dataset or a subset of it.

$$\\ \begin{matrix}T C A {V}_{ij}^{{}^{} C} ( {D}_{x} ) := \frac{\vert \{ x ∈ {D}_{x} : {S}_{ij}^{{}^{} C} ( x ) > 0 \} \vert}{\vert {D}_{x} \vert} & ( 7 )\end{matrix}$$

This gives us the fraction of tested inputs positively influenced by the concept. As mentioned in [18], it is possible to consider a metric based on the magnitude of the sensitivities as well.

Regressing from the Latent Space

Since understanding the sensitivity of the auto-encoder output is not particularly interesting, we train another neural network r_{θr} that can regress a quantity of interest from the latent space.

r:Z→y (8)

Since this is a scalar physical quantity y∈R, the sensitivities have a more intuitive interpretation than for the autoencoder case:

S_{y}^{C}(x)=w_{c}·∇_{z}y(z) (9)

That is, the sensitivity captures how much the quantity y increases or decreases if we move in the direction of the concept. This value, along with the corresponding TCAV metric, can have practical engineering applications.

Exploring the Latent Space with CAVs

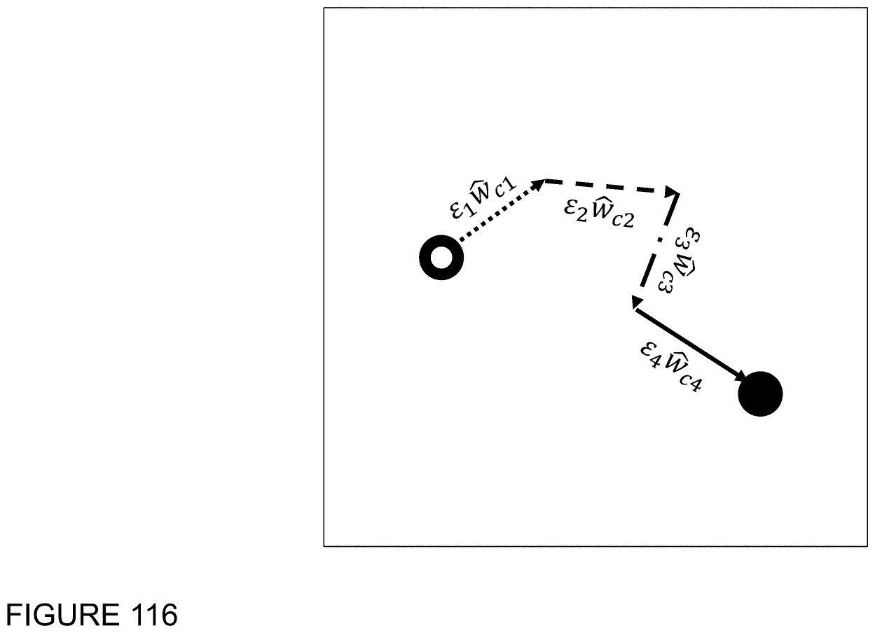

FIG. 116 shows a diagram illustrating a conceptual path in latent space.

Since each CAV describes an un-normalized direction in latent space, we can use them to translate a point in z∈R^{h} along this direction:

z′=z+εw\hat{ }_{C}, (10)

where ε∈R is a parameter controlling how far we go towards the concept if ε>0 or away from the concept if ε<0. Then we can use the decoder to transform the new point in latent space back into the input space x′=d(z′). In this way, we can both navigate the latent space and interpret the output in a naturally human-understandable form. As a straightforward extension, we can chain multiple translations in the latent space and thus blend multiple concepts.

Say that we have identified a set M={Cᵢ}ᵢ₌₁^{m} of concepts and found their corresponding CAVs, then we can add any linear combination of these concepts to the original point.

z′=z+Σᵢ₌₁^{m}εᵢŵCᵢ (11)

Thus the complicated task of modifying an existing design to exhibit a combination of multiple design concepts and styles has been reduced to a simple linear algebra operation. Concept querying is a natural benefit of using the CAVs to interpret the latent space. Since the classifier essentially computes a similarity score between the CAV and the latent representation of the input, we can define the query with respect to a certain concept as

Q(Dₓ,C):={q:q=w_{C}·e(x),x∈Dₓ,|q|>>0}. (12)

We can recover the instances in Dₓ that are most similar or dissimilar to the concept for strongly positive or negative q's, respectively.

### Results

In this section, we outline the results obtained for an in-house dataset consisting of 1165 car shapes represented by point clouds of dimension R^{6146×3} with accompanying drag coefficients obtained from CFD simulations. A quarter of the shapes were reserved for validation, and the autoencoder was trained on the rest. The auto-encoder consists of 4 fully connected layers for the encoder resulting in an embedding space with 8 dimensions; the decoder mirrors the encoder structure with the final output dimension equal to that of the original shapes. All activations in the autoencoder are LeakyReLU [30] apart from the latent layer, which has a tan h activation function to provide some hard bounds on the latent space, and no activation for the final layer of the decoder so that we can model the points in all of R³. For the regressor network r_{θr}, we use a similar fully connected deep architecture to predict the drag coefficient for each car. Consequently we restrict the output to values in R>₀ via a ReLU activation.

Given the small size of the dataset, a small dropout was added to most layers to combat over-fitting. All models are trained for 1000 epochs using the ADAM optimizer [19] with default settings.

### Obtaining CAVs

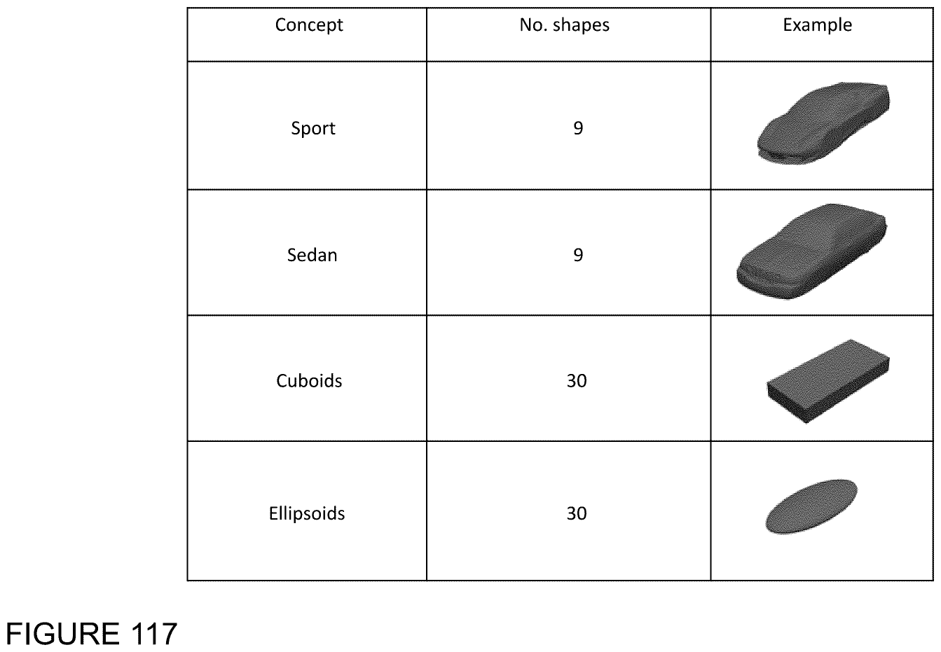

Collecting concepts. To collect interesting concepts, we manually inspected the dataset and identified several styles of cars with a few examples each. In addition, to test the capability of the latent space to encode out of distribution shapes, we decided to represent the concept of boxiness and curviness via randomly generated cuboids and ellipsoids. To be close to the car shape distribution, we restrict the aspect ratio of the generated shapes to lie in a similar range to the cars. Specific numbers and examples are given in FIG. 117. We chose the examples from the validation set to test the representation power of the latent space. Where nonconcepts were necessary, we chose 50 random shapes from both the training and validation set.

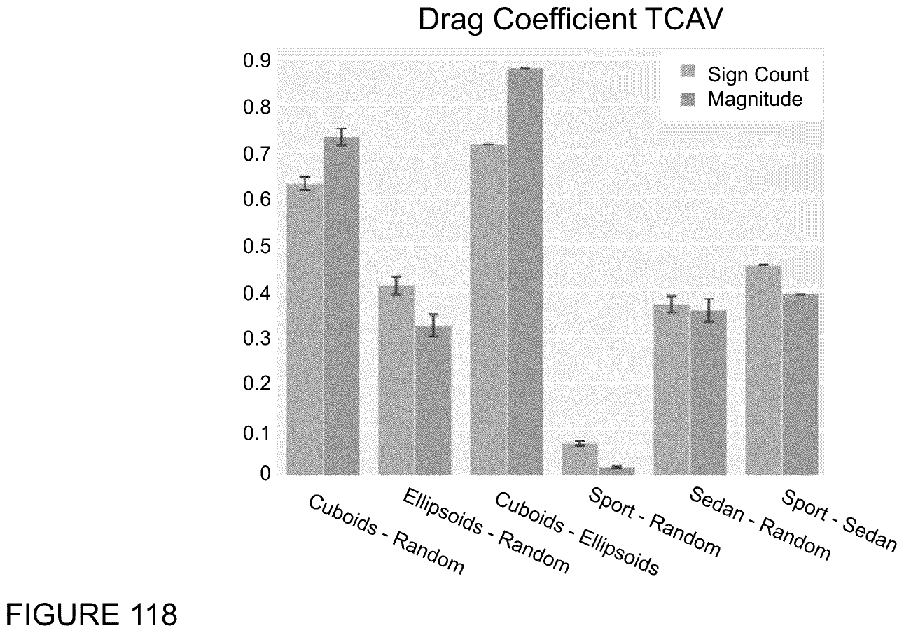

Training CAVs. Once the concept examples are selected, we train linear classifiers on the latent space representation of the examples via SGD and with an L₂ penalty. We explore CAVs obtained for each concept in FIG. 117 paired with a random subset of the car dataset. In addition, we train CAVs for the Cuboids-Ellipsoids and Sport-Sedan pairs since they are roughly opposite concepts. We can see the TCAV metrics of the drag coefficient in FIG. 118.

The TCAV metrics broadly follow our intuitions in that the less aero-dynamical concepts tend to increase the drag coefficients much more than the streamlined concepts. This is even more pronounced for the Cuboids-Ellipsoids CAV; however, the same can not be said for the Sport-Sedan CAV. This suggests that the Sedan concept might be more aerodynamic than first thought or that this is a poorly understood concept for the model. All the CAVs were verified to be statistically significant using a two-sided t-test.

### Concept Blending and Querying

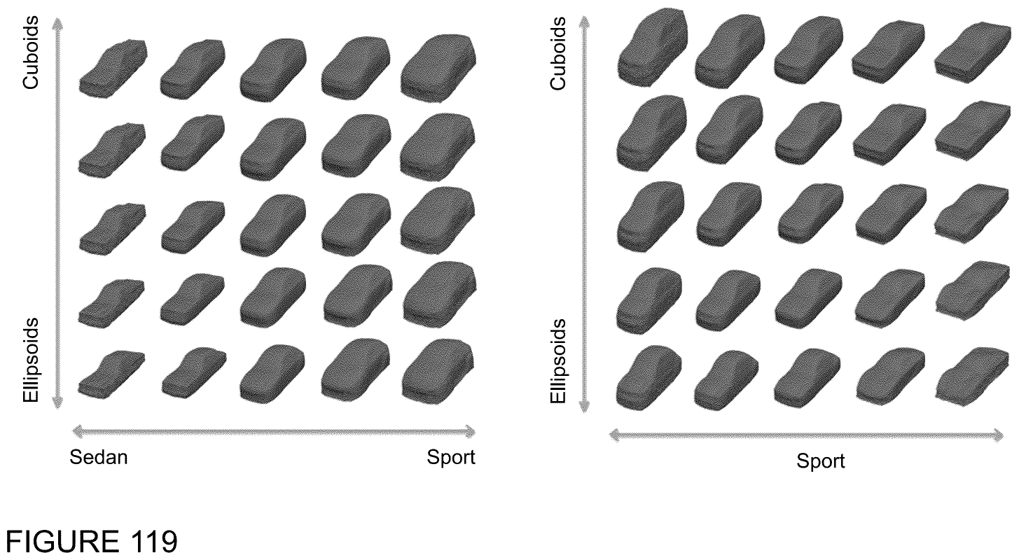

As discussed above, we can blend different concepts into an existing design by adding linear combinations of the CAVs to the latent space embeddings. Image grids for two pairs of interesting CAVs are presented in FIG. 119. First, we would like to note that both examples confirm the viability of our approach since the generated designs are not present in the original dataset and follow the intuition of blending designs well. In addition, it is interesting to observe how the behavior of the CAVs depends on the concepts used to generate them. Specifically moving towards the Sport concept for the Sport—Sedan CAV generates wider based and larger sporty designs in contrast to the Sport influenced shapes of the Sport—Random CAV. Both the synthetic concepts are also changing the design in sensible ways affecting both the shape of the front of the cars as well as the back to generate more compact or SUV-like types. Finally, the different concepts constrain each other in interesting ways depending on their relative strengths in the blend. For example, the last column of the right figure features muscle-type sports cars or racing-type sports cars depending on the degree of Cuboids or Ellipsoids added.

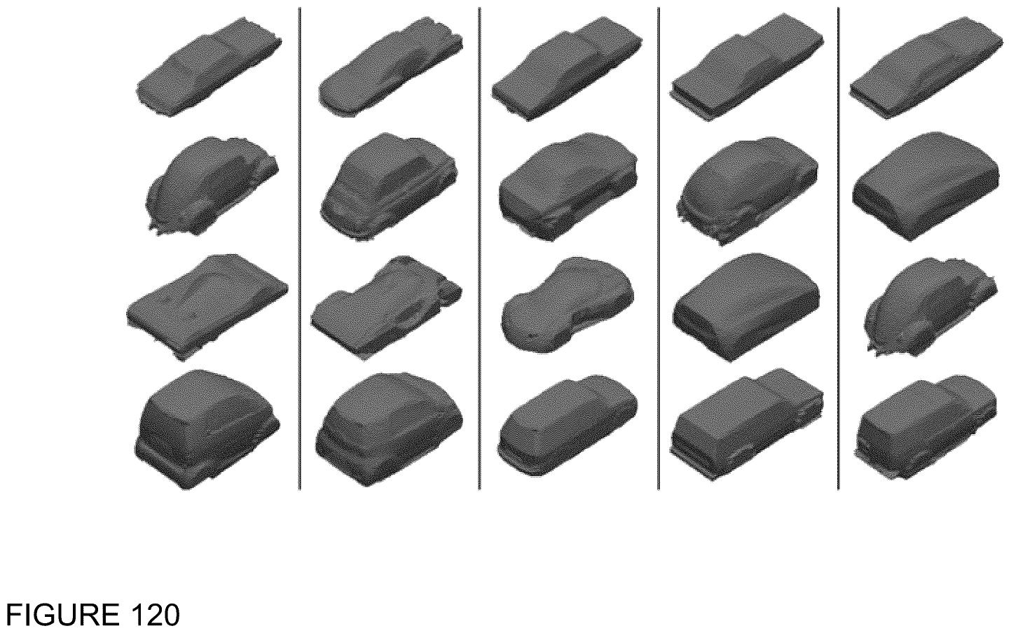

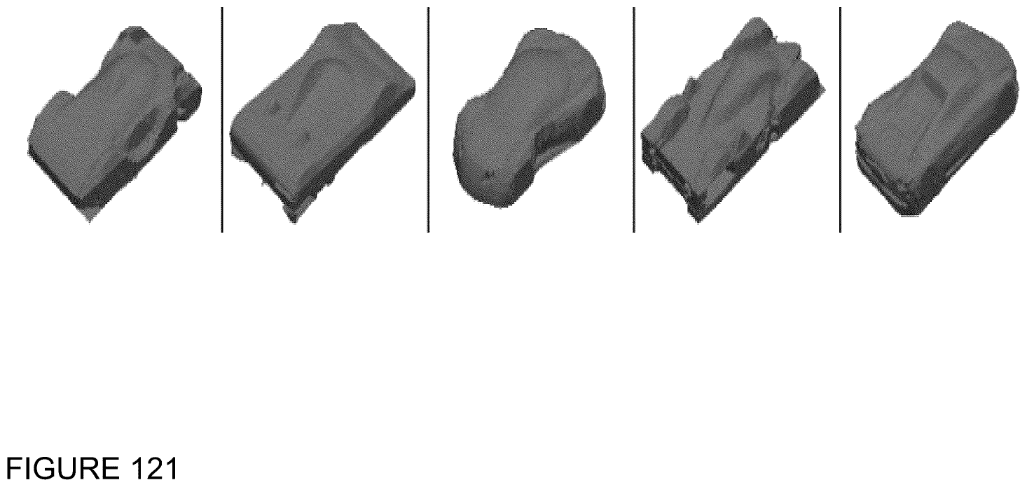

Querying. We present the top five most similar designs for some concepts in FIG. 120. We note that querying the dataset is a good way to evaluate the quality of the learned CAV, as observed from the overlap between the results for the Sport and Ellipsoids concepts. Retraining the CAV for the Sport concept results in better query results in FIG. 121. This behavior emphasizes the stochastic nature of the CAV and that adding more examples and tuning the classifier might be worthwhile.

### Parametric CAVs

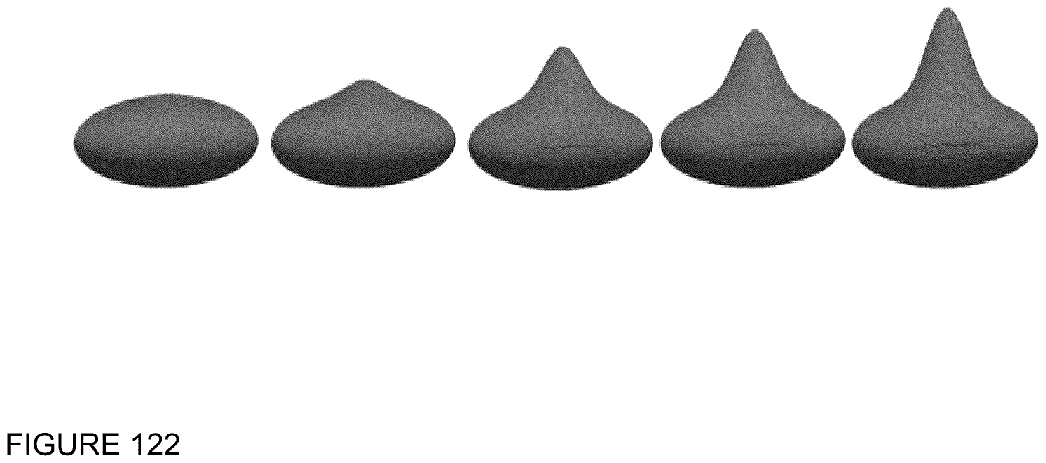

While the TCAV framework is great for exploring intangible concepts, it would also be useful for designers and engineers to control the parametric qualities of a design. To test whether this is possible, we generate a synthetic dataset of ellipsoids with constant proportions but with deformations of random height. We then select some examples with the highest deformations to obtain a HighBump—Random CAV. By varying the strength of the CAV, we can control the height of the deformation as seen in FIG. 122.

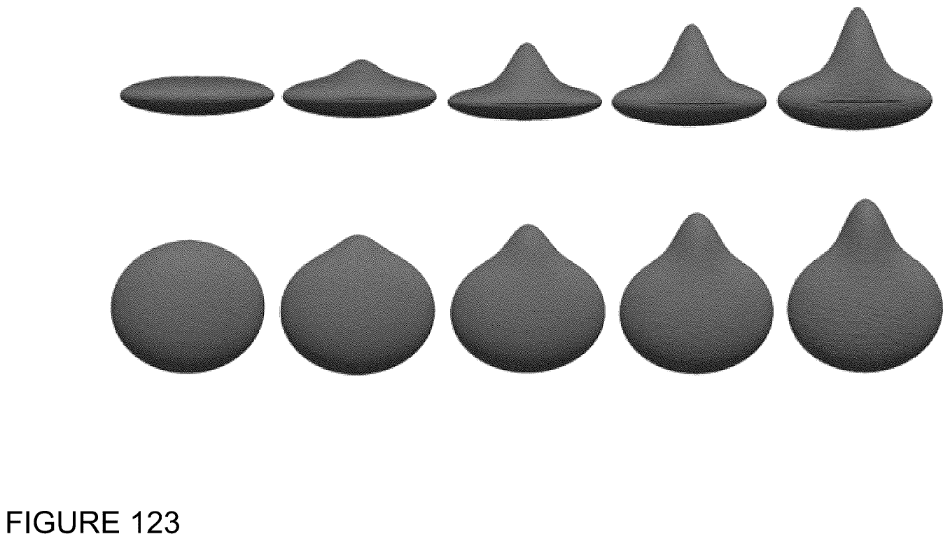

Even though the embedding dimension is set to 8, the data manifold is essentially one-dimensional, as evidenced by the mean off-diagonal correlation coefficient being 0.97. Thus it is not surprising that the CAV can control the height of the deformation so well. To determine if we could isolate the deformation from the other shape parameters, we trained another auto-encoder on a similar dataset but with random ellipsoid proportions. The new manifold is not one dimensional with an absolute off-diagonal mean correlation of 0.57. However, because of the still significant correlation between the dimensions, we found it necessary to define the CAV using a converse LowBump concept instead of a nonconcept. Using this CAV, we were able to vary the height of the deformation without affecting the rest of the ellipsoid shown in FIG. 123.

These results hint that the TCAV framework could be easily extended to regressive concepts. Indeed the HighBump—LowBump CAV is effectively a biased linear regression problem.

### Discussion

In this work, we demonstrated the applicability of the TCAV XAI framework to a dataset of 3D car shapes. We trained a simple auto-encoder to embed high dimensional point clouds into a low dimensional manifold. By gathering examples of different car types from the dataset together with abstract representations of style concepts, we were able to explore the latent space in a human interpretable way. Even with this simple architecture, the latent space proved to be rich enough to blend and represent concepts outside the data distribution. However, at the same time, the model was able to constrain the linear combinations of CAVs to produce interesting blends of various concepts without degenerating quickly into previously seen data points.

We introduced the notion of a parametric CAV that allows for a reinterpretation of the latent space in terms of a known design parameter or one that might have become of interest later. Our approach was to cast the regression problem into a classification task to define the parametric CAV; however, we can use a linear regressor instead of a classifier. Using a linear regressor would, in principle, allow for the construction of single concept CAVs, and we leave it as a future direction of work.

Finally, we would like to highlight that the high performance of the networks was not a prerequisite for the success of these experiments. Indeed, the low amount of data, simple architecture, and small latent dimension hampered the reconstruction capabilities of the auto-encoder. It is encouraging that concept blending worked well in this regime, and we believe it will also work well for high-performance, latent space-based generative models. TCAV may prove even more valuable for such models with a high number of latent dimensions since understanding and directly exploring these spaces is very challenging.

### REFERENCES

[1] Panos Achlioptas, Olga Diamanti, Ioannis Mitliagkas, and Leonidas J. Guibas. Representation learning and adversarial generation of 3d point clouds. ArXiv, abs/1707.02392, 2017.
[2] Julius Adebayo, Justin Gilmer, Michael Muelly, Ian Goodfellow, Moritz Hardt, and Been Kim. Sanity checks for saliency maps. arXiv preprint arXiv:1810.03292, 2018.
[3] Julius Adebayo, Michael Muelly, Ilaria Liccardi, and Been Kim. Debugging tests for model explanations. arXiv preprint arXiv:2011.05429, 2020.
[4] Matan Atzmon and Yaron Lipman. SAL: Sign agnostic learning of shapes from raw data. In Proceedings of the IEEE/CVF Conference on Computer Vision and Pattern Recognition, pages 2565-2574, 2020.
2020. Matan Atzmon and Yaron Lipman. Sald: Sign agnostic learning with derivatives. arXiv preprint arXiv:2006.05400, 2020.
[5] Alexander Binder, Gregoire Montavon,′ Sebastian Lapuschkin, Klaus-Robert Muller, and Wojciech Samek. Layer-wise relevance propagation for neural networks with local renormalization layers. In International Conference on Artificial Neural Networks, pages 63-71. Springer, 2016.
[6] Andrew Brock, Theodore Lim, James M. Ritchie, and Nick Weston. Generative and discriminative voxel modeling with convolutional neural networks. ArXiv, abs/1608.04236, 2016.
[7] Zhiqin Chen, Andrea Tagliasacchi, and Hao Zhang. Bsp-net: Generating compact meshes via binary space partitioning. In Proceedings of the IEEE/CVF Conference on Computer Vision and Pattern Recognition, pages 45-54, 2020.
[8] Zhiqin Chen and Hao Zhang. Learning implicit fields for generative shape modeling. 2019 IEEE/CVF Conference on Computer Vision and Pattern Recognition (CVPR), pages 5932-5941, 2019.
[9] Boyang Deng, Kyle Genova, Soroosh Yazdani, Sofien Bouaziz, Geoffrey Hinton, and Andrea Tagliasacchi. Cvxnet: Learnable convex decomposition. In Proceedings of the IEEE/CVF Conference on Computer Vision and Pattern Recognition, pages 31-44, 2020.
[10] Jeff Donahue, Philipp Krahenb uhl, and Trevor Darrell. Adversarial feature learning. ArXiv, abs/1605.09782, 2017.
[11] Sambit Ghadai, Aditya Balu, Soumik Sarkar, and Adarsh Krishnamurthy. Learning localized features in 3D CAD models for manufacturability analysis of drilled holes. Computer Aided Geometric Design, 62:263-275, 2018.
[12] Yash Goyal, Amir Feder, Uri Shalit, and Been Kim. Explaining classifiers with causal concept effect (cace). arXiv preprint arXiv:1907.07165, 2019.
[13] Amos Gropp, Lior Yariv, Niv Haim, Matan Atzmon, and Yaron Lipman. Implicit geometric regularization for learning shapes. arXiv preprint arXiv:2002.10099, 2020.
[14] Yanran Guan, Tansin Jahan, and Oliver Matias van Kaick. Generalized autoencoder for volumetric shape generation. 2020 IEEE/CVF Conference on Computer Vision and Pattern Recognition Workshops (CVPRW), pages 1082-1088, 2020.
[15] Shikun Huang, Binbin Zhang, Wen Shen, and Zhihua Wei. A claim approach to understanding the pointnet. In Proceedings of the 2019 2nd International Conference on Algorithms, Computing and Artificial Intelligence, pages 97-103, 2019.
[16] Asako Kanezaki, Yasuyuki Matsushita, and Yoshifumi Nishida. RotationNet: Joint object categorization and pose estimation using multiviews from unsupervised viewpoints. In Proceedings of the IEEE Conference on Computer Vision and Pattern Recognition, pages 5010-5019, 2018.
[16] Been Kim, Martin Wattenberg, Justin Gilmer, Carrie Cai, James Wexler, Fernanda Viegas, et al. Interpretability beyond feature attribution: Quantitative testing with concept activation vectors (tcav). In International conference on machine learning, pages 2668-2677. PMLR, 2018.
[18] Diederik P. Kingma and Jimmy Ba. Adam: A method for stochastic optimization. CoRR, abs/1412.6980, 2015.
[19] Akira Kudo, Y. Kitamura, Yuanzhong Li, Satoshi Iizuka, and Edgar Simo-Serra. Virtual thin slice: 3d conditional gan-based super-resolution for ct slice interval. In MLMIR@MICCAI, 2019.
[20] Yann LeCun, Yoshua Bengio, and Geoffrey Hinton. Deep learning. nature, 521(7553):436-444, 2015.
[21] Jiaxin Li, Ben M Chen, and Gim Hee Lee. So-net: Selforganizing network for point cloud analysis. In Proceedings of the IEEE Conference on Computer Vision and Pattern Recognition, pages 9397-9406, 2018.
[22] Xinyu Lin, Ce Zhu, Q. Zhang, and Y. Liu. 3d keypoint detection based on deep neural network with sparse autoencoder. ArXiv, abs/1605.00129, 2016.
[23] Ben Mildenhall, Pratul P. Srinivasan, Matthew Tancik, Jonathan T. Barron, Ravi Ramamoorthi, and Ren Ng. Nerf: Representing scenes as neural radiance fields for view synthesis. In ECCV, 2020.
[24] Thomas Muller, Alex Evans, Christoph Schied, and Alexander Keller. Instant neural graphics primitives with a multiresolution hash encoding. ArXiv, abs/2201.05989, 2022.
[25] Charlie Nash and Christopher K. I. Williams. The shape variational autoencoder: A deep generative model of partsegmented 3d objects. Computer Graphics Forum, 36, 2017.
[26] Jeong Joon Park, Peter R. Florence, Julian Straub, Richard A. Newcombe, and S. Lovegrove. Deepsdf: Learning continuous signed distance functions for shape representation. 2019 IEEE/CVF Conference on Computer Vision and Pattern Recognition (CVPR), pages 165-174, 2019.
[27] Despoina Paschalidou, Angelos Katharopoulos, Andreas Geiger, and Sanja Fidler. Neural parts: Learning expressive 3d shape abstractions with invertible neural networks. In Proceedings of the IEEE/CVF Conference on Computer Vision and Pattern Recognition, pages 3204-3215, 2021.
[28] Charles R Qi, Hao Su, Matthias NieBner, Angela Dai, Mengyuan Yan, and Leonidas J Guibas. Volumetric and multi-view CNNs for object classification on 3D data. In Proceedings of the IEEE Conference on Computer Vision and Pattern Recognition, pages 5648-5656, 2016.
[29] Joseph Redmon, Santosh Kumar Divvala, Ross B. Girshick, and Ali Farhadi. You only look once: Unified, real-time object detection. 2016 IEEE Conference on Computer Vision and Pattern Recognition (CVPR), pages 779-788, 2016.
[30] Ramprasaath R Selvaraju, Michael Cogswell, Abhishek Das, Ramakrishna Vedantam, Devi Parikh, and Dhruv Batra. Grad-cam: Visual explanations from deep networks via gradient-based localization. In Proceedings of the IEEE international conference on computer vision, pages 618-626, 2017.
[31] Konstantinos Sfikas, Ioannis Pratikakis, and Theoharis Theoharis. Ensemble of PANORAMA-based convolutional neural networks for 3D model classification and retrieval. Computers & Graphics, 2017.
[32] Karen Simonyan, Andrea Vedaldi, and Andrew Zisserman. Deep inside convolutional networks: Visualising image classification models and saliency maps. arXiv preprint arXiv:1312.6034, 2013.
[33] Vincent Sitzmann, Julien N. P. Martel, Alexander W. Bergman, David B. Lindell, and Gordon Wetzstein. Implicit neural representations with periodic activation functions. ArXiv, abs/2006.09661, 2020.
[34] Shuran Song and Jianxiong Xiao. Deep sliding shapes for amodal 3D object detection in RGB-D images. In Proceedings of the IEEE Conference on Computer Vision and Pattern Recognition, pages 808-816, 2016.
[35] Feng-Guang Su, Ci-Siang Lin, and Yu-Chiang Frank Wang. Learning interpretable representation for 3d point clouds. In 2020 25th International Conference on Pattern Recognition (ICPR), pages 7470-7477. IEEE, 2021.
[36] Hang Su, Subhransu Maji, Evangelos Kalogerakis, and Erik Learned-Miller. Multi-view convolutional neural networks for 3D shape recognition. In Proceedings of the IEEE International Conference on Computer Vision, pages 945-953, 2015.
[37] Hanxiao Tan and Helena Kotthaus. Surrogate model-based explainability methods for point cloud nns. In Proceedings of the IEEE/CVF Winter Conference on Applications of Computer Vision, pages 2239-2248, 2022.
[38] Richard Tomsett, Dan Harborne, Supriyo Chakraborty, Prudhvi Gurram, and Alun Preece. Sanity checks for saliency metrics. In Proceedings of the AAAI conference on artificial intelligence, volume 34-04, pages 6021-6029, 2020.
[39] Jiajun Wu, Chengkai Zhang, Tianfan Xue, Bill Freeman, and Joshua B. Tenenbaum. Learning a probabilistic latent space of object shapes via 3d generative-adversarial modeling. In NIPS, 2016.
[40] Zhirong Wu, Shuran Song, Aditya Khosla, Fisher Yu, Linguang Zhang, Xiaoou Tang, and Jianxiong Xiao. 3D ShapeNets: A deep representation for volumetric shapes. In Proceedings of the IEEE Conference on Computer Vision and Pattern Recognition, pages 1912-1920, 2015.
[41] K. Yin, Hui Huang, Daniel Cohen-Or, and Hao Zhang. P2pnet. ACM Transactions on Graphics (TOG), 37:1-13, 2018.
[42] Soyoung Yoo and Namwoo Kang. Explainable artificial intelligence for manufacturing cost estimation and machining feature visualization. Expert Systems with Applications, 183:115430, 2021.
[43] Binbin Zhang, Shikun Huang, Wen Shen, and Zhihua Wei. Explaining the pointnet: What has been learned inside the pointnet? In CVPR Workshops, pages 71-74, 2019.
[44] Bolei Zhou, Aditya Khosla, Agata Lapedriza, Aude Oliva, and Antonio Torralba. Learning deep features for discriminative localization. In Proceedings of the IEEE conference on computer vision and pattern recognition, pages 2921-2929, 2016.

### Section 9—Key Features

This section summarises the most important high-level features; an implementation of the invention may include one or more of these high-level features, or any combination of any of these. Note that each high-level feature is therefore potentially a stand-alone invention and may be combined with any one or more other high-level feature or features or any one or more of the ‘optional’ features.

### Feature A—Machine Learning Platform Solving Complex Engineering Problems and Generating Novel 3D Objects

The monolith platform improves efficiency between designers and engineers through the use of AI/ML to solve complex engineering problems. The platform allows engineers to easily train machine learning models to enable end-users, such as designers or engineers, to quickly and/or automatically understand if a set of design files relating to 3D objects meets engineering and/or aesthetic requirements. Advantageously, the platform can output a set of optimal design parameters that would satisfy the engineering and/or aesthetic requirements.

We can generalise to:

A computer implemented method for generating a 3D object, the method comprising:
training a machine learning system to learn design parameter values that give rise to an optimally performing version of the 3D object; and
processing, using the machine learning system, input data relating to the 3D object, in an unsupervised manner such that it can be used for generative purposes, such as the creation of novel geometries or other parameters of the 3D object.

The novel geometries or other parameters of the 3D object may define an optimally performing version of the 3D object; the design parameters may relate to any one or more of the following areas: design, durability, ergonomics, structural dynamics, aerodynamics, simulation, testing and manufacturing.

The corresponding system is generalised as follows:

A computer implemented system for processing input data relating to a 3D object, the system comprising:
a non-transitory storage medium;
a processor coupled to the storage medium and configured to:
train a machine learning system to learn design parameter values that give rise to an optimally performing version of the 3D object; and
process, using the machine learning system, input data relating to the 3D object, in an unsupervised manner such that it can be used for generative purposes, such as the creation of novel geometries or other parameters of the 3D object.

### Feature B—Data Agnostic Platform

Advantageously, the machine learning platform is agnostic to the particular type of data, meaning that many types of input data can be used interchangeably e.g. 3D CAD files, parametric design data or physical experimental data in csv format. Input data can also be easily updated/appended to enhance the training data and provide optimum design parameters to satisfy engineering and/or aesthetic requirements. Training data and input data may include for example: simulation, measurement, test, or physics data; training data and input data can extend to design, durability, ergonomics, structural dynamics, aerodynamics, simulation, testing and manufacturing data, so that the benefits of AI-based predictions can be applied across each of these areas when predicting the performance of a 3D object. Any engineer can link their designs to predicted product performance, across potentially all of the relevant areas (e.g. (design, durability, ergonomics, structural dynamics, aerodynamics, simulation, testing and manufacturing etc.). This removes the conventional, slow, costly iterative process of an engineer in an area having to review and modify candidate 3D object designs, and for those changes to then be reviewed by engineers in other areas, and for any changes they make to then be re-reviewed by the initial engineer.

We can generalise to:

A computer implemented method for predicting the performance of a 3D object, the method comprising:
training a machine learning system to predict the performance of the 3D object across multiple areas, the areas including several of the following areas: design, durability, ergonomics, structural dynamics, aerodynamics, simulation, testing and manufacturing;
processing, using the machine learning system, input data relating to the 3D object, the 3D object having a set of raw data relating to the 3D object, design parameters and/or operating conditions;
predicting, using the machine learning system, the performance of the 3D object across one or more of the areas.

The method may also be used for predicting the performance of novel geometries of the 3D object across one or more of the areas. The method may also be used for predicting the performance of the 3D object across each of the multiple areas.

The corresponding system is generalised as follows:

A computer implemented system for processing input data relating to a 3D object, the system comprising:
a non-transitory storage medium;
a processor coupled to the storage medium and configured to:
train a machine learning system to predict the performance of the 3D object across multiple areas, the areas including several of the following areas: design, durability, ergonomics, structural dynamics, aerodynamics, simulation, testing and manufacturing;
process, using the machine learning system, input data relating to the 3D object, the 3D object having a set of raw data relating to the 3D object, design parameters and/or operating conditions;
predict, using the machine learning system, the performance of the 3D object across one or more of the areas.

### Feature C—Exploring a Latent Space of a 3D Object Using Human Understandable Concepts

Autoencoders can be used to reduce the high dimensional information of a 3D object to a latent space having a far smaller number of parameters than the existing data. The platform is able to quickly identify specific parameterisations of a 3D object that can be easily expressed in terms user defined concepts thereby adding an interpretability to the these complex models. Advantageously, using the platform one can quickly determine how to modify one or more latent parameters to tailor or modify the design of a 3D object to morph closer/further to/from any number of user defined concepts.

We can also generalise to:

A computer implemented method for generating a 3D object, the method comprising:
training a machine learning system to map at least one user configurable concept to a latent space;
processing, using the machine learning system, input data relating to the 3D object, to classify the 3D object in terms of the user configurable concept;
generating and applying AI-derived parameters to the 3D object to alter, or enable a user to alter, a value or parameter of the user configurable concept of the 3D object.

The corresponding system is generalised as follows:

A computer implemented system for processing input data relating to a 3D object, the system comprising:
a non-transitory storage medium;
a processor coupled to the storage medium and configured to:
train a machine learning system to map at least one user configurable concept to a latent space;
process, using the machine learning system, input data relating to the 3D object, to classify the 3D object in terms of the user configurable concept;
generate and apply AI-derived parameters to the 3D object to alter, or enable a user to alter, a value or parameter of the user configurable concept of the 3D object.
   Feature D—Local Design Optimisation Augmented with AI

The platform outputs a 3D saliency map that indicates the relative importance of a geometrical region of the 3D object for a given target variable e.g. drag. The platform also outputs whether a specific geometrical region positively or negatively affects the target variable. Based on the saliency maps identified regions, the platform can further morph local geometrical regions identified in order to optimize the 3D object based on the target variable.

We can also generalise to:

A computer implemented method for generating a 3D object, the method comprising:
training a machine learning system to map the importance or saliency of object geometry to a target variable;
processing, using the machine learning system, input data relating to the geometry of the 3D object;
generating and displaying a saliency map that shows the value of the target variable across the 3D object.

The machine learning system may automatically alter the geometry of the 3D object to optimise that geometry against the target variable. A target variable may relate to any one or more of the following areas: design, durability, ergonomics, structural dynamics, aerodynamics, simulation, testing and manufacturing of the 3D object.

The corresponding system is generalised as follows:

A computer implemented system for processing input data relating to a 3D object, the system comprising:
a non-transitory storage medium;
a processor coupled to the storage medium and configured to:
train a machine learning system to map the importance or saliency of object geometry to a target variable;
process, using the machine learning system, input data relating to the geometry of the 3D object;
generate and display a saliency map that shows the value of the target variable across the 3D object.

### Feature E—3D Explainability—Machine Learning Based Technique for Making Models Applied to 3D Data Explainable

A computer implemented method for evaluating a machine learning system, in which the machine learning system processes input data relating to one or more 3D objects, the method including the step of providing explainability data relating to the machine learning system that is human interpretable.

### Feature F—Platform for Implementing the Engineering Workflow Using a Graphical User Interface

A computer implemented system for predicting the performance of one or more 3D objects, the system including a graphical user interface that is configured to receive input data and to output one or more 3D objects, and in which a processor is programmed to automatically apply queries received from the end-user and to provide the results of each query.

### Feature G—Improved Dynamic Graph CNN Technique for Higher-Fidelity Meshes.

A computer implemented method of processing input data relating to a 3D object and generating a plurality of 3D surface field predictions using a Dynamic Graph CNN approach with training data, in which the input data is processed multiple times using multiple subsets of the training data.

### Feature H—Improved Structured Autoencoder (SAE) Technique

A computer implemented method of processing input data relating to a 3D object and converting a dimensionality of the 3D object into a latent space having one or more of latent parameters using a structured autoencoder approach, in which principal component analysis (PCA) is used as a pre-processing step.

### Feature I—Unstructured Autoencoder (UAE) Implemented Using a Stacked Autoencoder Architecture

A computer implemented method of processing data relating to a 3D object and converting a dimensionality of the 3D object into a latent space having one or more of latent parameters using a stacked autoencoder architecture, in which a first autoencoder is used to encode the input data into a first set of latent vectors, and a second autoencoder is then used to encode the first set of latent vectors into a second set of latent vectors.

Feature J—Unstructured Autoencoder (UAE) that Automatically Determines an Optimum Autoencoder Based on the 3D Input Data

A computer implemented method of processing data relating to a 3D object and converting a dimensionality of the 3D object into a latent space having one or more of latent parameters using an unstructured autoencoder architecture, in which the method includes the step of automatically choosing an optimum autoencoder, such as convolutional or non-convolutional UAE, based on the input data.

The unstructured aspect of the model represents an extension from its structured equivalent because it can work with 3D data sets where each individual geometry can have a variable number of points in it.

Optional features:
The novel geometries or other parameters of the 3D object define an optimally performing version of the 3D object;
The design parameters may relate to any one or more of the following areas: design, durability, ergonomics, structural dynamics, aerodynamics, simulation, testing and manufacturing.
The machine learning system is configured to automatically alter the geometry of the 3D object to optimise that geometry against a target variable.
Input data includes point cloud or scalar values.
Input data is one or more of the following: 3D data, CAD files, HDF, Matlab, or Tabular file or any other data representing a 3D object;
Method includes the step of identifying an optimum set of design parameters to meet the target variable;
Method includes the step of generating an optimum set of design parameters based on a target variable.
Method includes the step of predicting the outcome of multi-physics 3D numerical simulations for the 3D object or for novel geometries of the 3D object.
Method includes the step of providing instant predictions for what a 3D simulation results would be if the 3D object or novel geometries of the 3D object were tested under different operating or testing conditions (e.g. gust of winds for the case of wind turbine).
Machine learning system includes a 3D deep learning model such as 3D to scalar model, autoencoder for structured mesh, autoencoder for unstructured mesh, decoder or surface field.
Machine learning parameters are user configurable, in which the machine learning parameters include one or more of the following: number of hidden layers, size of hidden layer, number of training steps, batch size, dropout fraction, uncertainty.
The method includes the step of estimating or predicting the error in satisfying a target variable.
The method includes the step of evaluating the level of noise in the input data.
The method includes the step of determining the sensitivity of each design parameters on the performance of the 3D object.
The method includes the step of determining one or more design parameters having the biggest influence on the performance of the 3D object.
The method includes the step of determining how much changes of the design parameters cause changes in one or more target variables.
The method is implemented automatically.
The method is implemented in real-time.

Latent Space
Machine learning system includes an autoencoder to reduce a dimensionality of the 3D object to a latent space having one or more latent parameters;
An optimal set of latent parameters is generated based on a target variable.
The method includes the step of determining an optimum number of latent parameters automatically.
The method includes the step of determining an optimum dimension of latent parameters based on a target variable.
Latent parameters can be updated by an end-user, such as using sliders via a GUI.
The method includes the step of predicting the performance of novel geometries of the 3D object corresponding to the updated latent parameters.
The method includes the step of generating novel geometries of the 3D object based on different combination of latent parameters.
Random sampling from latent space enables the generation of an infinite plurality of previously unseen novel geometries of the 3D object.
The set of latent parameters corresponding to the 3D object is labeled with a user configurable concept.
The set of labeled latent parameters is inputted to another machine learning system, such as linear regression model.
The method includes the step of generating a set of latent parameters that have a high probability of belonging to a user defined concept.

Explainability
The method includes the step of providing a quick comparison of quality and/or accuracy of different machine learning systems.
The method includes the step of determining regions of input space that are the most important for the machine learning system.
The method includes the step of predicting error of the machine learning system.
The method includes selecting one or more explainability techniques based on a target variable.
Existing explainability techniques such as LIME, Deep SNAP, ExpectedGradients are adapted to work in the 3D domain.
Explainability data is tailored to a target variable.
Explainability data is tailored to an intermediate target variable or concept, in which the intermediate target variable or concept is designed by an end-user using a DL model.
Target variable is predicted by fitting an interpretable model to one or more intermediary target variable or concept.
Explainability data is tailored to an end-user level of expertise, such as non-technical end-user, or technical end-user.
Explainability data is tailored based on a downstream application for the 3D object.
Quality of explainability data is determined by (i) segmenting point clouds using k-means clustering, (ii) removing the top k % of segments deemed the most informative (iii) comparing the loss value with a random selection of segments to assess performance above a random baseline.
Machine learning system is a neural network consisting of an input layer, output layer and a plurality of hidden layers.
Method includes understanding or predicting one or more of the following: efficiency, quality, stability or sensitivity of the machine learning system.
The method includes understanding relationships and sensitivities between an input layer and an output layer of the neural network.
The method is used to determine and/or visualise activation function in one or more hidden layers of the machine learning system.
The method is used to determine patterns that cause activations in one or more hidden layers of the machine learning system.
The method is used to determine training samples that are pushing the prediction of a downstream quantity in a particular direction.
The method includes highlighting regions of the input pushing the prediction in a specific direction.
The method is a hybrid method, in which an end-user evaluates explainability data.
The method outputs evaluation results, in which the evaluations results are then used to augment or update training data of the machine learning system.
The method is implemented automatically.
The method is implemented in real-time.
The method outputs one or more novel geometries of the 3D object.
The method takes into account previously outputted novel geometries of the 3D object.
Behaviour of previously generated novel geometries of the 3D object is considered to predict the behaviour of unseen geometries of the 3D object.
The method includes understanding behavior or predicting trends of unseen geometries of the 3D object.
The method includes understanding local part(s) of a geometry of the 3D object that is affecting a downstream performance or target variable.

GUI
the method includes the step of: receiving queries from an end-user, using a graphical user interface (GUI); and providing the results of each query on the GUI.
The GUI is a low code or zero code notebook style interface.
Method includes the step of displaying 3D saliency map for the 3D object in the GUI.
Method includes the step of displaying a 3D saliency map that indicates relative importance of input regions for a given set of target variables.
The method includes highlighting geometric regions that affects one or more target variables in the GUI.
Queries are received sequentially to build a data processing pipeline.
When the orders of the queries are changed, each subsequent query following the re-ordered query is automatically re-run.
When a query is updated, each subsequent query following the updated query is automatically re-run.
GUI is configured to provide a historical overview of how and when each data and machine learning system has been inputted, created, transformed and/or used.
GUI provides a simple interface in which the end-user can easily train one or multiple machine learning systems, such as neural network, decision tree regression, gaussian process regression, linear regression, nearest neighbours regression, polynomial regression, random forest regression or support vector regression or any other 3D machine learning or deep learning model.
GUI provides a scoring metric for each machine learning system, such as result of loss function as a function of training steps.
Scoring metric is determined with each training step.
Scoring metric is displayed in real-time, as the model is being trained.
input data is automatically split between training data and testing data based on a user configurable percentage.

Output Data
Method includes the step of outputting or displaying 3D output data.
3D output data is an exportable 3D format tailored for a specific downstream application.
Method can be applied to any one or more of the following downstream applications: random shape generation, interpolation between designs, embedding data in a downstream quantity of interest prediction task, discovery of optimal designs.
The method further includes a step of implementing a shape optimization algorithm.

Dynamic Graph CNN
the method includes the step of generating a plurality of 3D surface field predictions using a Dynamic Graph CNN approach with training data, in which the input data is processed multiple times using multiple subsets of the training data.
Input data includes a mesh, and when the number of points in the mesh is prohibitively large, multiple random subsets of training data are sampled to create manageable sized of training batches.
Training data is augmented by applying random transformations.
The method is used to estimate uncertainties by making predictions for different subsets of input points and estimating the standard deviation of prediction for each point.
The method implements a regression model to predict either a scalar or surface field target.

Structure Autoencoder (SAE)
The method includes the step of converting a dimensionality of the 3D object into a latent space having one or more of latent parameters using a structured autoencoder approach, in which a principal component analysis (PCA) is used as a pre-processing step of the structured autoencoder approach.
Number of PCA components is pre-determined.
Number of PCA components is automatically determined based on the input data.
Number of PCA components is automatically determined based on a subset of the training data.
Single hidden layer is used for both encoder and decoder of the autoencoder.

Unstructured Autoencoder (UAE)
The method includes the step of converting a dimensionality of the 3D object into a latent space having one or more of latent parameters using a stacked autoencoder architecture, in which a first autoencoder is used to encode the input data into a first set of latent vectors, and a second autoencoder is then used to encode the first set of latent vectors into a second set of latent vectors.
Wasserstein loss function is implemented.
Wasserstein regularization is implemented to provide a pre-determined dimensions of the latent parameters.
Each autoencoder is configured in such a way that the latent parameters are approximately normally distributed.
The method includes the step of automatically choosing the first and second autoencoder based on the input data.
Dimension of latent parameters is adjusted by retraining only one of the autoencoder.
The second ‘stacked auto-encoder’ is configured to be much faster to train than the first autoencoder.
One or more hyper-parameter, such as the latent dimension, can be varied and tested without the need to train the entire UAE.
the method includes the step of converting a dimensionality of the 3D object into a latent space having one or more of latent parameters using an unstructured autoencoder architecture, in which the method includes the step of automatically choosing an optimum autoencoder, such as convolutional or non-convolutional UAE, based on the input data.
stacked autoencoder architecture is implemented.

### Note

It is to be understood that the above-referenced arrangements are only illustrative of the application for the principles of the present invention. Numerous modifications and alternative arrangements can be devised without departing from the spirit and scope of the present invention. While the present invention has been shown in the drawings and fully described above with particularity and detail in connection with what is presently deemed to be the most practical and preferred example(s) of the invention, it will be apparent to those of ordinary skill in the art that numerous modifications can be made without departing from the principles and concepts of the invention as set forth herein.

1. A computer implemented method for generating a 3D object, the method comprising:
training a machine learning system to learn design parameter values that give rise to an optimally performing version of the 3D object; and
processing, using the machine learning system, input data relating to the 3D object, in an unsupervised manner such that it can be used for generative purposes, such as the creation of novel geometries or other parameters of the 3D object.

2. The method of claim 1, in which the novel geometries or other parameters of the 3D object define an optimally performing version of the 3D object.

3. The method of claim 1, in which the design parameters relate to any one or more of the following areas: design, durability, ergonomics, structural dynamics, aerodynamics, simulation, testing and manufacturing.

4. The method of claim 1, in which the machine learning system is trained to predict the performance of the 3D object across multiple areas, the areas including several of the following areas: design, durability, ergonomics, structural dynamics, aerodynamics, simulation, testing and manufacturing.

5. The method of claim 4, in which the method further includes the steps of:
processing, using the machine learning system, input data relating to the 3D object, the 3D object having a set of raw data relating to the 3D object, design parameters and/or operating conditions; and
predicting, using the machine learning system, the performance of the 3D object across one or more of the areas.

6. The method of claim 4, in which the method further includes the step of predicting, using the machine learning system, the performance of the novel geometries of the 3D object across one or more of the areas.

7. The method of claim 4, in which the method further includes the step of predicting, using the machine learning system, the performance of the 3D object across each of the multiple areas.

8. The method of claim 1, in which the method further includes the steps of:
training the machine learning system to map at least one user configurable concept to a latent space;
processing, using the machine learning system, input data relating to the 3D object, to classify the 3D object in terms of the user configurable concept; and
generating and applying AI-derived parameters to the 3D object to alter, or enable a user to alter, a value or parameter of the user configurable concept of the 3D object.

9. The method of claim 1, in which the method further includes the steps of:
training the machine learning system to map the importance or saliency of object geometry to a target variable;
processing, using the machine learning system, input data relating to the geometry of the 3D object; and
generating and displaying a saliency map that shows the value of the target variable across the 3D object.

10. The method of claim 1, in which the method further includes the step of automatically altering the geometry of the 3D object to optimise that geometry against a target variable, and/or generating an optimum set of design parameters based on a target variable.

11. The method of claim 1, in which the method includes the step of predicting the outcome of multi-physics 3D numerical simulations for the 3D object or for the novel geometries of the 3D object.

12. The method of claim 1, in which the method includes the step of providing instant predictions for what a 3D simulation results would be if the 3D object or novel geometries of the 3D object were tested under different operating or testing conditions.

13. The method of claim 1, in which the machine learning system includes a 3D deep learning model such as 3D to scalar model, autoencoder for structured mesh, autoencoder for unstructured mesh, decoder or surface field.

14. The method of claim 1, in which the method includes the step of estimating or predicting the error in satisfying a target variable.

15. The method of claim 1, in which the method includes the step of determining one or more design parameters having the biggest influence on one or more target variables and/or how much changes of the design parameters cause changes in one or more target variables.

16. The method of claim 1, in which the machine learning system includes an autoencoder to reduce a dimensionality of the 3D object to a latent space having one or more latent parameters.

17. The method of claim 16, in which an optimal set of latent parameters is generated based on a target variable.

18. The method of claim 16, in which the method includes the step of determining an optimum number of latent parameters automatically.

19. The method of claim 16, in which the latent parameters are updated by an end-user, such as using sliders via a GUI, and the method includes the step of predicting the performance of the novel geometries of the 3D object corresponding to the updated latent parameters.

20. The method of claim, 16 in which the method includes the step of generating the novel geometries of the 3D object based on different combination of latent parameters.

21. The method of claim 16, in which random sampling from latent space enables the generation of an infinite plurality of previously unseen novel geometries of the 3D object.

22. The method of claim 1, in which the method includes the step of providing explainability data relating to the machine learning system that is human interpretable.

23. The method of claim 22, in which the method outputs evaluation results; and in which the evaluations results are then used to augment or update training data of the machine learning system.

24. The method of claim 1, in which the method includes the step of:
receiving queries from an end-user, using a graphical user interface (GUI); and
providing the results of each query on the GUI and in which the GUI is a low code or zero code notebook style interface.

25. The method of claim 24, in which when the orders of the queries are changed or when a query is updated, each subsequent query following the re-ordered or updated query is automatically re-run.

26. The method of claim 1, in which the method includes the step of generating a plurality of 3D surface field predictions using a Dynamic Graph CNN approach with training data, in which the input data is processed multiple times using multiple subsets of the training data.

27. The method of claim 1, in which the method includes the step of converting a digital representation of the 3D object into a latent space having one or more of latent parameters using a stacked autoencoder architecture, in which a first autoencoder is used to encode the input data into a first set of latent vectors, and a second autoencoder is then used to encode the first set of latent vectors into a second set of latent vectors and in which the second ‘stacked auto-encoder’ is configured to be much faster to train than the first autoencoder.

28. The method of claim 1, in which the method includes the step of converting a digital representation of the 3D object into a latent space having one or more of latent parameters using an unstructured autoencoder architecture, in which the method includes the step of automatically choosing an optimum autoencoder, such as convolutional or non-convolutional UAE, based on the input data.

29. A computer implemented system for processing input data relating to a 3D object, the system comprising:
a non-transitory storage medium;
a processor coupled to the storage medium and configured to:
train a machine learning system to learn design parameter values that give rise to an optimally performing version of the 3D object;
process, using the machine learning system, input data relating to the 3D object, in an unsupervised manner such that it can be used for generative purposes, such as the creation of novel geometries or other parameters of the 3D object.

30. A 3D object generated by a computer implemented method comprising the steps of:
training a machine learning system to learn design parameter values that give rise to an optimally performing version of the 3D object;
processing, using the machine learning system, input data relating to the 3D object, in an unsupervised manner such that it can be used for generative purposes, such as the creation of novel geometries or other parameters of the 3D object.
